(19) United States
(12) Patent Application Publication
(10) Pub. No.: US 2009/0311494 A1
(43) Pub. Date: Dec. 17, 2009

(54) RELIEF PRINTING PLATE PRECURSOR FOR LASER ENGRAVING, RELIEF PRINTING PLATE, AND PROCESS FOR PRODUCING RELIEF PRINTING PLATE

(75) Inventors: Masako YAMASHITA, Shizuoka-ken (JP); Atsushi SUGASAKI, Shizuoka-ken (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/476,260

(22) Filed: Jun. 2, 2009

(30) Foreign Application Priority Data
Jun. 17, 2008 (JP) 2008-157907
Feb. 10, 2009 (JP) 2009-028816

(51) Int. Cl. B32B 3/00; G03F 7/20; G03F 7/004

(52) U.S. Cl. 428/195.1; 430/306; 430/286.1

(57) ABSTRACT

A relief printing plate precursor for laser engraving, including a relief forming layer containing (A) a polymerizable compound having an ethylenic unsaturated bond, (B) a binder polymer, and (C) a compound having deodorizing ability.

### CROSS-REFERENCE TO RELATED APPLICATION

This application claims priority under 35 USC 119 from Japanese Patent Application Nos. 2008-157907 and 2009-028816, the disclosures of which are incorporated by reference herein.

### BACKGROUND OF THE INVENTION

1. Field of the Invention

The present invention relates to a relief printing plate precursor for laser engraving, a relief printing plate, and a process for producing a relief printing plate.

2. Description of the Related Art

As a method of forming concavity and convexity on a photosensitive resin layer laminated on a support surface to form a printing plate, a method of exposing a relief forming layer formed using a photosensitive composition with ultraviolet light via an original image film to selectively cure an image area, and removing an uncured area with a developer, so-called “analog platemaking”, is well known.

A relief printing plate is a letterpress printing plate including a relief layer having concavity and convexity, and such a relief layer having concavity and convexity is obtained by patterning a relief forming layer containing a photosensitive composition containing an elastomeric polymer such as a synthetic rubber, a resin such as a thermoplastic resin, or a mixture of a resin and a plasticizer as a main component, to form concavity and convexity. Among such relief printing plates, a printing plate having a soft relief layer is sometimes called a flexographic plate.

When a relief printing plate is made by analog platemaking, generally, since an original image film using a silver salt material is required, the production time and the cost for the original image film are necessary. Further, since chemical treatment is necessary for developing an original image film, and disposal of a development waste solution is also necessary, further simpler processes for producing a plate such as, for example, a method not using an original image film, and a method not requiring development treatment are being studied.

In recent years, a method of platemaking of a relief forming layer by scanning light exposure without requiring an original film is being studied.

For a procedure not requiring an original film, a relief printing plate precursor has been proposed in which a laser-sensitive mask layer element which can form an image mask is provided on a relief forming layer (see e.g. Japanese Patent No. 2773847 and Japanese Patent Application Laid-Open (JP-A) No. 9-171247). According to the process of platemaking using the plate precursor, since an image mask having the same function as that of an original image film is formed from the mask layer element by laser irradiation based on image data, the process is called a “mask CTP method”. In this process, an original image film is not required, but platemaking treatment thereafter is a step of performing light exposure with ultraviolet light via an image mask to develop and remove an uncured area, and there is room for improvement since development treatment is necessary.

As a method of making a plate without requiring a developing step, many so-called “direct engraving CTP methods” have been proposed in which a relief forming layer is directly engraved with a laser to make a plate. The direct engraving CTP method is a method of forming concavity and convexity, which are to be a relief, by engraving with a laser, and has an advantage in that unlike a relief formation method using an original image film, a relief shape can be freely controlled. For this reason, when an image such as an outline character is formed, its region may be engraved deeper than other regions, or in a fine dot image, in view of resistance to a printing pressure, engraving with a shoulder may be performed.

However, there is a problem in that, for forming a relief having concavity and convexity withstanding a printing pressure on a relief forming layer having a predetermined thickness, a high energy is necessary, and since a rate of laser engraving is slow, productivity is low as compared with a type for forming an image via a mask.

For this reason, improvement in a sensitivity of a relief plate precursor has been tried and, for example, a flexographic printing plate precursor for laser engraving including a foamed elastomer has been proposed (see e.g. JP-A No. 2002-357907). In this technique, improvement in an engraving sensitivity is made by using a foamed material having a low density in a relief forming layer, but since it is a material having a low density, a strength for a printing plate is insufficient, and print durability is remarkably deteriorated.

In addition, for example, Japanese Patent No. 2846954, JP-A No. 11-338139, and JP-A No. 11-170718 disclose a flexographic plate precursor which may be laser-engraved, or a flexographic plate obtained by laser engraving. In these publications, a monomer is mixed into an elastomeric rubber as a binder, the mixture is cured by a thermal polymerization mechanism or a photopolymerization mechanism, and laser engraving is performed to obtain a flexographic plate, but there is a problem in that an unpleasant odor such as a burnt rubber odor is generated at laser engraving.

In addition, as a problem possessed by the direct engraving CPT method, there is a slow rate of laser engraving. This is because in the mask CTP method, a thickness of a mask layer element to be ablated is around 1 to 10 μm, while in the direct engraving CTP method, it is necessary to engrave at least 100 μm for directly forming a relief.

For this reason, some proposals aiming at improving a laser engraving sensitivity have been made as follows.

For example, a flexographic printing plate precursor for laser engraving including a foamed elastomer has been proposed (see e.g. JP-A No. 2000-318330). In this technique, by using a foamed material having a low density, improvement in an engraving sensitivity is made, but since the material is a material having a low density, there is a problem in that a strength as a printing plate is insufficient, and print durability is remarkably deteriorated.

For example, a flexographic printing plate precursor for laser engraving containing a microsphere in which a hydrocarbon gas has been encapsulated, has been proposed (see e.g. US Patent Application Publication 2003/180636). In this technique, by a system of expanding a gas in a microsphere with heat produced by a laser, and disintegrating a material to be engraved, improvement in an engraving sensitivity is made, but since the material is a material containing bubbles, there is a problem in that a strength as a printing plate tends to be lacking. In addition, since a gas has a nature of being easily expanded with heat as compared with a solid, even when a microsphere having a high thermal deformation initiating temperature is selected, a volume change due to change in an external temperature cannot be avoided, and thus, it is not suitable to use a material containing bubbles in a printing plate required to have stability of a thickness precision.

For example, a resin letterpress printing plate for laser engraving containing a polymer filler having a ceiling temperature of lower than 600 K has been proposed (see e.g. JP-A No. 2000-168253). In this technique, by adding a polymer filler having a low depolymerization temperature, improvement in an engraving sensitivity is made, but there is a problem in that when such a polymer filler is used, concavity and convexity are generated on a surface of a printing plate precursor, and this imparts great influence on printing quality.

In addition, as a technique of suppressing an unpleasant odor generated when carrying out laser engraving, for example, a flexographic printing plate has been proposed which includes a laser processing polymer material obtained by crosslinking a polymer composition containing a polymer including 45% by mass or more of an ethylene unit as a repetition unit, and an organic peroxide (see e.g. JP-A No. 2002-3665). According to this flexographic printing plate, an odor from a polymer material may be improved.

As described above, regarding a relief forming layer of a relief printing plate precursor for laser engraving, various techniques have been proposed, but a technique of suppressing an unpleasant odor generated at laser engraving while maintaining a high engraving sensitivity when carrying out laser engraving has, for the most part, not been proposed.

### SUMMARY OF THE INVENTION

According to an aspect of the invention, there is provided a relief printing plate precursor for laser engraving, comprising a relief forming layer containing (A) a polymerizable compound having an ethylenic unsaturated bond, (B) a binder polymer, and (C) a compound having deodorizing ability.

### BRIEF DESCRIPTION OF THE DRAWINGS

FIG. 1 is a schematic constitution view (perspective view) showing a platemaking apparatus provided with a semiconductor laser recording device equipped with a fiber, which may be applied to the invention.

### DETAILED DESCRIPTION OF THE INVENTION

The relief printing plate precursor for laser engraving, the relief printing plate, and the process for producing the relief printing plate of the present invention will be explained below in detail.

[Relief Printing Plate Precursor for Laser Engraving]

The relief printing plate precursor for laser engraving of the invention has a relief forming layer containing at least (A) a polymerizable compound having an ethylenic unsaturated bond, (B) a binder polymer, and (C) a compound having deodorizing ability.

The relief printing plate precursor for laser engraving of the invention is also referred to as simply “relief printing plate precursor of the invention”.

Since the relief printing plate precursor of the invention has a sufficiently high engraving sensitivity when carrying out laser engraving, and may perform laser engraving at a high speed, an engraving time may be shortened and, at the same time, an unpleasant odor generated at laser engraving may be suppressed.

Respective components constituting the relief forming layer will be explained below.

<(A) Polymerizable Compound Having Ethylenic Unsaturated Bond>

The relief forming layer in the invention contains (A) a polymerizable compound having an ethylenic unsaturated bond.

The polymerizable compound having an ethylenic unsaturated bond used in the invention (hereinafter, simply referred to as “polymerizable compound” in some cases) may be arbitrarily selected from compounds having at least 1, preferably 2 or more, more preferably 2 to 6 ethylenic unsaturated double bonds.

A monofunctional monomer having one ethylenic unsaturated double bond in the molecule, and a polyfunctional monomer having 2 or more ethylenic unsaturated double bonds in the molecule, which are used as the polymerizable compound, will be explained below.

In the relief forming layer in the invention, the polyfunctional monomer is preferably used. It is preferable that a molecular weight of the polyfunctional monomer is 200 to 2,000.

Examples of the monofunctional monomer and the polyfunctional monomer include esters of unsaturated carboxylic acid (e.g. acrylic acid, methacrylic acid, itaconic acid, crotonic acid, isocrotonic acid, maleic acid etc.) and a polyhydric alcohol compound, and amides of unsaturated carboxylic acid and a polyvalent amine compound.

Examples of the monomer of the ester of the polyhydric alcohol compound and the unsaturated carboxylic acid include, as an acrylic acid ester, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol pentaacrylate, dipentaerythritol hexaacrylate, sorbitol triacrylate, sorbitol tetraacrylate, sorbitol pentaacrylate, sorbitol hexaacrylate, tri(acroyloxyethyl) isocyanurate, and polyester acrylate oligomer.

Examples of the monomer as a methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, dipentaerythritol pentamethacrylate, sorbitol trimethacrylate, sorbitol tetramethacrylate, bis[p-(3-methacryloxy-2-hydroxypropoxy)phenyl]dimethylmethane, and bis-[p-(methacryloxyethoxy)phenyl]dimethylmethane.

Examples of the monomer as an itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the monomer as a crotonic acid ester include ethylene glycol dicrotonate, tetramethylene glycol dicrotonate, pentaerythritol dicrotonate, and sorbitol tetradicrotonate.

Examples of the monomer as an isocrotonic acid ester include ethylene glycol diisocrotonate, pentaerythritol diisocrotonate, and sorbitol tetraisocrotonate.

Examples of the monomer as a maleic acid ester include ethylene glycol dimaleate, triethylene glycol dimaleate, pentaerythritol dimaleate, and sorbitol tetramaleate.

Further, a mixture of the aforementioned ester monomers may be exemplified.

In addition, examples of the monomer of amide of the polyvalent amine compound and the unsaturated carboxylic acid include methylenebis-acrylamide, methylenebis-methacrylamide, 1,6-hexamethylenebis-acrylamide, 1,6-hexamethylenebis-methacrylamide, diethylenetriamine trisacrylamide, xylylenebisacrylamide, and xylylenebismethacrylamide.

In addition, examples include polyfunctional acrylates and methacrylates such as urethane acrylates described in JP-A No. 51-37193, and polyester acrylates, and epoxy acrylates obtained by reacting an epoxy resin and (meth)acrylic acid described in JP-A No. 48-64183, Japanese Patent Application Publication (JP-B) No. 49-43191, and JP-B No. 52-30490. Further, compounds which are introduced as a photocurable monomer and oligomer in Journal of the Adhesion Society of Japan, Vol. 20, No. 7, pp 300 to 308 (1984) may be used.

Specifically, examples include NK Oligo U-4HA, U-4H, U-6HA, U-6ELH, U-108A, U-1084A, U-200AX, U-122A, U-340A, U-324A, UA-100 (all, manufactured by Shin-Nakamura Chemical Co., Ltd.), UA-306H, AI-600, UA-101T, UA-101I, UA-306T, UA-306I (all, manufactured by Kyoeisha Chemical Co., Ltd.), Art Resin UN-9200A, UN-3320HA, UN-3320HB, UN-3320HC, SH-380G, SH-500, SH-9832 (all, manufactured by Negami Chemical Industrial Co., Ltd.), and PLEX6661-0 (manufactured by Degussa, Germany).

In the invention, it is preferable to use a compound having a sulfur atom in the molecule as the polymerizable compound from a viewpoint of improvement in an engraving sensitivity.

It is preferable to use, as such a polymerizable compound having a sulfur atom in the molecule, particularly, a polymerizable compound having 2 or more ethylenic unsaturated bonds, and having a carbon-sulfur bond at a site connecting two ethylenic unsaturated bonds among them (hereinafter conveniently referred to as “sulfur-containing polyfunctional monomer”) from a viewpoint of improvement in an engraving sensitivity.

Examples of the functional group containing a carbon-sulfur bond in the sulfur-containing polyfunctional monomer in the invention include functional groups containing sulfide, disulfide, sulfoxide, sulfonyl, sulfonamide, thiocarbonyl, thiocarboxylic acid, dithiocarboxylic acid, sulfamic acid, thioamide, thiocarbamate, dithiocarbamate, or thiourea.

The number of sulfur atoms contained in the molecule of the sulfur-containing polyfunctional monomer is not particularly limited as far as it is 1 or more, but may be arbitrarily selected depending on the purpose and, from a viewpoint of balance between an engraving sensitivity and solubility in a coating solvent, the number is preferably 1 to 10, more preferably 1 to 5, further preferably 1 to 2.

On the other hand, the number of ethylenic unsaturated sites contained in the molecule is not particularly limited as far as it is 2 or more, but may be arbitrarily selected depending on the purpose and, from a viewpoint of softness of a crosslinked film, the number is preferably 2 to 10, more preferably 2 to 6, further preferably 2 to 4.

Examples of the sulfur-containing polyfunctional monomer which is used preferably, are shown below.

R in the following examples represents a hydrogen atom or a methyl group, and plural Rs present in the molecule may be the same or different.

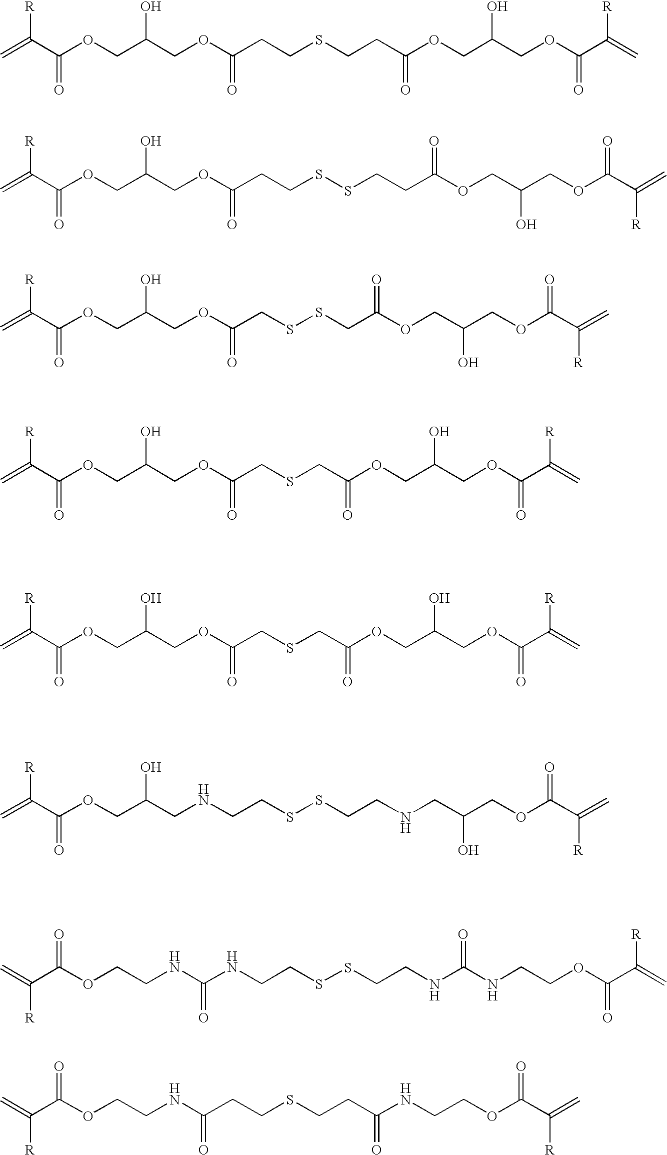

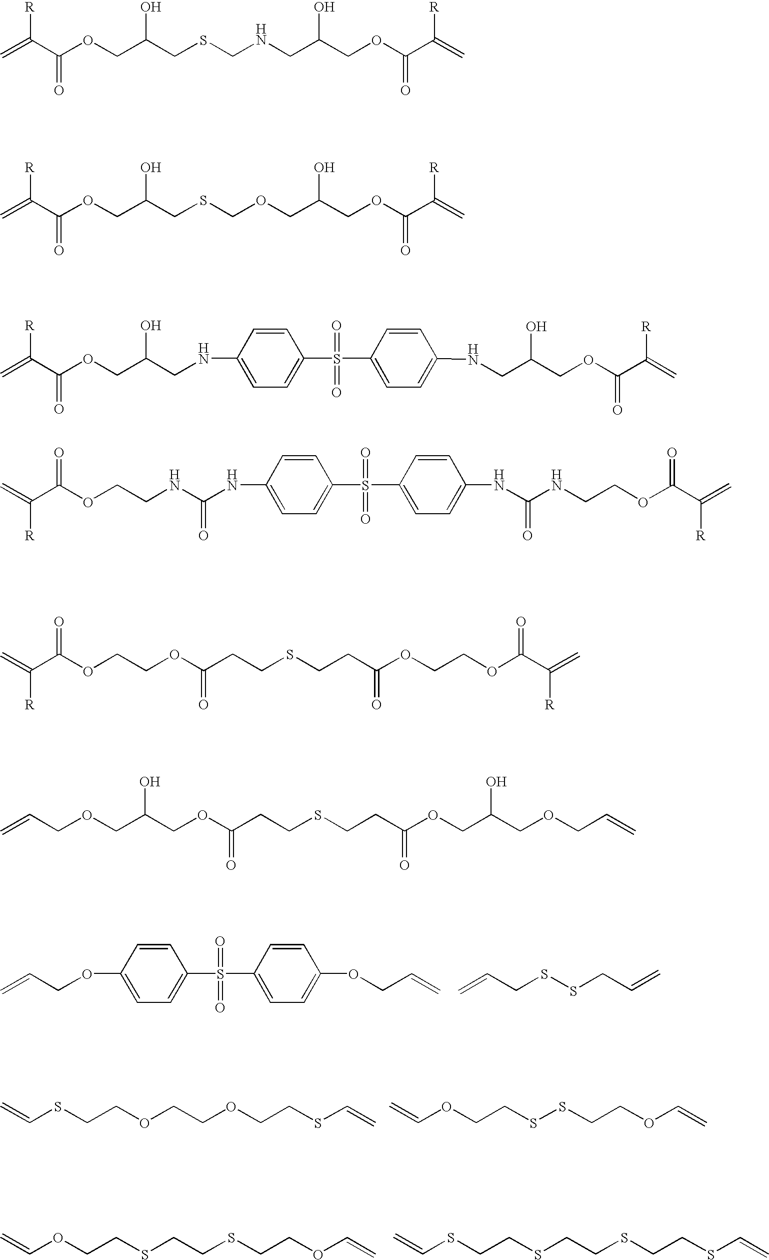

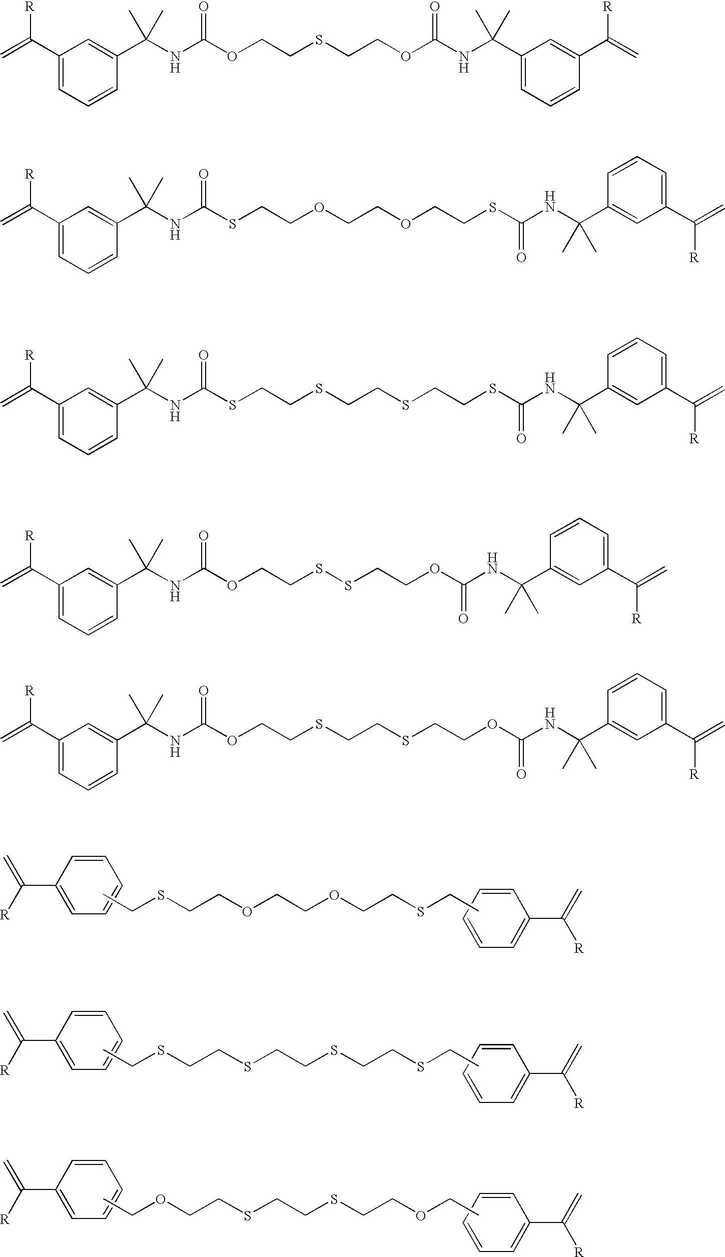

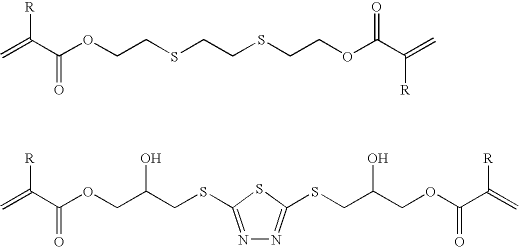

The sulfur-containing polyfunctional monomer in the invention may be synthesized using a reaction of a sulfur atom-containing dicarboxylic acid and an epoxy group-containing (meth)acrylate, a reaction of sulfur atom-containing diol and isocyanate-containing (meth)acrylate, a reaction of dithiol and isocyanate-containing (meth)acrylate, a reaction of diisothiocyanate and hydroxyl group-containing (meth)acrylate, or the known esterification reaction. Alternatively, a commercially available product may be used.

A molecular weight of the sulfur-containing polyfunctional monomer in the invention is preferably 120 to 3000, more preferably 120 to 1500 from a viewpoint of softness of a formed film.

The sulfur-containing polyfunctional monomer in the invention may be used alone, or may be used as a mixture with a polyfunctional polymerizable compound or monofunctional polymerizable compound having no sulfur atom in the molecule.

From a viewpoint of an engraving sensitivity, an embodiment in which the sulfur-containing polyfunctional monomer is used alone, or the monomer is used as a mixture of the sulfur-containing polyfunctional monomer and a monofunctional ethylenic monomer is preferable, and an embodiment in which the monomer is used as a mixture of the sulfur-containing polyfunctional monomer and a monofunctional ethylenic monomer is more preferable.

In the relief forming layer in the invention, film physical properties, for example, fragility and softness may be also adjusted by using the polymerizable compound including the sulfur-containing polyfunctional monomer.

A total content of the polymerizable compound including the sulfur-containing polyfunctional monomer in the relief forming layer in the invention is preferably in the range of 5% by mass to 90% by mass, more preferably in the range of 10% by mass to 75% by mass, further preferably in the range of 10% by mass to 60% by mass, particularly preferably in the range of 15% by mass to 40% by mass from a viewpoint of softness and fragility of a crosslinked film.

When the sulfur-containing polyfunctional monomer and other polymerizable compound are used together, the amount of the sulfur-containing polyfunctional monomer in the total polymerizable compound is preferably 5% by mass or more, more preferably 10% by mass or more.

### <(B) Binder Polymer>

The relief forming layer in the invention contains (B) a binder polymer.

The (B) binder polymer used in the invention is a main component contained in the relief forming layer, and usually, a thermoplastic resin and a thermoplastic elastomer are used depending on the purpose.

For example, from a viewpoint of a laser engraving sensitivity, a polymer containing a partial structure which is thermally decomposed by light exposure or heating is preferable.

For example, when formation of a film which is soft and has flexibility is aimed at, a soft resin or a thermoplastic elastomer is selected.

Further, from a viewpoint of easiness of preparation of a coating composition for the relief forming layer, and improvement in resistance to an oily ink in the resulting relief printing plate, it is preferable to use a hydrophilic or alcoholphilic polymer.

In addition, for example, when used for the purpose of curing by heating or light exposure to improve a strength, a polymer having a carbon-carbon unsaturated bond in the molecule is selected as the binder polymer.

Like this, in view of physical properties depending on application of the relief printing plate precursor, the binder polymer depending on the purpose is selected, and one kind of the binder polymer, or a combination of two or more kinds may be used.

Various polymers which may be used as the binder polymer in the invention will be explained below.

(Polymer Having Decomposability)

Examples of the binder polymer which is preferably used from a viewpoint of a laser engraving sensitivity include a polymer having a partial structure which is decomposed by energy application such as light exposure and heating (polymer having decomposability).

Examples of the polymer having decomposability include polymers containing, as a monomer unit having a partial structure which is easily decomposed or cut in a molecular chain, styrene, α-methylstyrene, α-methoxystyrene, acryl esters, methacryl esters, other ester compounds, ether compounds, nitro compounds, carbonate compounds, carbamoyl compounds, hemiacetal ester compounds, oxyethylene compounds, or aliphatic cyclic compounds.

Among them, particularly, preferable examples include polyethers such as polyethylene glycol, polypropylene glycol, and polytetraethylene glycol, aliphatic polycarbonates, aliphatic carbamates, polymethyl methacrylate, polystyrene, nitrocellulose, polyoxyethylene, polynorbornene, hydrogenated polycyclohexadiene, and a polymer having a molecular structure such as a dendrimer having many branched structures, from a viewpoint of decomposability.

A polymer containing a number of oxygen atoms in a molecular chain is preferable from a viewpoint of decomposability. From such a point of view, preferable examples include compounds having a carbonate group, a carbamate group, or a methacryl group in a polymer main chain.

Preferable examples of a polymer having good heat decomposability include polyester and polyurethane synthesized using, as a raw material, (poly)carbonate diol and (poly)carbonate dicarboxylic acid, and polyamide synthesized using, as a raw material, (poly)carbonate diamine. These polymers may contain a polymerizable unsaturated group in a main chain and a side chain. Particularly, when the polymers have a reactive functional group such as a hydroxyl group, an amino group, and a carboxyl group, it is easy to introduce a polymerizable unsaturated group into such a heat-decomposable polymer.

As the polymer having decomposability, a polyester containing a hydroxylcarboxylic acid unit such as polylactic acid may be used. As such a polyester, specifically a polyester selected from the group consisting of polyhydroxyalkanoate (PHA), lactic acid polymer, polyglycolic acid (PGA), polycaprolactone (PCL), poly(butylenesuccinic acid), and a derivative or a mixture thereof is preferable.

(Thermoplastic Polymer)

As one of binder polymers which are preferably used from a viewpoint of a laser engraving sensitivity, there is a thermoplastic polymer.

The thermoplastic polymer may be an elastomeric or non-elastomeric resin, and may be selected depending on use mode of the relief printing plate precursor of the invention.

Examples of the thermoplastic elastomer include a urethane thermoplastic elastomer, an ester thermoplastic elastomer, an amide thermoplastic elastomer, and a silicone thermoplastic elastomer. For the purpose of improving a laser engraving sensitivity of these thermoplastic elastomers, an elastomer in which an easily decomposable functional group such as a carbamoyl group and a carbonate group is introduced into a main chain thereof may be used. The thermoplastic polymer and the thermally decomposable polymer may be used by mixing them.

The thermoplastic elastomer is a material exhibiting rubber elasticity at a normal temperature and, as a molecular structure, contains a soft segment such as polyether and a rubber molecule, and a hard segment which prevents plastic deformation like a vulcanized rubber at around a normal temperature and, as the hard segment, various types such as frozen phase, crystal phase, hydrogen bond, and ion crosslinking are present. Such a thermoplastic elastomer is suitable, for example, when the relief printing plate precursor of the invention needs flexibility such as a flexographic plate.

The kind of the thermoplastic elastomer is selected depending on the purpose, for example, when solvent resistance is required, urethane, ester, amide, and fluorine thermoplastic elastomers are preferable and, when heat resistance is required, urethane, olefin, ester, and fluorine thermoplastic elastomers are preferable. And, by selecting the kind of the thermoplastic elastomer, hardness of the relief forming layer may be greatly changed.

Examples of the non-elastomeric resin include a polyester resin, an unsaturated polyester resin, a polyamide resin, a polyamideimide resin, a polyurethane resin, an unsaturated polyurethane resin, a polysulfone resin, a polyether sulfone resin, a polyimide resin, a polycarbonate resin, a wholly aromatic polyester resin, and a hydrophilic polymer containing a hydroxyethylene unit (e.g. polyvinyl alcohol derivative).

(Hydrophilic or Alcoholphilic Polymer)

As the binder polymer used in the invention, a hydrophilic or alcoholphilic binder polymer is preferable from a viewpoint of removability of waste after engraving. More particularly, examples of the hydrophilic polymer include hydrophilic polymers described later and, among them, a hydrophilic polymer containing a hydroxyethylene unit is preferable. In addition, as the alcoholphilic binder, for example, a polymer such as polyvinyl butyral may be suitably used.

—Hydrophilic Polymer—

The hydrophilic polymer which is one of preferable embodiments of the binder polymer will be described in detail.

The hydrophilic polymer refers to a water-soluble or water-swellable polymer. Herein, in the invention, the “water-soluble” refers to that the polymer is dissolved in water at 25° C. in an amount of 5% by mass or more, and the “water-swellable” refers to the state where, when the polymer is added to water at 25° C. in an amount of 5% by mass, the polymer absorbs water, and is swollen and, when it is seen visually, it is not dissolved, but an apparent solid (powdery) precipitate is not present.

As the hydrophilic polymer, the polymer alone may be used, or plural kinds of polymers may be used.

Examples of the hydrophilic polymer include a hydrophilic polymer containing a hydroxyethylene unit, polysaccharides having a hydrophilic functional group including cellulose, an acryl resin containing a salt structure in which an acidic functional group is neutralized such as polysodium acrylate, a salt structure in which an amino group is neutralized, or an onium structure, a polyamide resin or a polyester resin in which a hydrophilic group such as polyethylene oxide is introduced, and gelatin.

As the hydrophilic polymer, from a viewpoint of exhibiting good hydrophilicity, a hydrophilic polymer containing hydroxyethylene, cellulose containing a polar group such as an amino group, a carboxylic acid group, a sulfonic acid group, a sulfuric acid group, and a salt structure obtained by neutralizing these groups, an acryl resin containing a polar group such as an amino group, a carboxylic acid group, a sulfonic acid group, a sulfuric acid group, and a salt structure obtained by neutralizing these groups, and a polyamide resin are preferable. A hydrophilic polymer containing hydroxyethylene, and an acryl resin containing a polar group such as an amino group, a carboxylic acid group, a sulfonic acid group, a sulfuric acid group, and a salt structure obtained by neutralizing these groups, and a polyamide resin are more preferable, and polyvinyl alcohols, and polyamide resins are further preferable.

The hydrophilic polymer is particularly preferably a polymer selected from polyvinyl alcohol (PVA) and a derivative thereof, from a viewpoint of film forming property, and resistance to a UV ink.

PVA and a derivative thereof in the invention include copolymers and polymers containing 0.1 mol % or more but 100 mol % or less, preferably 1 mol % or more but 98 mol % or less, further preferably 5 mol % or more but 95 mol % or less of the hydroxyethylene unit, and modified products thereof.

A monomer for forming a copolymer together with a vinyl alcohol structural unit may be arbitrarily selected from the known copolymerizable monomers.

Among PVA and its derivative, particularly preferably, PVA and vinyl alcohol/vinyl acetate copolymers (partially saponified polyvinyl alcohol) may be exemplified, which also include modified products thereof.

As the hydrophilic polymer, particularly, one or more kinds selected from PVA and its derivative, and a hydrophilic polymer not containing a hydroxyethylene unit (hereinafter, conveniently also referred to as “non-PVA derivative”) may be used together.

As a method of synthesizing the hydrophilic polyamide, the following is exemplified.

By reacting ε-caprolactam and/or adipic acid with polyethylene glycol having both terminals modified with amine, polyamide having a polyethylene glycol unit is obtained and, by reacting with piperazine, hydrophilic polyamide having a piperazine skeleton is obtained. And, by reacting an amido group of the hydrophilic polyamide and an epoxy group of glycidyl methacrylate, hydrophilic polyamide in which a crosslinking functional group is introduced into a polymer is obtained. These non-PVA derivatives may be used alone, or plural kinds may be used by mixing them.

Examples of the PVA derivative include a polymer in which at least a part of hydroxy groups of hydroxyethylene units is modified to have a carboxyl group, a polymer in which a part of the hydroxy groups is modified to have a (meth)acroyl group, a polymer in which at least a part of the hydroxy groups is modified to have an amino group, and a polymer in which ethylene glycol or propylene glycol or a multimer thereof is introduced to at least a part of the hydroxy groups.

A polymer in which at least a part of hydroxy groups is modified to have a carboxyl group may be obtained by esterifying polyvinyl alcohol or partially saponified polyvinyl alcohol with polyfunctional carboxylic acid such as succinic acid, maleic acid and adipic acid. An amount of a carboxyl group to be introduced in the polymer is preferably 0.01 mol to 1.00 mol, further preferably 0.05 mol to 0.80 mol relative to 1 mol of a hydroxy group.

A polymer in which at least a part of hydroxy groups is modified to have a (meth)acroyl group may be obtained by adding glycidyl(meth)acrylate to the carboxyl group-modified polymer, or esterifying polyvinyl alcohol or partially saponified polyvinyl alcohol with (meth)acrylic acid. An amount of a (meth)acroyl group to be introduced in the polymer is preferably 0.01 mol to 1.00 mol, further preferably 0.03 mol to 0.50 mol relative to 1 mol of a hydroxy group. The expression of (meth)acroyl group means an acroyl group and/or methacroyl group. The expression of (meth)acrylate means acrylate and/or methacrylate. In addition, this is the case in (meth)acrylic acid.

A polymer in which at least a part of hydroxy groups is modified to have an amino group may be obtained by esterifying polyvinyl alcohol or partially saponified polyvinyl alcohol with carboxylic acid containing an amino group such as carbamic acid. An amount of an amino group to be introduced in the polymer is preferably 0.01 mol to 1.00 mol, further preferably 0.05 mol to 0.70 mol relative to 1 mol of the hydroxy group.

A polymer in which ethylene glycol or propylene glycol or a multimer thereof is introduced to at least a part of hydroxy groups may be obtained by heating polyvinyl alcohol or partially saponified polyvinyl alcohol and glycols in the presence of a sulfuric acid catalyst, and removing water as a byproduct to the outside of the reaction system. A total amount of ethylene glycol or propylene glycol or a multimer thereof to be introduced in the polymer is preferably 0.01 mol to 0.90 mol, further preferably 0.03 mol to 0.50 mol relative to 1 mol of a hydroxy group.

Among modified products of PVA derivatives, a polymer in which at least a part of hydroxy groups is modified to have a (meth)acroyl group is particularly preferably used. This is because, by directly introducing an unreacted crosslinking functional group into the hydrophilic polymer, a strength of a crosslinked material when the relief forming layer is crosslinked may be enhanced without using a large amount of the sulfur-containing polyfunctional monomer, and both of softness and a strength of the crosslinked material may be realized. That is, in this embodiment, both of softness and a strength may be realized in the relief forming layer of the relief printing plate precursor of the invention.

The non-PVA derivatives mean those having so similar polarity as to have compatibility with PVA and a derivative thereof.

Examples of the non-PVA derivative include hydrophilic polyamide in which a hydrophilic group such as polyethylene glycol and piperazine is introduced into a non-water-soluble polyamide obtained by polymerization of adipic acid and 1,6-hexanediamine, or ε-caprolactam only. Since the hydrophilic polyamide exhibits compatibility with the PVA derivative due to working of its hydrophilic group, it is suitable for use as the non-PVA derivative. That is, since such a hydrophilic polyamide has good compatibility with PVA and a derivative thereof, and easily enters between molecules of PVA and a derivative thereof, an intermolecular force of two kinds of polymers is reduced, and the polymer is softened.

—Alcoholphilic Polymer—

As the alcoholphilic polymer in the invention, it is preferable to use a polymer which is water-insoluble but is soluble in an alcohol having 1 to 4 carbon atoms (hereinafter, referred to as specified alcoholphilic polymer).

The specified alcoholphilic polymer related to the invention has the property that it is highly polar, but is water-insoluble, and since it has this property, when this is applied to the relief forming layer, both of aqueous ink suitability and UV ink suitability may be attained.

Herein, hereinafter, the alcohol having 1 to 4 carbon atoms is referred to as lower alcohol in some cases.

Herein, in the invention, the term “insoluble” in a predetermined liquid refers to that when 0.1 g of a binder polymer and 2 ml of a predetermined liquid (e.g. water or organic solvent) are mixed, sealed, allowed to stand at room temperature for 24 hours, and observed visually, precipitation of the binder polymer is recognized, or precipitation is not recognized but the solution (dispersion) is cloudy. The term “soluble” refers to the case where, under the above condition, when observed visually, there is no precipitate, and a transparent and uniform state is given.

The specified alcoholphilic polymer in the invention is required to be soluble in an alcohol having 1 to 4 carbon atoms. Herein, examples of the alcohol having 1 to 4 carbon atoms include methanol, ethanol, 2-propanol, 1-propanol, 1-methoxy-2-propanol, 1-butanol, and tert-butanol from a viewpoint of good UV ink suitability, and it is preferable that the polymer is soluble in at least any of them.

More preferably, as the specified alcoholphilic polymer, a polymer which is soluble in any of methanol, ethanol, 2-propanol, and 1-methoxy-2-propanol is preferable, and a polymer which is soluble in all of methanol, ethanol, and 1-methoxy-2-propanol is particularly preferable.

It is preferable that the specified alcoholphilic polymer in the invention is insoluble in an ester solvent, a representative of which is ethyl acetate. By selecting a polymer which is insoluble in the ester solvent, UV ink suitability is further improved, and reduction in a film strength due to swelling during printing with a UV ink, and elution of a low-molecular component from a relief layer may be effectively suppressed.

When the specified alcoholphilic polymer is a substance having a glass transition temperature, the glass transition temperature is preferably from 20° C. to 200° C., more preferably from 20° C. to 170° C., particularly preferably from 25° C. to 150° C. from a viewpoint of balance between an engraving sensitivity and film forming property.

In the invention, a glass transition temperature (Tg) of room temperature or higher refers to a Tg of 20° C. or higher.

In the case where the specified alcoholphilic polymer which may be used in the invention has the above range of the glass transition temperature, when the polymer is combined with (D) a photothermal converting agent described later, which is a preferable additional component for constituting the relief forming layer in the invention, and which may absorb light having a wavelength of 700 nm to 1300 nm, an engraving sensitivity is improved. The binder polymer having such a glass transition temperature is referred to as “non-elastomer”, hereinafter.

That is, the elastomer is generally academically defined as a polymer having a glass transition temperature of a normal temperature or lower (see Kagaku Daijiten second edition, edited by Foundation for Advancement of International Science, published by Maruzen, P154). Therefore, the non-elastomer refers to a polymer having a glass transition temperature higher than a normal temperature.

When a glass transition temperature of the specified alcoholphilic polymer is room temperature (20° C.) or higher, since the polymer has a glass state at a normal temperature, the polymer is in the state where thermal molecular movement is considerably suppressed as compared with the case where the polymer has a rubber state.

In laser engraving on the relief printing plate precursor of the invention, at laser irradiation (preferably, at infrared laser irradiation), applied heat and heat produced by the function of (D) a photothermal converting agent optionally used are transmitted to the specified alcoholphilic polymer present at the periphery, and this is thermally decomposed and dissipated and, as a result, engraved to form a concave portion.

In a preferable embodiment of the invention, it is thought that when the (D) photothermal converting agent is present in the state where thermal molecular movement of the specified alcoholphilic polymer is suppressed, heat transmission to, and thermal decomposition of the specified alcoholphilic polymer effectively occur, and it is presumed that an engraving sensitivity has been further increased due to such an effect.

On the other hand, in the state (rubber state) where the glass transition temperature is lower than room temperature and thermal molecular movement of the specified alcoholphilic polymer is not suppressed, since due to an intensity of its vibration, that is, thermal molecular movement, an intermolecular distance between the (D) photothermal converting agent and the specified alcoholphilic polymer becomes great, and a volume (space) present between them becomes very great, it is presumed that not only an efficacy of heat transmission from the (D) photothermal converting agent to the specified alcoholphilic polymer is reduced, but also the transmitted heat contributes to active thermal movement, heat loss is generated, and contribution to occurrence of effective thermal decomposition is decreased, and thereby, it is difficult to contribute to improvement in an engraving sensitivity.

From the foregoing, examples of a non-elastomer which is a particularly preferable embodiment of the specified alcoholphilic polymer preferably used in the invention are as follows.

Examples of the particularly preferable specified alcoholphilic polymer in the invention, from a viewpoint of that both of aqueous ink suitability and UV ink suitability are realized, and an engraving sensitivity is high, and film forming property is also good, include a polyvinyl butyral (PVB) derivative, a polyamide, a cellulose derivative, and an epoxy resin and, among them, a polyvinyl butyral (PVB) derivative, a polyamide, and a cellulose derivative are preferable.

### (1) Polyvinyl Butyral and Derivative Thereof

As polyvinyl butyral (hereinafter, referred to as PVB), a homopolymer may be used, or a polyvinyl butyral derivative may be used.

A content of butyral in the PVB derivative (total mole number of raw material monomer is 100%) is preferably 30% to 90%, more preferably 50% to 85%, particularly preferably 55% to 78%.

From a viewpoint that balance between an engraving sensitivity and film forming property is retained, a weight average molecular weight of PVB and a derivative thereof is preferably 5000 to 800000, more preferably 8000 to 500000. Further, from a viewpoint of improvement in the rinsing property of an engraving waste, 50000 to 300000 is particularly preferable.

PVB and a derivative thereof are also available as a commercialized product, and preferable examples, from a viewpoint of alcohol solubility (particularly, ethanol), include “ESLEC B” Series, “ESLEC K (KS)” Series manufactured by Sekisui Chemical Co., Ltd., and “Denka Butyral” manufactured by Denki Kagaku Kogyo K.K. From a viewpoint of alcohol solubility (particularly ethanol), further preferable are “ESLEC B” Series manufactured by Sekisui Chemical Co., Ltd. and “Denka Butyral” manufactured by Denki Kagaku Kogyo K.K., and particularly preferable are “BL-1”, “BL-1H”, “BL-2”, “BL-5”, “BL-S”, “BX-L”, “BM-S”, “BH-S” in “ESLEC B” Series manufactured by Sekisui Chemical Co., Ltd., and “#3000-1”, “#3000-2”, “#3000-4”, “#4000-2”, “#6000-C”, “#6000-EP”, “#6000-CS”, “#6000-AS” in “Denka Butyral” manufactured by Denki Kagaku Kogyo K.K.

When a film of the relief forming layer is made using PVB as the specified alcoholphilic polymer, a method of casting and drying a solution of the polymer dissolved in a solvent is preferable from a viewpoint of smoothness of a surface of a film.

### (2) Alcohol-Soluble Polyamide

Since a polyamide in which a polar group such as polyethylene glycol and piperazine is introduced into a main chain improves alcohol solubility due to working of the polar group, it is suitable as the specified alcoholphilic polymer used in the invention.

By reacting ε-caprolactam and/or adipic acid with polyethylene glycol having both terminals modified with amine, a polyamide having a polyethylene glycol unit (also called polyethylene oxide segment) is obtained and, by reacting this with piperazine, a polyamide having a piperazine skeleton is obtained.

As a polyamide containing a polyethylene glycol unit, usually, polyether amide obtained by polycondensing or copolycondensing α,ω-diaminoproplypolyoxyethylene as at least a part of a raw material diamine component by the known method (e.g. JP-A No. 55-79437), or polyether ester amide obtained by polycondensing or copolycondensing polyethylene glycol as at least a part of a raw material diol component by the known method (e.g. JP-A No. 50-159586) is used without any limitation, and a polymer having an amide bond in a main chain may be widely used.

Herein, a number average molecular weight of the polyethylene oxide segment in a polyamide is preferably in the range of 150 to 5000, more preferably in the range of 200 to 3000 from a viewpoint of the form retainability of the relief forming layer. A number average molecular weight of these polyamides having the polyethylene oxide segment is preferably in the range of 5000 to 300000, further preferably in the range of 10000 to 200000, particularly preferably in the range of 10000 to 50000.

As the polyamide, a polyamide having a highly polar unit such as polyethylene oxide in a main chain is preferably used, but since even when a side chain of a polyamide has a highly polar functional group, the same function may be obtained, a polyamide having a polar group in a side chain is also suitable in the specified alcoholphilic polymer in the invention.

From a viewpoint of an engraving sensitivity, more preferable is the case where a side chain of a polyamide has a highly polar functional group.

As such a polyamide, specifically, methoxymethylated polyamide, and methoxymethylated nylon are preferable. As a commercialized product of such a polyamide derivative, a methoxymethylated polyamide “TORESIN” Series manufactured by Nagase Chemtex is preferable. Particularly preferable is a methoxymethylated polyamide “TORESIN F-30K”, and “TORESIN EF-30T” manufactured by Nagase Chemitex.

### (3) Cellulose Derivative

Usual cellulose is hardly dissolved in water and an alcohol, but water- or solvent-solubility may be controlled by modifying remaining OH of a glucopyranose unit with a specified functional group, and a cellulose derivative which is thus insoluble in water, but is made to be soluble in an alcohol having 1 to 4 carbon atoms is also suitable as the specified alcoholphilic polymer used in the invention.

Examples of the cellulose derivative suitable in the invention include alkylcellulose such as ethylcellulose and methylcellulose, hydroxyethylenecellulose, hydroxypropylenecellulose, and cellulose acetate butyrate, which have physical property of being water-insoluble and lower alcohol-soluble.

Further, specific examples include Metholose Series manufactured by Shin-Etsu Chemical Co., Ltd. This series is such that a part of a hydrogen atom of a hydroxy group of cellulose is replaced with a methyl group (—CH₃), a hydroxypropyl group (—CH₂CHOHCH₃), or a hydroxyethyl group (—CH₂CH₂OH).

In addition, in the invention, particularly preferable in solubility in a lower alcohol and an engraving sensitivity is alkylcellulose, inter alia, ethylcellulose and methylcellulose.

### (4) Epoxy Resin

As a water-insoluble and alcohol-soluble epoxy resin which may be used in the invention, a modified epoxy resin in which a bisphenol A-type epoxy resin or a bisphenol A-type epoxy resin is high-molecularized or highly functionalized with a modifying agent is preferable from a viewpoint of water-insolubility. Particularly preferable is a modified epoxy resin.

Preferable examples of the modified epoxy resin include “Arakyd 9201N”, “Arakyd 9203N”, “Arakyd 9205”, “Arakyd 9208”, “KA-1439A”, “MODEPICS 401”, and “MODEPICS 402” manufactured by Arakawa Chemical Industries Ltd.

As the specified alcoholphilic polymer in the invention, an acryl resin and polyurethane as shown below may be preferably used as far as they are water-insoluble and lower alcohol-soluble.

### (5) Acryl Resin

As the specified alcoholphilic polymer in the invention, a water-insoluble and lower alcohol-soluble acryl resin may be also used.

As such an acryl resin, an acryl resin obtained by using the known acryl monomer, solubility of which has been controlled so as to satisfy the aforementioned physical conditions, may be used. As an acryl monomer used in synthesizing an acryl resin, for example, (meth)acrylic acid esters, and crotonic acid esters, (meth)acrylamides are preferable. Examples of such a monomer include the following compounds.

That is, examples of (meth)acrylic acid esters include methyl(meth)acrylate, ethyl (meth)acrylate, n-propyl(meth)acrylate, isopropyl(meth)acrylate, n-butyl(meth)acrylate, isobutyl(meth)acrylate, tert-butyl(meth)acrylate, n-hexyl(meth)acrylate, 2-ethylhexyl (meth)acrylate, acetoxyethyl(meth)acrylate, phenyl(meth)acrylate, 2-hydroxyethyl (meth)acrylate, 2-hydroxypropyl(meth)acrylate, 4-hydroxybutyl(meth)acrylate, 2-methoxyethyl(meth)acrylate, 2-ethoxyethyl(meth)acrylate, 2-(2-methoxyethoxy)ethyl (meth)acrylate, cyclohexyl(meth)acrylate, benzyl(meth)acrylate, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acrylate, polyethylene glycol monomethyl ether (meth)acrylate, polypropylene glycol monomethyl ether (meth)acrylate, monomethyl ether (meth)acrylate of a copolymer of ethylene glycol and propylene glycol, N,N-dimethylaminoethyl (meth)acrylate, N,N-diethylaminoethyl(meth)acrylate, and N,N-dimethylaminopropyl (meth)acrylate.

From a viewpoint of alcohol solubility, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acrylate, polyethylene glycol monomethyl ether (meth)acrylate, polypropylene glycol monomethyl ether (meth)acrylate, and monomethyl ether (meth)acrylate of a copolymer of ethylene glycol and propylene glycol are preferable.

Examples of crotonic acid esters include butyl crotonate, and hexyl crotonate.

Examples of (meth)acrylamides include (meth)acrylamide, N-methyl(meth)acrylamide, N-ethyl(meth)acrylamide, N-propyl(meth)acrylamide, N-n-butyl(meth)acrylamide, N-tert-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-benzyl(meth)acrylamide, and (meth)acryloylmorpholine.

As the acryl resin, a modified acryl resin containing an acryl monomer having a urethane group or a urea group may be also preferably used.

Examples of an acryl monomer used in synthesis of an acryl resin used as the specified alcoholphilic polymer in the invention include compounds such as the following exemplified monomers (AM-1) to (AM-22).

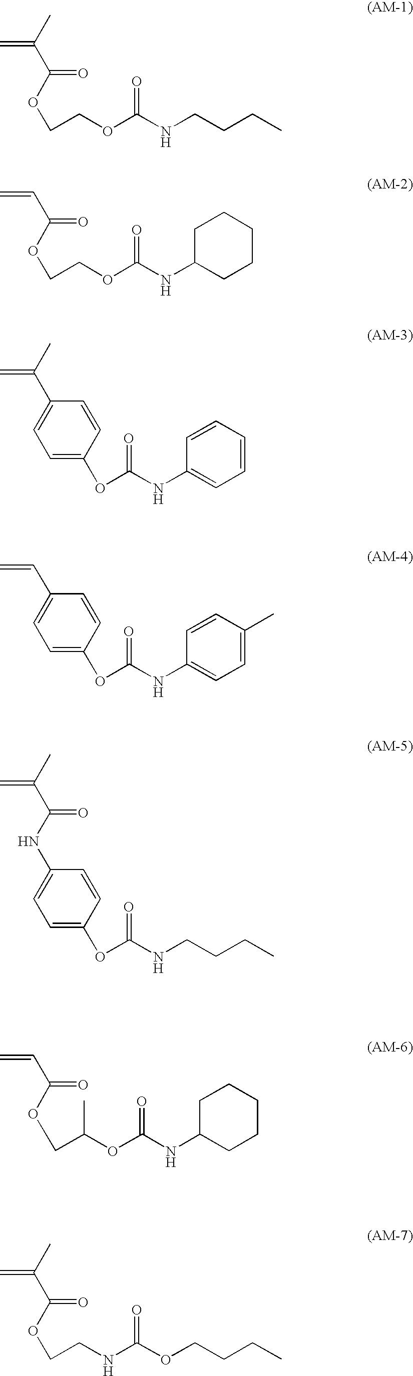

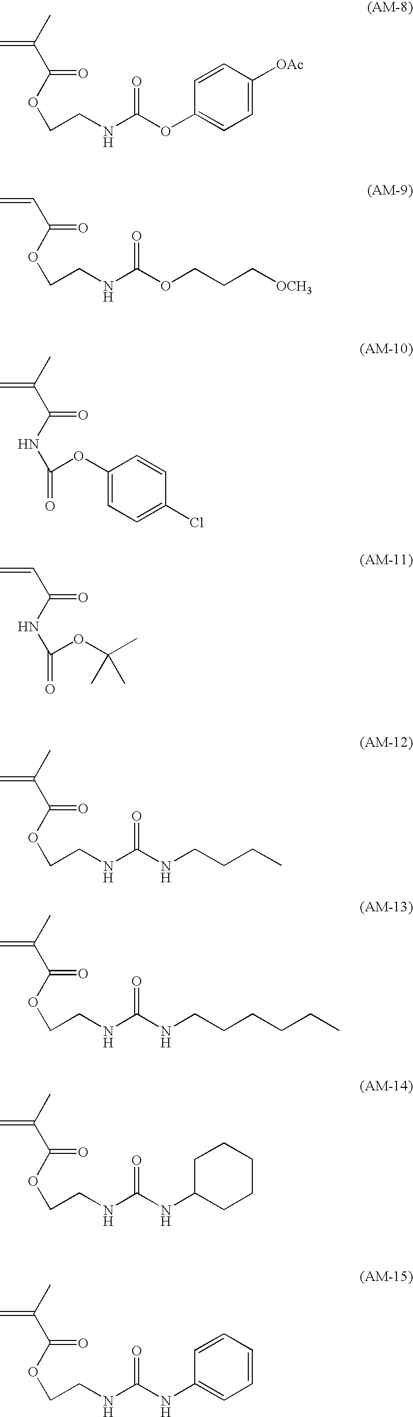

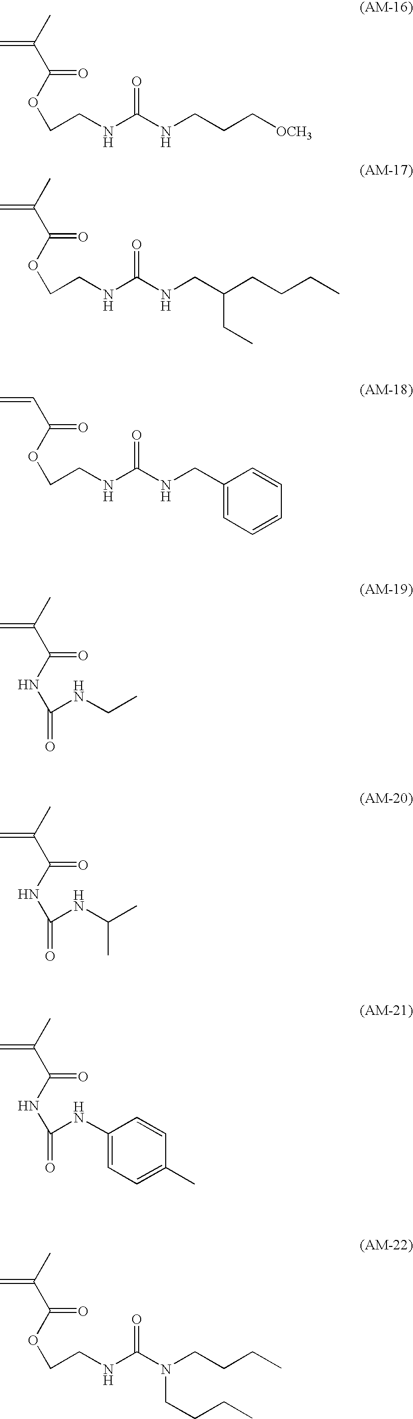

Examples of the acryl resin which may be suitably used as the specified alcoholphilic polymer in the invention are shown below together with a weight average molecular weight measured by the GPC method [described as Mw (GPC)], but the acryl resin which may be used in the invention is not limited to them as far as it has the aforementioned preferable properties.

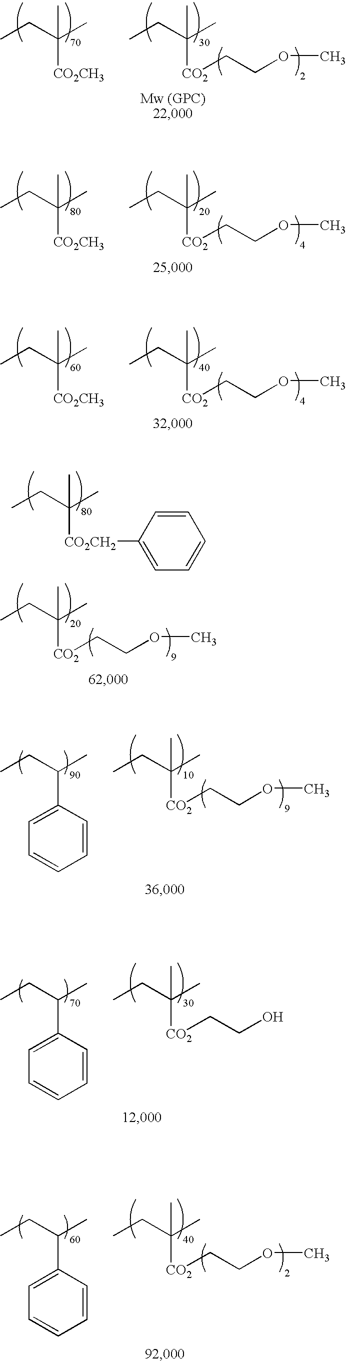

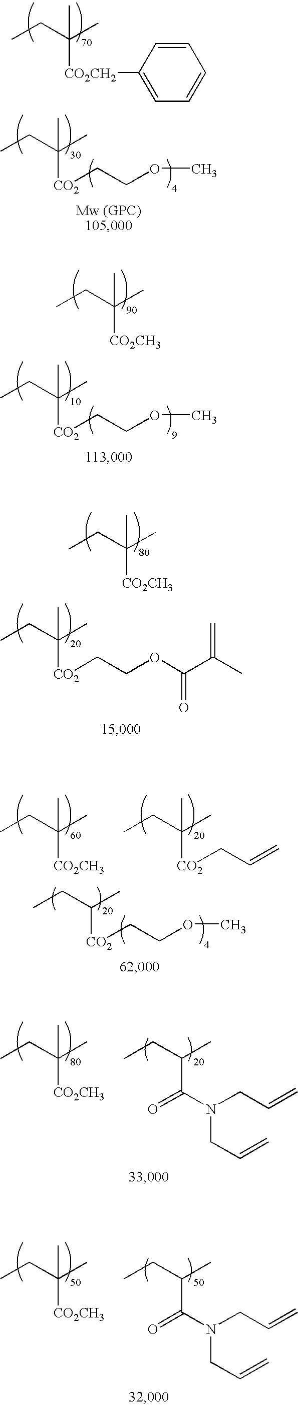

### (6) Polyurethane Resin

As the specified alcoholphilic polymer in the invention, a water-insoluble and lower alcohol-soluble polyurethane resin may be also used.

A polyurethane resin which may be used as the specified alcoholphilic polymer in the invention is a polyurethane resin having, as a fundamental skeleton, a structural unit which is a reaction product of at least one kind of a diisocyanate compound represented by the following formula (U-1), and at least one kind of a diol compound represented by the following formula (U-2).

OCN—X⁰—NCO (U-1)

HO—Y⁰—OH (U-2)

In the formulas (U-1) and (U-2), X⁰ and Y⁰ each represent independently a divalent organic residue, provided that at least one of organic residues represented by X⁰ and Y⁰ is linked to a NCO group or an OH group through an aromatic group.

—Diisocyanate Compound—

It is preferable that in a diisocyanate compound represented by the formula (U-1), an organic residue represented by X⁰ contains, in a structure, an aromatic group directly linked to a NCO group.

A preferable diisocyanate compound is a diisocyanate compound represented by the following formula (U-3).

OCN-L¹-NCO (U-3)

In the formula (U-3), L¹ represents a divalent aromatic hydrocarbon group optionally having a substituent. Examples of the substituent include an alkyl group, an aralkyl group, an aryl group, an alkoxy group, an aryloxy group, and a halogen atom (—F, —Cl, —Br, —I). If necessary, L¹ may have other functional group which does not react with an isocyanate group, for example, an ester group, a urethane group, an amido group, and a ureido group.

Examples of the diisocyanate compound represented by the formula (U-3) include the following compounds.

That is, examples of the aromatic diisocyanate compound include 2,4-tolylene diisocyanate, 2,4-tolylene diisocyanate dimer, 2,6-tolylenedilene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate.

Particularly, from a viewpoint of thermal decomposability, 4,4′-diphenylmethane diisocyanate, and 1,5-naphthylene diisocyanate are preferable.

The polyurethane resin used as the specified alcoholphilic polymer in the invention may be a polymer synthesized by using a diisocyanate compound other than the aforementioned diisocyanate compounds, for example, from a viewpoint that compatibility with other components in the relief forming layer is improved, and storage stability is improved.

Examples of the diisocyanate compound which may be used together include aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylene bis(cyclohexylisocyanate), methylcyclohexane-2,4 (or 2,6) diisocyanate, 1,3-(isocyanatemethyl)cyclohexane; and diisocyanate compounds which are a reaction product of diol and diisocyanate, such as an adduct of 1 mol of 1,3-butylene glycol and 2 mol of tolylene diisocyanete.

Diisocyanate obtained by adding a monofunctional alcohol to one of three NCOs of triisocyanate may be also used.

—Diol Compound—

It is preferable that in the diol compound represented by the formula (U-2), an organic residue represented by Y° contains, in a structure, an aromatic group directly linked to an OH group.

More specifically, diol compounds represented by the following formulas (A-1) to (A-3) are preferable.

HO—Ar¹—OH Formula (A-1)

HO—(Ar¹—Ar²)ₘ—OH Formula (A-2)

HO—Ar¹—X—Ar²—OH Formula (A-3)

In the formulas (A-1) to (A-3), Ar¹ and Ar² may be the same or different, and each represent an aromatic ring. Examples of such an aromatic ring include a benzene ring, a naphthalene ring, an anthracene ring, a pyrene ring, and a heterocyclic ring. These aromatic rings may have a substituent. Examples of the substituent include an alkyl group, an aralkyl group, an aryl group, an alkoxy group, an aryloxy group, and a halogen atom (—F, —Cl, —Br, —I).

From a viewpoint of easy availability of a raw material, preferable is a benzene ring and a naphthalene ring. Also in view of film forming property, a benzene ring is particularly preferable.

X is a divalent organic residue. And, m is preferably 1 to 3, particularly preferably 1, from a viewpoint of film forming property.

Preferable examples of the diol compound represented by the formula (A-1) are 1,4-dihydroxybenzene, and 1,8-dihydroxynaphthalene.

Preferable examples of the diol compound represented by the formula (A-2) are 4,4-dihydroxybiphenyl, and 2,2-hydroxybinaphthyl.

Preferable examples of the diol compound represented by the formula (A-3) are bisphenol A, and 4,4-bis(hydroxyphenyl)methane.

The polyurethane resin used as the specified alcoholphilic polymer in the invention may be a polymer synthesized by using an additional diol compound other than the aforementioned diol compounds, for example, from a viewpoint that compatibility with other components in the relief forming layer is improved, and storage stability is improved.

Examples of the diol compound which may be used together include a polyether diol compound, a polyester diol compound, and a polycarbonate diol compound.

Examples of the polyether diol compound include compounds represented by the following formulas (U-4), (U-5), (U-6), (U-7), and (U-8), and a random copolymer of ethylene oxide and propylene oxide having hydroxyl groups at the terminal positions.

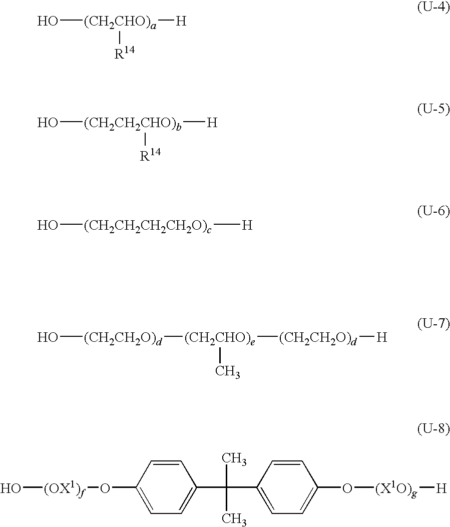

In the formulas (U-4) to (U-8), R¹⁴ represents a hydrogen atom or a methyl group, and X¹ represents the following groups. And, a, b, c, d, e, f, and g each indicate independently an integer of 2 or more, preferably an integer of 2 to 100.

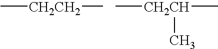

Examples of the polyether diol compounds represented by the formulas (U-4) and (U-5) include the following compounds.

That is, examples include diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having a weight average molecular weight of 1000, polyethylene glycol having a weight average molecular weight of 1500, polyethylene glycol having a weight average molecular weight of 2000, polyethylene glycol having a weight average molecular weight of 3000, polyethylene glycol having a weight average molecular weight of 7500, polypropylene glycol having a weight average molecular weight of 400, polypropylene glycol having a weight average molecular weight of 700, polypropylene glycol having a weight average molecular weight of 1000, polypropylene glycol having a weight average molecular weight of 2000, polypropylene glycol having a weight average molecular weight of 3000, and polypropylene glycol having a weight average molecular weight of 4000.

Examples of the polyether diol compound represented by the formula (U-6) include the following compounds.

That is, examples include PTMG650, PTMG1000, PTMG2000, and PTMG3000 (trade name) manufactured by Sanyo Chemical Industries, Ltd.

Further, examples of the polyether diol compound represented by the formula (U-7) include the following compounds.

That is, examples include New Pole PE-61, New Pole PE-62, New Pole PE-64, New Pole PE-68, New Pole PE-71, New Pole PE-74, New Pole PE-75, New Pole PE-78, New Pole PE-108, New Pole PE-128, New Pole PE-61 (trade name) manufactured by Sanyo Chemical Industries, Ltd.

Examples of the polyether diol compound represented by the formula (U-8) include the following compounds.

That is, examples include New Pole BPE-20, New Pole BPE-20F, New Pole BPE-20NK, New Pole BPE-20T, New Pole BPE-20G, New Pole BPE-40, New Pole BPE-60, New Pole BPE-100, New Pole BPE-180, New Pole BPE-2P, New Pole BPE-23P, New Pole BPE-3P, and New Pole BPE-5P (trade name) manufactured by Sanyo Chemical Industries, Ltd.

Examples of the random copolymer of ethylene oxide and propylene oxide having hydroxy groups at the terminal positions include the following copolymers.

That is, examples include New Pole 50HB-100, New Pole 50HB-260, New Pole 50HB-400, New Pole 50HB-660, New Pole 50HB-2000, and New Pole 50HB-5100 (trade name) manufactured by Sanyo Chemical Industries, Ltd.

Examples of the polyester diol compound include compounds represented by the following formulas (U-9), and (U-10).

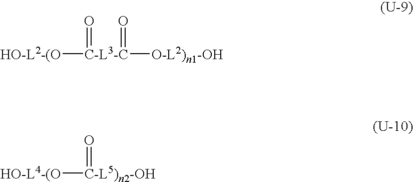

In the formulas (U-9) and (U-10), L², L³, and L⁴ may be the same or different, and each represent a divalent aliphatic or aromatic hydrocarbon group, and L⁵ represents a divalent aliphatic hydrocarbon group. Preferably, L² to L⁴ each represent independently an alkylene group, an alkenylene group, an alkynylene group, or an allylene group, and L⁵ represents an alkylene group. In L² to L⁵, other functional group which does not react with an isocyanate group, for example, an ether group, a carbonyl group, an ester group, a cyano group, an olefin group, a urethane group, an amido group, a ureido group, or a halogen atom may be present. And, n1 and n2 are an integer of 2 or more, respectively, preferably represent an integer of 2 to 100.

Examples of the polycarbonate diol compound include a compound represented by the formula (U-11).

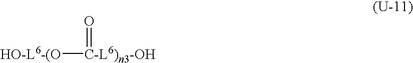

In the formula (U-11), two L⁶s may be the same or different, and each represent a divalent aliphatic or aromatic hydrocarbon group. Preferably, L⁶ represents an alkylene group, an alkenylene group, an alkynylene group, or an arylene group. In L⁶, other functional group which does not react with an isocyanate group, for example, an ether group, a carbonyl group, an ester group, a cyano group, an olefin group, a urethane group, an amido group, a ureido group, or a halogen atom may be present. And, n3 is an integer of 2 or more, preferably represents an integer of 2 to 100.

Examples of the diol compounds represented by the formula (U-9), (U-10), or (U-11) include the following compounds [exemplified compounds (No. 1) to (No. 18)]. In examples, n represents an integer of 2 or more.

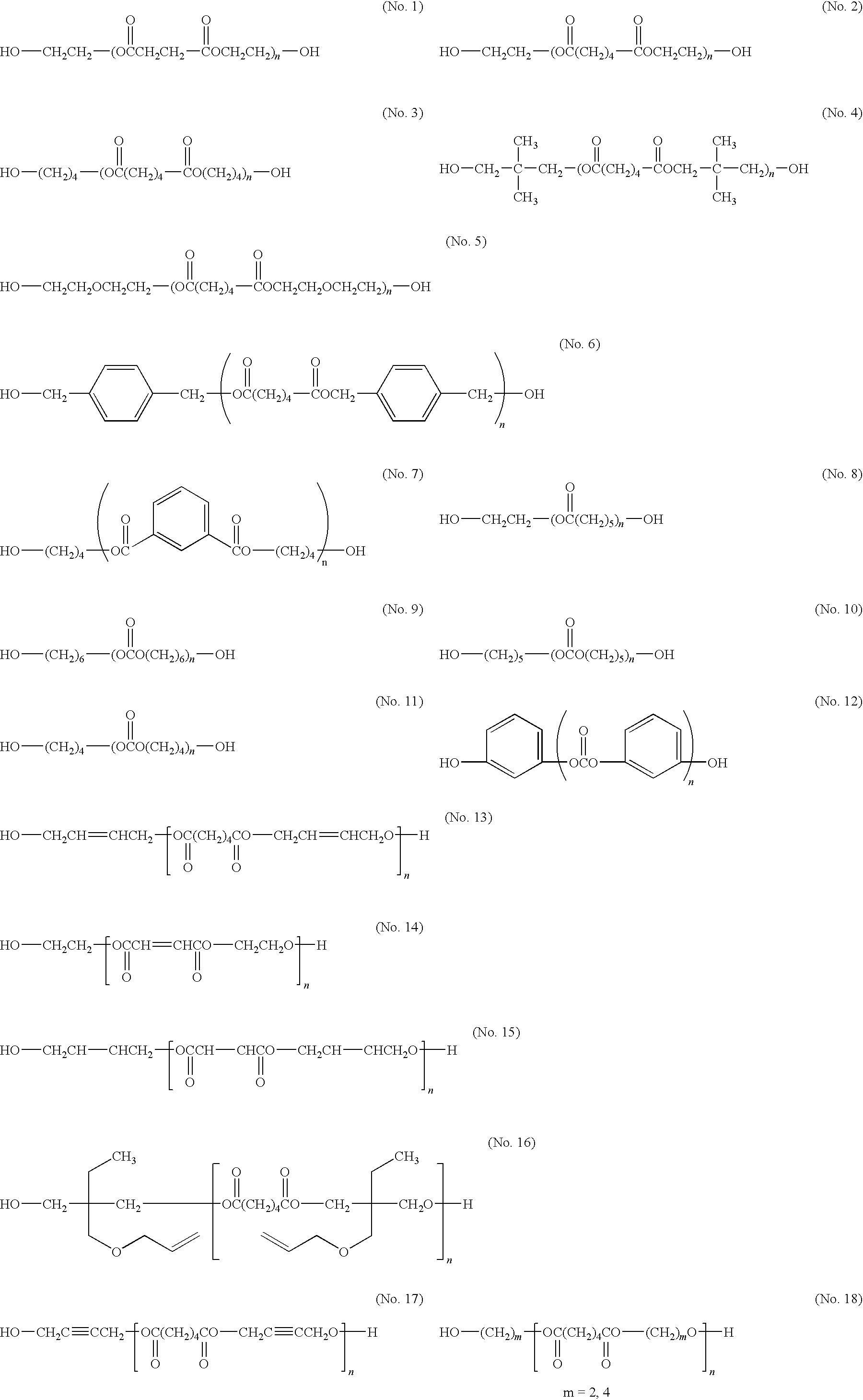

In addition, for synthesizing a polyurethane resin used as the specified alcoholphilic polymer, in addition to the aforementioned diol compounds, a diol compound having a substituent which does not react with an isocyanate group may be used together. Examples of such a diol compound include the following compounds.

That is, for example, compounds represented by the following formulas (U-12), and (U-13) are used.

HO-L⁷-O—CO-L⁸-CO—O-L⁷-OH (U-12)

HO-L⁸-CO—O-L⁷-OH (U-13)

In the formulas (U-12) and (U-13), L⁷ and L⁸ may be the same or different, and each represent a divalent aliphatic hydrocarbon group, aromatic hydrocarbon group or heterocyclic group, each optionally having a substituent (e.g. alkyl group, aralkyl group, aryl group, alkoxy group, aryloxy group, halogen atom (—F, —Cl, —Br, —I) etc.). If necessary, L⁷ and L⁸ may have other functional group which does not react with an isocyanate group, for example, a carbonyl group, an ester group, a urethane group, an amido group, and a ureido group. L⁷ and L⁸ may form a ring.

Further, for synthesizing a polyurethane resin used as the specified alcoholphilic polymer, a diol compound having an acid group such as a carboxyl group, a sulfone group, and a phosphoric acid group may be used together. Particularly, a diol compound having a carboxyl group is preferable from a viewpoint of improvement in a film strength, and water resistance due to a hydrogen bond.

Examples of the diol compound having a carboxyl group include, for example, compounds represented by the following formulas (U-14) to (U-16).

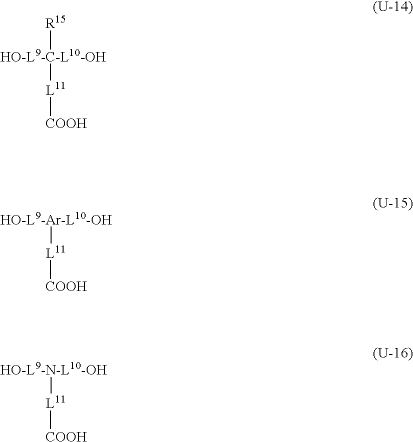

In the formulas (U-14) to (U-16), R¹⁵ represents a hydrogen atom, an alkyl group optionally having a substituent [e.g. cyano group, nitro group, halogen atom such as —F, —Cl, —Br, —I etc., —CONH₂, —COOR¹⁶, —OR¹⁶, —NHCONHR¹⁶, —NHCOOR¹⁶, —NHCOR¹⁶, —OCONHR¹⁶ (wherein R¹⁶ represents an alkyl group having 1 to 10 carbon atoms, or an aralkyl group having 7 to 15 carbon atoms) etc.], an aralkyl group, an aryl group, an alkoxy group, or an aryloxy group, preferably represents a hydrogen atom, an alkyl group having 1 to 8 carbon atoms, or an aryl group having 6 to 15 carbon atoms. L⁹, L¹⁰ and L¹¹ may be the same or different, and represent a single bond, or a divalent aliphatic or aromatic hydrocarbon group optionally having a substituent (for example, each group of alkyl, aralkyl, aryl, alkoxy, and halogeno is preferable), preferably represent an alkylene group having 1 to 20 carbon atoms, an arylene group having 6 to 15 carbon atoms, and further preferably represent an alkylene group having 1 to 8 carbon atoms. If necessary, L⁹ to L¹¹ may have other functional group which does not react with an isocyanate group, for example, a carbonyl group, an ester group, a urethane group, an amido group, a ureido group, or an ether group. Two or three of R¹⁵, L⁷, L⁸ and L⁹ may form a ring.

Ar represents a trivalent aromatic hydrocarbon group optionally having a substituent, and preferably represents an aromatic group having 6 to 15 carbon atoms.

Examples of the diol compounds having a carboxyl group represented by the formulas (U-14) to (U-16) include the following compounds.

That is, examples of the diol compounds include 3,5-dihydroxybenzoic acid, 2,2-bis(hydroxymethyl)propionic acid, 2,2-bis(2-hydroxyethyl)propionic acid, 2,2-bis(3-hydroxypropyl)propionic aid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, and N,N-bis(2-hydroxyethyl)-3-carboxy-propionamide.

In addition, for synthesizing a polyurethane resin used as the specified alcoholphilic polymer, compounds obtained by ring-opening of tetracarboxylic acid dianhydrides represented by the following formulas (U-17) to (U-19) with a diol compound may be used together.

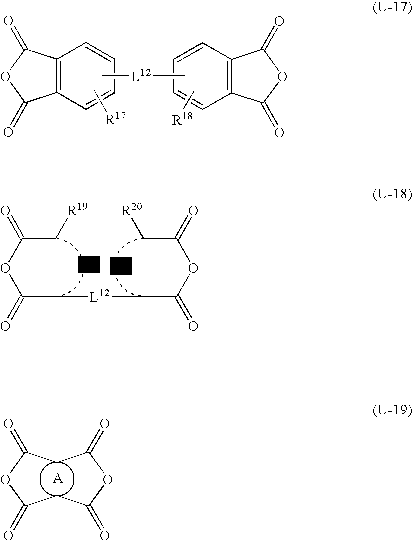

In the formulas (U-17) to (U-19), L¹² represents a single bond, a divalent aliphatic or aromatic hydrocarbon group optionally having a substituent (e.g. alkyl group, aralkyl group, aryl group, alkoxy group, halogeno group, ester group, and amido group are preferable), —CO—, —SO—, —SO₂—, —O—, or —S—, and preferably represents a single bond, a divalent aliphatic hydrocarbon group having 1 to 15 carbon atoms, —CO—, —SO₂—, —O—, or —S—. R¹⁷ and R¹⁸ may be the same or different, and represent a hydrogen atom, an alkyl group, an aralkyl group, an aryl group, an alkoxy group, or a halogeno group, and preferably represent a hydrogen atom, an alkyl group having 1 to 8 carbon atoms, an aryl group having 6 to 15 carbon atoms, an alkoxy group having 1 to 8 carbon atoms, or a halogeno group. Two of L¹², R¹⁷ and R¹⁸ may be linked to form a ring. R¹⁹ and R²⁰ may be the same or different, and represent a hydrogen atom, an alkyl group, an aralkyl group, an aryl group, or a halogeno group, and preferably represent a hydrogen atom, an alkyl group having 1 to 8 carbon atoms, or an aryl group having 6 to 15 carbon atoms. Two of L¹², R¹⁹ and R²⁰ may be linked to form a ring. L¹³ and L¹⁴ may be the same or different, and represent a single bond, a double bond, or a divalent aliphatic hydrocarbon group, and preferably represent a single bond, a double bond, or a methylene group. A represents a mononuclear or polynuclear aromatic ring, and preferably represents an aromatic ring having 6 to 18 carbon atoms.

Examples of the compounds represented by the formula (U-17), (U-18), or (U-19) include the following compounds.

That is, examples include aromatic tetracarboxylic dianhydrides such as pyromellitic dianhydride, 3,3′,4,4′-benzophenonetetracarboxylic dianhydride, 3,3′,4,4′-diphenyltetracarboxylic dianhydride, 2,3,6,7-naphthalenetetracarboxylic dianhydride, 1,4,5,8-naphthalenetetracarboxylic dianhydride, 4,4′-sulfonyldiphthalic dianhydride, 2,2-bis(3,4-dicarboxyphenyl)propane dianhydride, bis(3,4-dicarboxyphenyl)ether dianhydride, 4,4′-[3,3′-(alkylphosphoryldiphenylene)-bis(iminocarbonyl)]diphthalic dianhydride, an adduct of hydroquinonediacetate and trimellic anhydride, and an adduct of diacetyldiamine and trimellic anhydride; alicyclic tetracarboxylic dianhydrides such as 5-(2,5-dioxotetrahydrofuryl)-3-methyl-3-cyclohexy-1,2-dicarboxylic anhydride (trade name: EPICHLONE B-4400, manufactured by Dainippon Ink and Chemicals Inc.), 1,2,3,4-cyclopentanetetracarboxylic dianhydride, 1,2,4,5-cyclohexanetetracarboxylic dianhydride, and tetrahydrofurantetracarboxylic dianhydride; and aliphatic tetracarboxylic dianhydrides such as 1,2,3,4-butanetetracarboxylic dianhydride and 1,2,4,5-pentanetetracarboxylic dianhydride.

As a method of introducing a compound obtained by ring-opening of these tetracarboxylic dianhydrides with a diol compound, into a polyurethane resin, for example, there are the following methods.

a) A method of reacting a compound having an alcoholic terminal obtained by ring-opening of a tetracarboxylic dianhydride with a diol compound, and a diisocyanate compound.
b) A method of reacting a urethane compound having an alcoholic terminal obtained by reacting a diisocyanate compound under the condition of an excessive diol compound, and a tetracarboxylic dianhydride.

Examples of the diol compound used in the ring-opening reaction thereupon include the following compounds.

That is, examples include ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohaxanedimethanol, tricyclodecanedimethanol, hydrogenated bisphenol A, hydrogenated bisphenol F, an ethylene oxide adduct of bisphenol A, an propylene oxide adduct of bisphenol A, an ethylene oxide adduct of bisphenol F, a propylene oxide adduct oxide of bisphenol F, an ethylene oxide adduct of hydrogenated bisphenol A, a propylene oxide adduct of hydrogenated bisphenol A, hydroquinonedihydroxyethyl ether, p-xylylene glycol, dihydroxyethylsulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, and bis(2-hydroxyethyl)isophthalate.

—Other Copolymerization Component—

A polyurethane resin used as the specified alcoholphilic polymer in the invention may contain an organic group containing at least one of an ether bond, an amido bond, a urea bond, an ester bond, a urethane bond, a biuret bond, and an allophanate bond as a functional group, in addition to a urethane bond.

It is preferable that a polyurethane resin used as the specified alcoholphilic polymer further has a unit having an ethylenic unsaturated bond. It is preferable that the polyurethane resin having a unit having an ethylenic unsaturated bond has at least one of functional groups represented by the following formulas (E1) to (E3) in a side chain of a polyurethane resin. First, functional groups represented by the following formulas (E1) to (E3) will be explained.

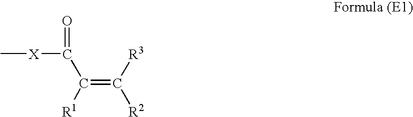

In the formula (E1), R¹ to R³ each represent independently a hydrogen atom or a monovalent organic group. Examples of R¹ include preferably a hydrogen atom, and an alkyl group optionally having a substituent and, among them, a hydrogen atom, and a methyl group are preferable due to high radical reactivity. R² and R³ each represent independently a hydrogen atom, a halogen atom, an amino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxy carbonyl group, an alkyl group optionally having a substituent, and an aryl group optionally having a substituent are preferable due to high radical reactivity.

X represents an oxygen atom, a sulfur atom, or —N(R¹²)—, and R¹² represents a hydrogen atom, or a monovalent organic group. Herein, example of the monovalent organic group include an alkyl group optionally having a substituent. Among them, R¹² is preferably a hydrogen atom, a methyl group, an ethyl group, or an isopropyl group due to high radical reactivity.

Herein, examples of the substituent which may be introduced include an alkyl group, an alkenyl group, an alkynyl group, an aryl group, an alkoxy group, an aryloxy group, a halogen atom, an amino group, an alkyl amino group, an arylamino group, a carboxyl group, an alkoxycarbonyl group, a sulfo group, a nitro group, a cyano group, an amido group, an alkylsulfonyl group, and an arylsulfonyl group.

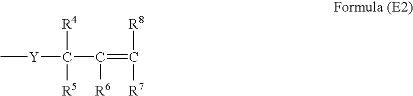

In the formula (E2), R⁴ to R⁸ each represent independently a hydrogen atom or a monovalent organic group. R⁴ to R⁸ preferably represent a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, and an arylsulfonyl group optionally having a substituent and, among them, a hydrogen atom, a carboxyl group, an alkoxycarbonyl group, an alkyl group optionally having a substituent, and an aryl group optionally having a substituent are preferable.

As a group which may be introduced as the substituent, the same substituents as those for the formula (E1) are exemplified. Y represents an oxygen atom, a sulfur atom, or —N(R¹²)—. R¹² has the same meaning as that of R¹² of the formula (E1), and a preferable example is similar.

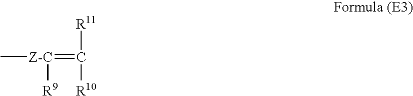

In the formula (E3), R⁹ to R¹¹ each represent independently a hydrogen atom or a monovalent organic group. Examples of R⁹ include preferably a hydrogen atom and an alkyl group optionally having a substituent and, among them, a hydrogen atom, and a methyl group are preferable due to high radical reactivity. R¹⁰ and R¹¹ each represent independently a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxycarbonyl group, an alkyl group optionally having a substituent, and an aryl group optionally having a substituent are preferable due to high radical reactivity.

Herein, as a group which may be introduced as the substituent, the same groups as those for the formula (E1) are exemplified. Z represents an oxygen atom, a sulfur atom, —N(R¹³)—, or a phenylene group optionally having a substituent. R¹³ represents an alkyl group optionally having a substituent and, inter alia, a methyl group, an ethyl group, and an isopropyl group are preferable due to high radical reactivity.

As a method of introducing an ethylenic unsaturated bond into a side chain of a polyurethane resin, a method of using a diol compound containing an ethylenic unsaturated bond as a raw material for producing a polyurethane resin is also suitable. Such a diol compound may be a commercially available compound such as trimethylolpropane monoallyl ether, or may be a compound which is easily produced by a reaction of a halogenated diol compound, a triol compound, or an aminodiol compound, and a carboxylic acid, acid chloride, isocyanate, alcohol, amine, thiol, or a halogenated alkyl compound containing an ethylenic unsaturated bond. Specific examples of these compounds are not limited to, but include the following compounds.

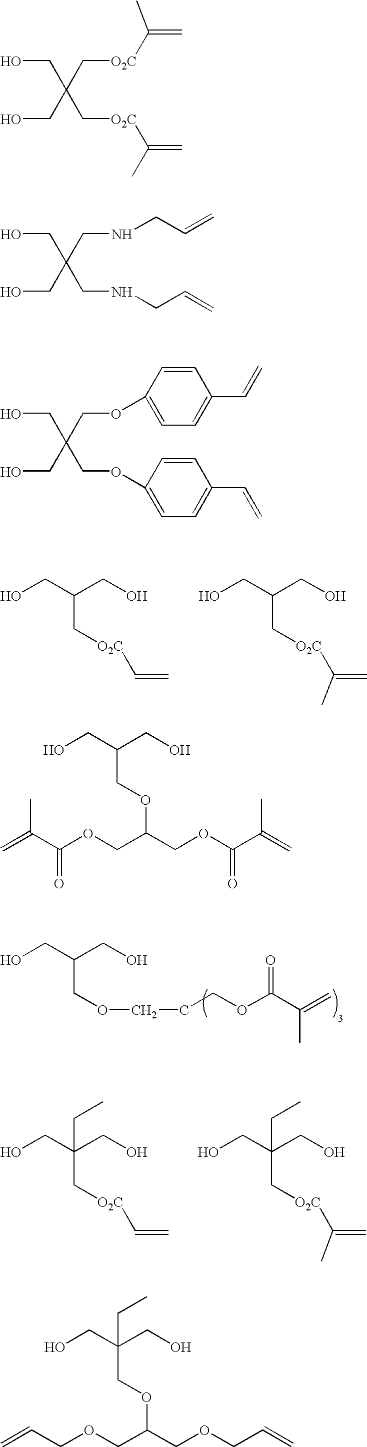

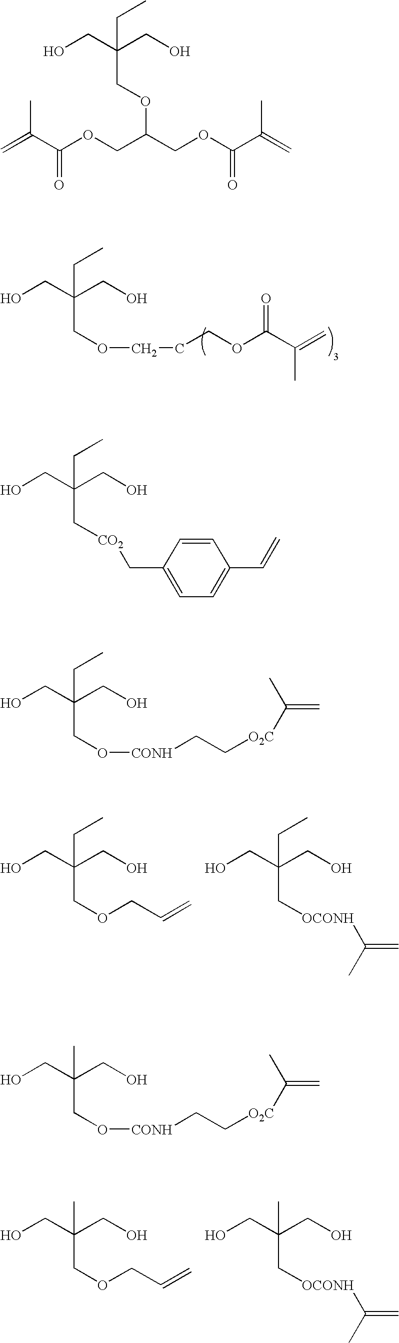

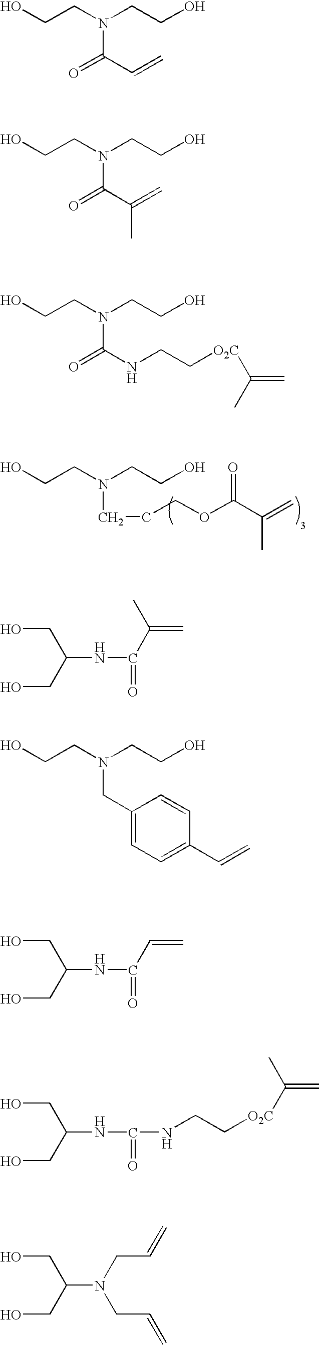

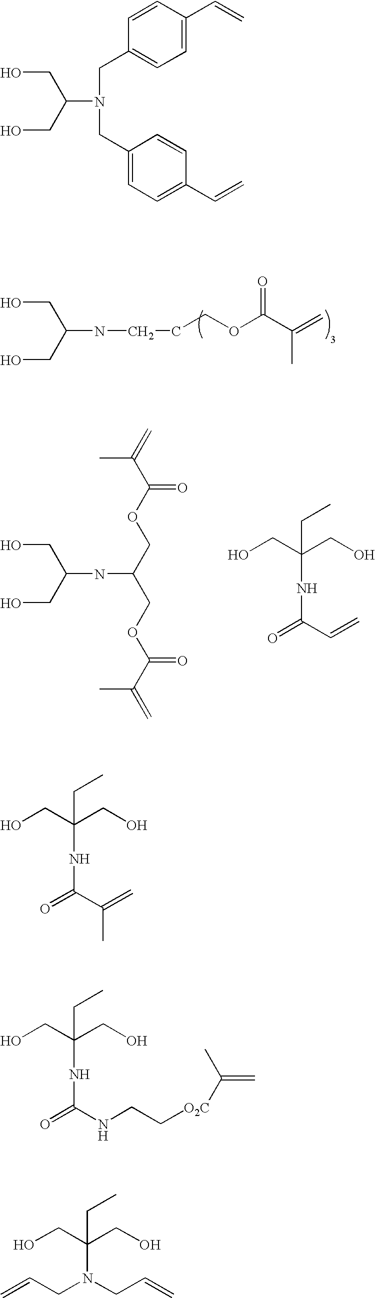

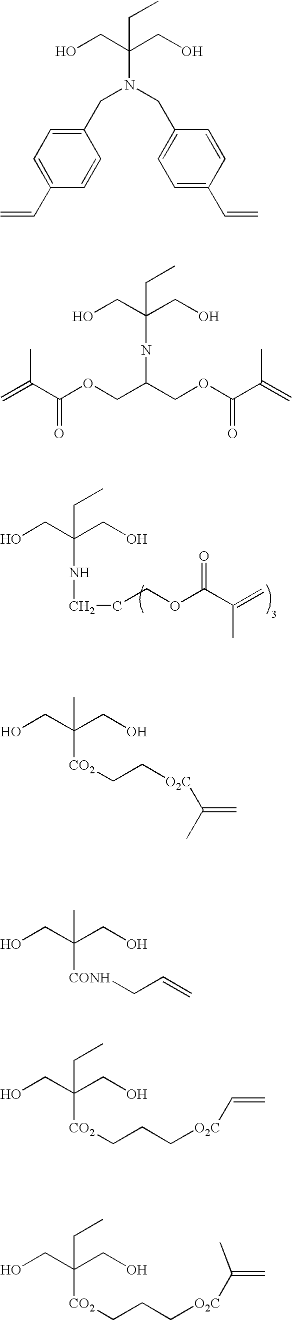

In addition, as a more preferable polyurethane resin, a polyurethane resin obtained using a diol compound represented by the following formula (G) as at least one of diol compounds having an ethylenic unsaturated bond group upon synthesis of a polyurethane resin is exemplified.

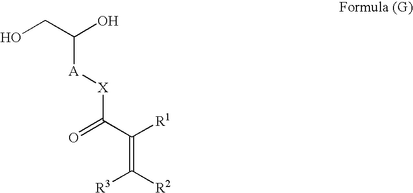

In the formula (G), R¹ to R³ each represent independently a hydrogen atom or a monovalent organic group, A represents a divalent organic residue, X represents an oxygen atom, a sulfur atom, or —N(R¹²)—, and R¹² represents a hydrogen atom, or a monovalent organic group.

R¹ to R³ and X in this formula (G) have the same meanings as those of R¹ to R³ and X in the formula (E1), and a preferable embodiment is similar.

A divalent organic residue represented by the A is a divalent organic linking group which contains a carbon atom and a hydrogen atom, and optionally an atom selected from an oxygen atom, a nitrogen atom, and a sulfur atom. Preferable is a divalent organic linking group which is constructed by suitably combining —C(═O)—, —C(═O)—O—, —C(═O)—NH—, —NH—C(═O)—O—, —NH—C(═O)—NH—, alkylene group, allylene group, or a group constructed by combining them and further —O—, —S—, or —NH—. The number of atoms constructing a linking chain contained in this divalent organic linking group is suitably within 60 and, from a viewpoint that film forming property is kept good, is preferably within 50, more preferably within 40.

It is thought that, by using a polyurethane resin derived from these diol compounds, the effect of suppressing excessive molecular motion of a polymer main chain due to a secondary alcohol having great steric hindrance is obtained, and improvement in a film strength of the relief forming layer is attained.

Examples of the diol compound represented by the formula (G) which is suitably used in synthesizing a polyurethane resin will be shown below.

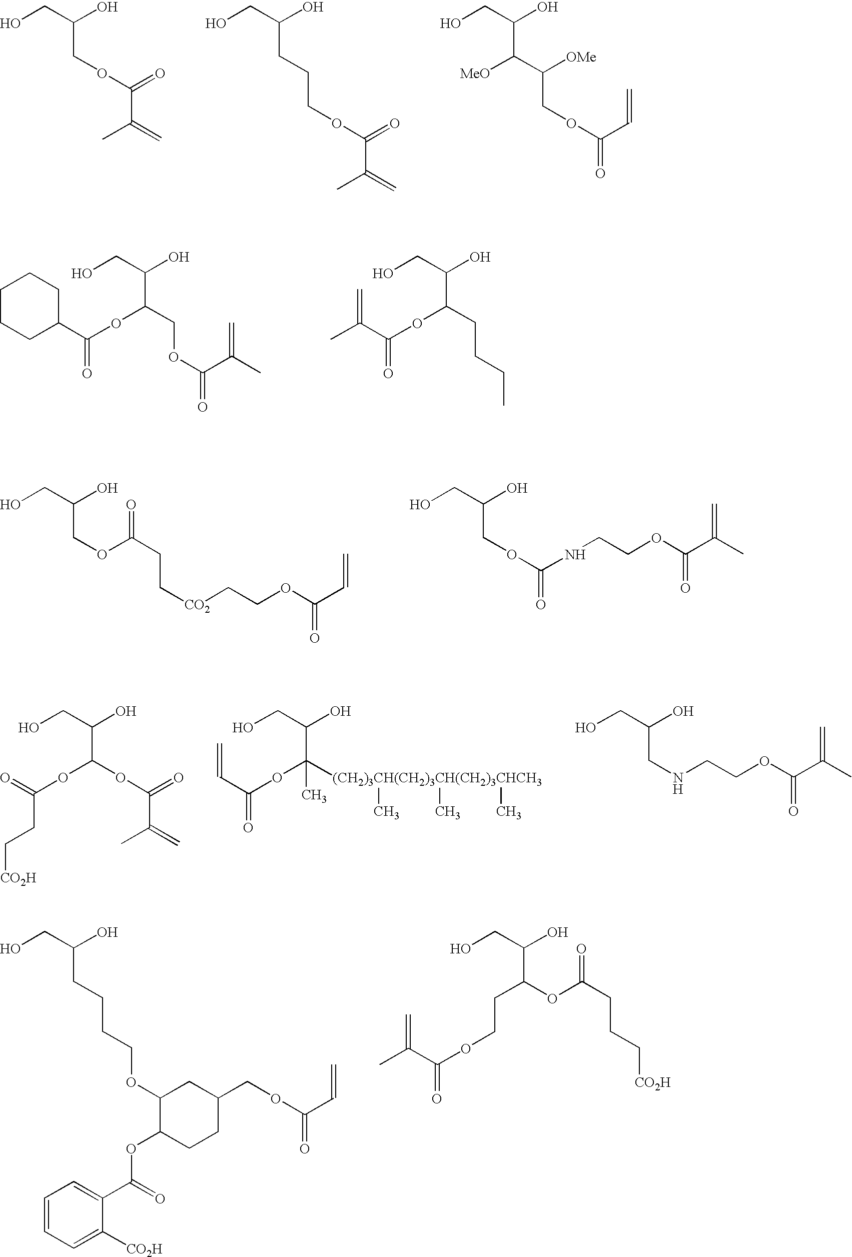

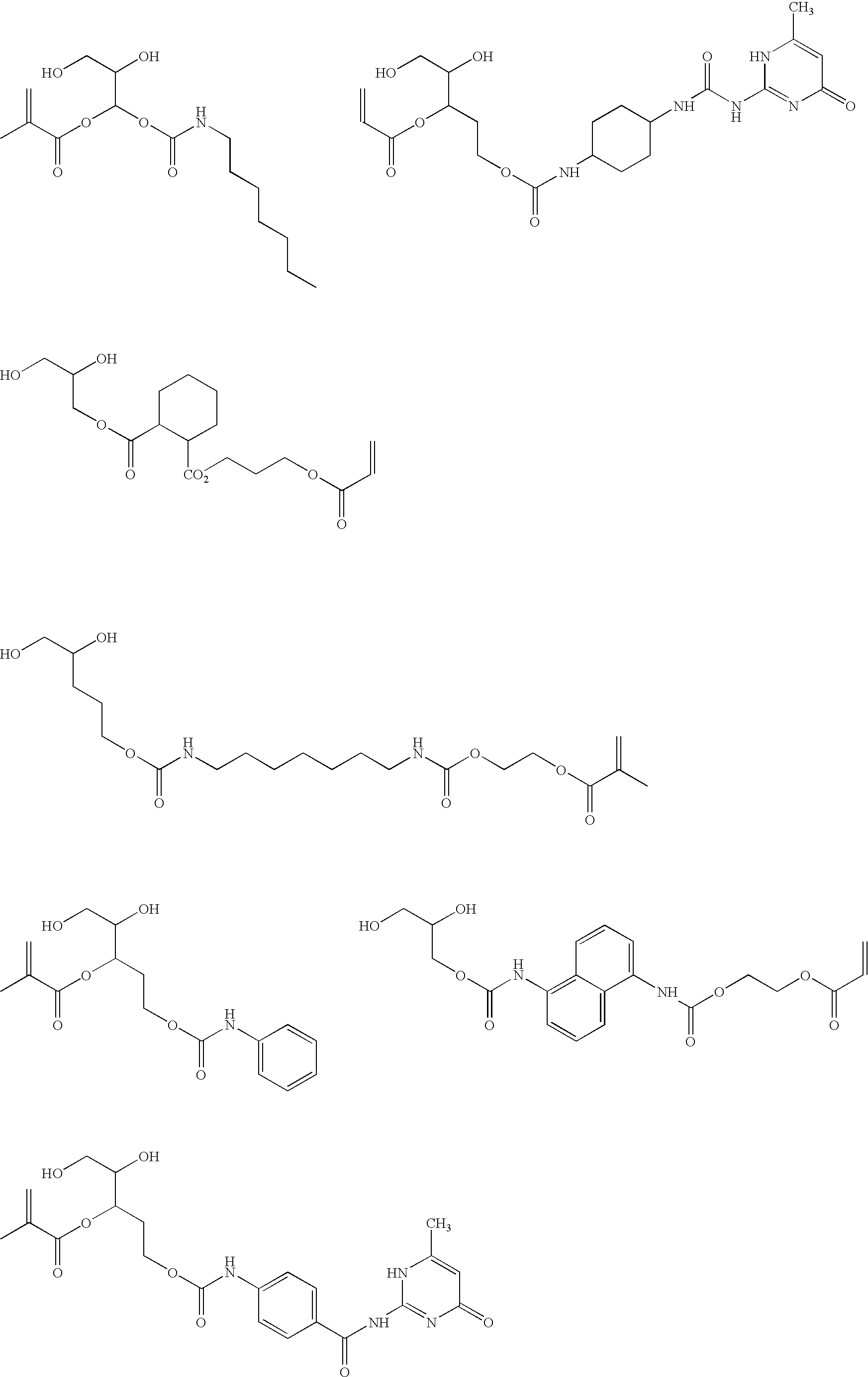

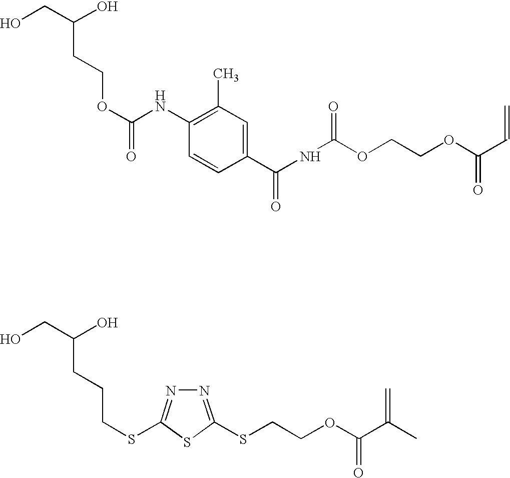

When synthesizing a polyurethane resin under the NCO group excessive condition where an NCO/OH ratio is 1 or more, a main chain terminal is an NCO group, and thus, by separately adding hereto an alcohol having an ethylenic unsaturated bond (2-hydroxyethyl (meth)acrylate, trade name: BLEMMER PME200, manufactured by NOF Corporation) etc.), an ethylenic unsaturated bond may be introduced into a main chain terminal.

That is, as a polyurethane resin suitable in the invention, a resin having an ethylenic unsaturated group not only in a side chain but also in a main chain terminal is also preferable.

As a polyurethane resin suitable in the invention, as described above, in addition to a resin having an ethylenic unsaturated bond in a side chain, a resin having an ethylenic unsaturated bond in a main chain terminal and/or a main chain is also suitably used.

As a method of introducing an ethylenic unsaturated bond into a main chain terminal of a polyurethane resin, there is the following method.

That is, when synthesizing a polyurethane resin, in a step of treating an isocyanate group remaining in a main chain terminal of the resulting intermediate product with alcohols or amines, alcohols or amines having an ethylenic unsaturated group may be used.

As a method of introducing an ethylenic unsaturated bond into a main chain of a polyurethane resin, there is a method of using a diol compound having an ethylenic unsaturated bond in a chain linking an OH group and an OH group in synthesis of a polyurethane resin. Examples of the diol compound having an ethylenic unsaturated bond in a chain linking an OH group and an OH group include the following compounds.

That is, examples include cis-2-butene-1,4-diol, trans-2-butene-1,4-diol, and polybutadiendiol.

From a viewpoint that an introduction amount is easily controlled, and an introduction amount may be increased, or a crosslinking reaction efficacy is improved, it is preferable that an ethylenic unsaturated bond is introduced into a side chain rather than into a main chain terminal of a polyurethane resin.

As an ethylenic unsaturated bond group to be introduced, from a viewpoint of crosslinked cured film forming property, a methacryloyl group, an acryloyl group, and styryl group are preferable and, a methacryloyl group and an acryloyl group are more preferable. From a viewpoint of realization of both of forming property and unused stock storability of a crosslinked cured film, a methacryloyl group is further preferable.

Regarding an amount of an ethylenic unsaturated bond contained in a polyurethane resin used in the invention, an ethylenic unsaturated bond group is contained in a side chain in an amount of preferably 0.3 meq/g or more, further preferably 0.35 to 1.50 meq/g as expressed by equivalent. That is, a polyurethane resin containing a methacryloyl group in a side chain in an amount of 0.35 to 1.50 meq/g is most preferable.

A weight average molecular weight of a polyurethane resin as the specified alcoholphilic polymer in the invention is preferably 10,000 or more, more preferably in the range of 40,000 to 200,000. Particularly, when a polyurethane resin having a molecular weight in this range is used, a strength of the formed relief layer (image area) is excellent.

A polyurethane resin used as the specified alcoholphilic polymer in the invention is synthesized by heating the diisocyanate compound and the diol compound in an aprotic solvent with the addition of the known catalyst having activity according to each reactivity. A molar ratio (Mₐ:M_{b}) of the diisocyanate and diol compounds used in synthesis is preferably 1:1 to 1.2:1.1 and, by treating with alcohols or amines, a product having desired physical properties such as a molecular weight and a viscosity is synthesized in such a final form that an isocyanate group does not remain.

Inter alia, synthesis using a bismuth catalyst is more preferable than a tin catalyst which has been previously used frequently, from a viewpoint of the environment and a polymerization rate. As such a bismuth catalyst, trade name: NEOSTAN U-600 manufactured by NITTO CHEMICAL INDUSTRY co., ltd. is particularly preferable.

Examples of the specified polyurethane resin used in the invention are shown below, but the invention is not limited by them.

| | | | Weight |
|---|---|---|---|
| Poly- | | | average |
| ure- | Diisocyanate | | molec- |
| thane | compound | Diol compound | ular |
| resin | used (mol %) | used (mol %) | weight |
| P-1 | 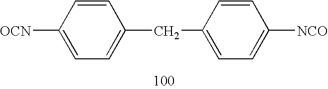 | 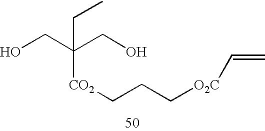 | 95,000 |
| | | 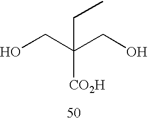 | |
| P-2 | 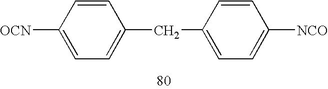 | 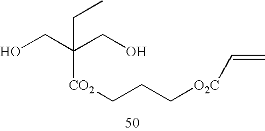 | 98,000 |
| | 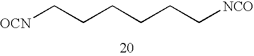 | 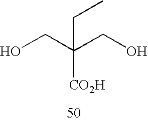 | |
| P-3 | 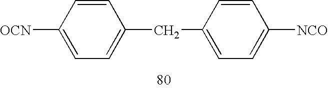 | 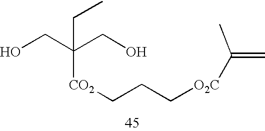 | 103,000 |
| | 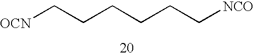 | 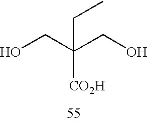 | |
| P-4 | 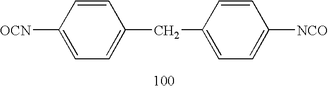 | 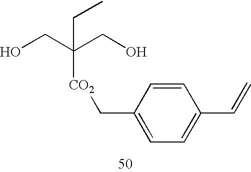 | 108,000 |
| | | 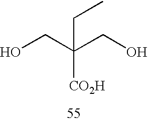 | |
| P-5 | 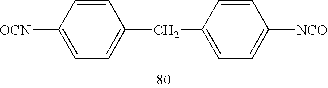 | 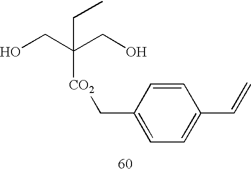 | 99,000 |
| | 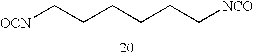 | 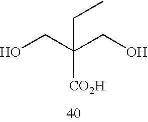 | |
| P-6 | 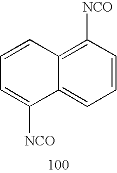 | 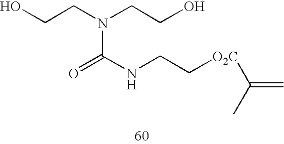 | 96,000 |
| | | 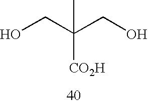 | |
| P-7 | 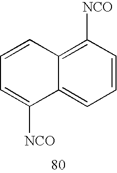 | 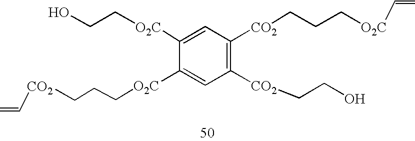 | 68,000 |
| | 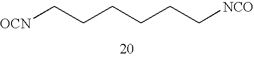 | 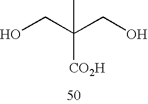 | |
| P-8 | 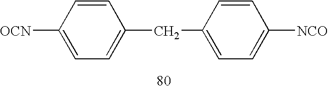 | 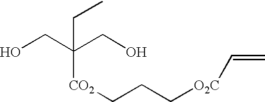 | 96,000 |
| | 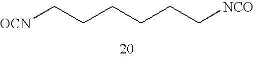 | 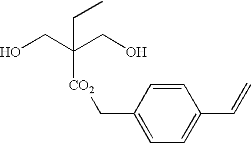 | |
| | | 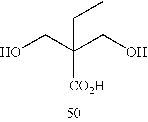 | |
| P-9 | 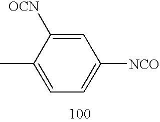 | 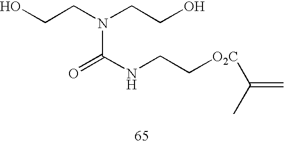 | 100,000 |
| | | 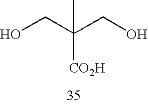 | |
| P-10 | 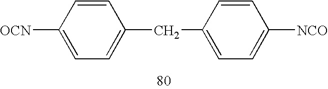 | 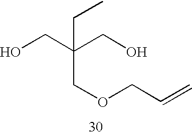 | 69,000 |
| | 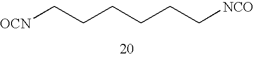 | 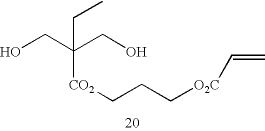 | |
| | | 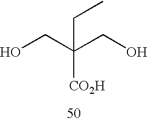 | |
| P-11 | 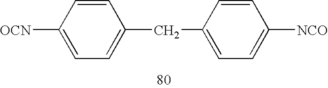 | 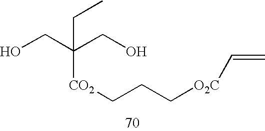 | 120,000 |
| | 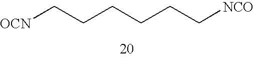 | 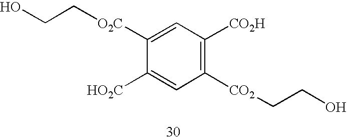 | |
| P-12 | 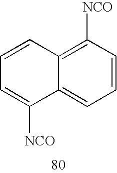 | 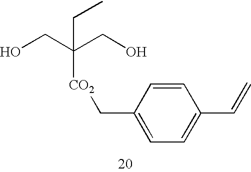 | 78,000 |
| | 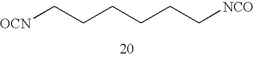 | 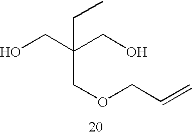 | |
| | | 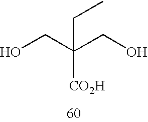 | |
| P-13 | 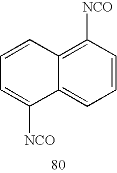 | 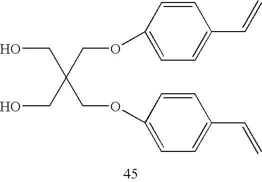 | 103,000 |
| | 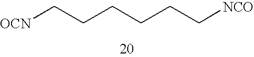 | 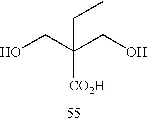 | |
| P-14 | 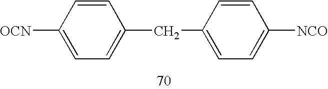 | 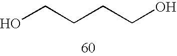 | 65,000 |
| | 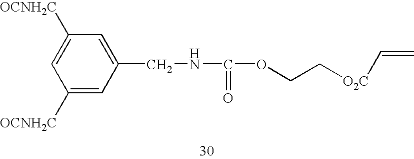 | 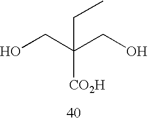 | |
| P-15 | 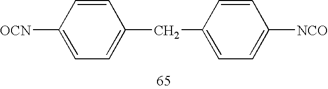 | 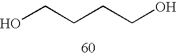 | 78,000 |
| | 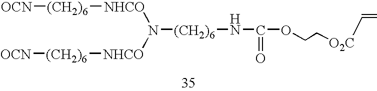 | 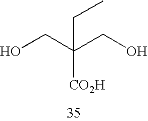 | |
| P-16 | 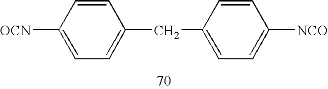 | 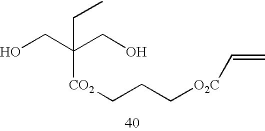 | 69,000 |
| | 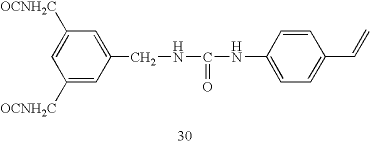 | 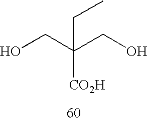 | |
| P-17 | 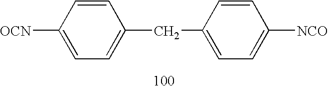 | 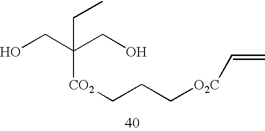 | 99,000 |
| | | 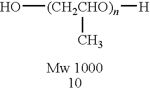 | |
| | | 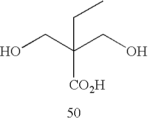 | |
| P-18 | 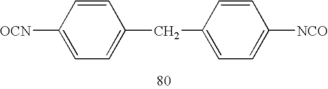 | 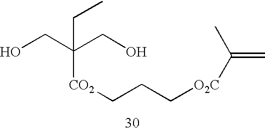 | 87,000 |
| | 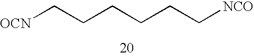 | 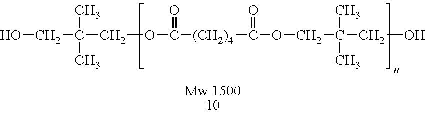 | |
| | | 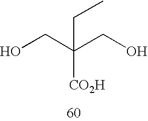 | |
| P-19 | 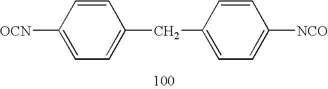 | 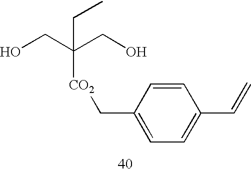 | 97,000 |
| | | 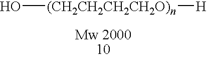 | |
| | | 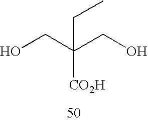 | |
| P-20 | 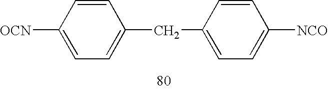 | 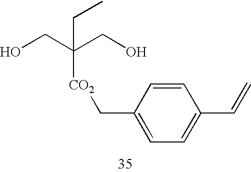 | 103,000 |
| | 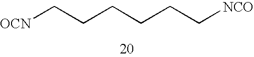 | 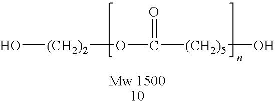 | |
| | | 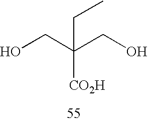 | |
| P-21 | 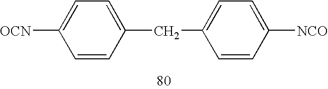 | 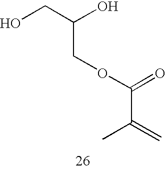 | 60,000 |
| | 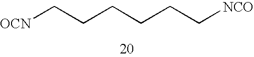 | 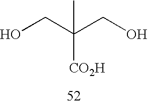 | |
| | | 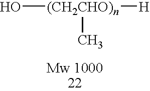 | |
| P-22 | 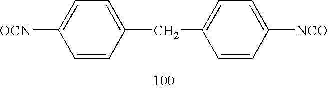 | 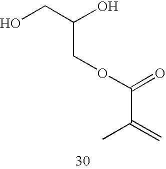 | 70,000 |
| | | 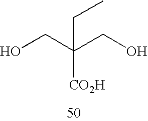 | |
| | | 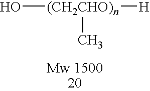 | |
| P-23 | 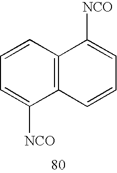 | 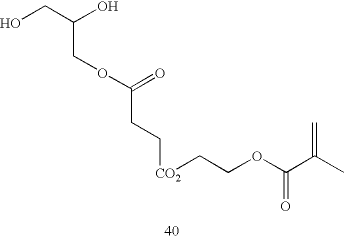 | 50,000 |
| | 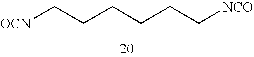 | 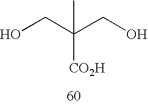 | |
| P-24 | 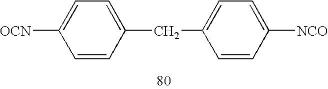 | 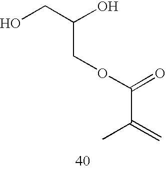 | 75,000 |
| | 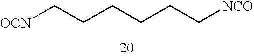 | 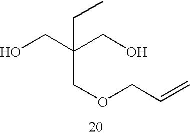 | |
| | | 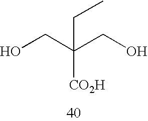 | |
| P-25 | 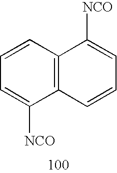 | 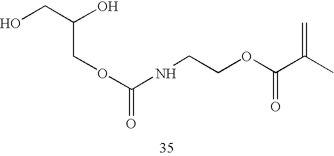 | 80,000 |
| | | 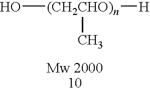 | |
| | | 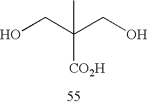 | |
| P-26 | 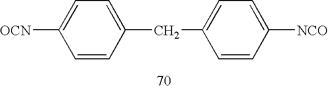 | 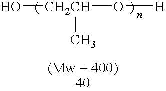 | 50,000 |
| | 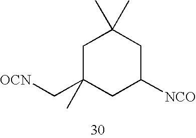 | 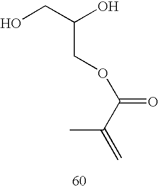 | |
| P-27 | 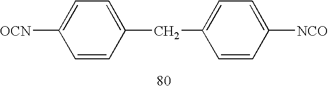 | 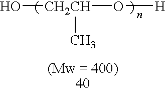 | 60,000 |
| | 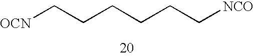 | 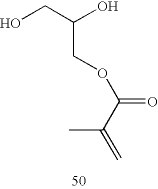 | |
| | | 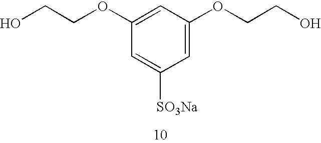 | |
| P-28 | 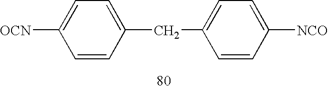 | 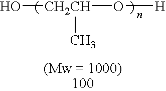 | 59,000 |
| | 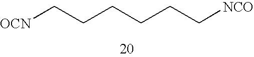 | | |
| P-29 | 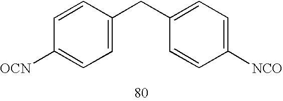 | 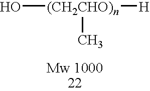 | 63,000 |
| | 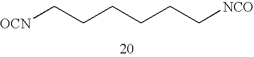 | 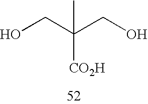 | |
| | | 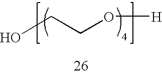 | |
| P-30 | 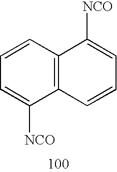 | 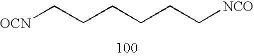 | 32,000 |
| P-31 | 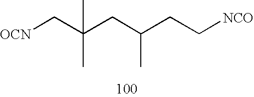 | 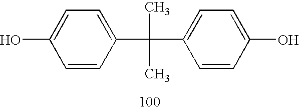 | 21,000 |
| P-32 | 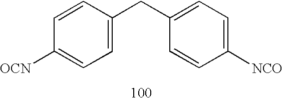 | 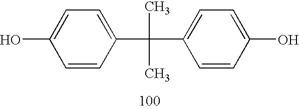 | 29,000 |
| P-33 | 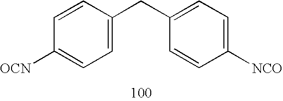 | 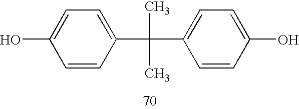 | 41,000 |
| | | 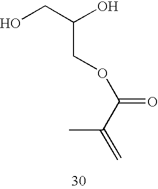 | |

A polyurethane resin as the specified alcoholphilic polymer related to the invention has the characteristic that it is thermally decomposed at a relatively low temperature (lower than 250° C.) as compared with a binder polymer used in the normal relief forming layer (in the case of a commercially available general-use resin, it is thermally decomposed at a high temperature of 300° C. to 400° C. in most cases). Therefore, the relief forming layer containing such a polyurethane resin may be decomposed at a high sensitivity.

In addition, in a system in which such a polyurethane resin is used as the specified alcoholphilic polymer and an additional binder polymer described later is used together, even in the state where these polymers are not uniformly mixed and are phase-separated, first, this polyurethane resin is decomposed by heat production with laser irradiation and, as a result, a gas (nitrogen etc.) generated upon thermal decomposition and vaporization of the polyurethane resin assists and promotes vaporization of the additional binder polymer. For this reason, the relief forming layer using such a polyurethane resin as the specified alcoholphilic polymer also has an advantage that, even when the additional binder polymer is present, laser decomposability is improved, and a high sensitivity is attained.

(Hydrophobic Polymer)

As a binder polymer in the invention, a relatively hydrophobic binder polymer may be used.

As the relatively hydrophobic binder polymer, polymers containing the following monomers as a polymerization or copolymerization component may be used for adjusting a nature such as a hardness or flexibility of a film when forming the film, and compatibility with other components such as a polymerization compound and an initiator which are present together.

Examples include compounds having only one ethylenic unsaturated bond such as (meth)acrylate having a hydroxy group such as 2-hydroxyethyl(meth)acrylate, 2-hydroxypropyl(meth)acrylate, 2-hydroxybutyl(meth)acrylate, 3-chloro-2-hydroxypropyl (meth)acrylate, and β-hydroxy-β′-(meth)acryloyloxyethyl phthalate, alkyl(meth)acrylate such as methyl(meth)acrylate, ethyl(meth)acrylate, propyl(meth)acrylate, butyl(meth)acrylate, isoamyl(meth)acrylate, 2-ethylhexyl(meth)acrylate, lauryl(meth)acrylate, and stearyl (meth)acrylate, cycloalkyl(meth)acrylate such as cyclohexyl(meth)acrylate, halogenated alkyl(meth)acrylate such as chloroethyl(meth)acrylate, and chloropropyl(meth)acrylate, alkoxylalkyl(meth)acrylate such as methoxyethyl(meth)acrylate, ethyoxyethyl (meth)acrylate, and butoxyethyl(meth)acrylate, phenoxyalkyl(meth)acrylate such as phenoxyethyl acrylate, and nonylphenoxyethyl(meth)acrylate, alkoxyalkylene glycol (meth)acrylate such as ethoxydiethylene glycol (meth)acrylate, methoxytriethylene glycol (meth)acrylate, and methoxydipropylene glycol (meth)acrylate, (meth)acrylamides such as (meth)acrylamide, diacetone(meth)acrylamide, and N,N′-methylenebis(meth)acrylamide, 2,2-dimethylaminoethyl(meth)acrylate, 2,2-diethylaminoethyl(meth)acrylate, N,N-dimethylaminoethyl(meth)acrylamide, and N,N-dimethylaminopropyl(meth)acrylamide, and compounds having two or more ethylenic unsaturated bonds such as di(meth)acrylate of polyethylene glycol such as diethylene glycol di(meth)acrylate, polypropylene glycol di(meth)acrylate such as dipropylene glycol di(meth)acrylate, trimethylolpropane tri(meth)acrylate, pentaerythritol tri(meth)acrylate, pentaerythritol tetra(meth)acrylate, glycerol tri(meth)acrylate, polyvalent (meth)acrylate obtained by addition-reacting a compound having an ethylenic unsaturated bond and active hydrogen such as unsaturated carboxylic acid and an unsaturated alcohol with ethylene glycol diglycidyl ether, polyvalent (meth)acrylate obtained by addition-reacting a compound having active hydrogen such as carboxylic acid and amine with an unsaturated epoxy compound such as glycidyl (meth)acrylate, polyvalent (meth)acrylamide such as methylenebis(meth)acrylamide, and a polyvalent vinyl compound such as divinylbenzene. In the invention, these may be used alone, or may be used by combining two or more kinds.

As a monomer of the polymerization components, from a viewpoint of film forming property, 2-hydroxylethyl(meth)acrylate, 2-hydroxypropyl(meth)acrylate, 2-hydroxybutyl (meth)acrylate, alkoxyalkylene glycol (meth)acrylate such as ethoxydiethylene glycol (meth)acrylate, methoxytriethylene glycol (meth)acrylate, and methoxydipropylene glycol (meth)acrylate, (meth)acrylamide, diacetone(meth)acrylamide, cyclohexyl(meth)acrylate, benzyl(meth)acrylate, and N-acryloylmorpholine are preferable. Among them, acrylates are particularly preferable from a viewpoint that softness of the resulting polymer is maintained.

Besides, as the binder polymer, the following polymers may be also used.

That is, there is a polymer containing at least any of olefin and a carbon-carbon triple bond in a main chain, and examples include SB (polystyrene-polybutadiene), SBS (polystyrene-polybutadiene-polystyrene), SIS (polystyrene-polyisoprene-polystyrene), and SEBS (polystyrene-polystyrene/polybutylene-polystyrene).

(Polymer Having Carbon-Carbon Unsaturated Bond)

As the binder polymer, a polymer having a carbon-carbon unsaturated bond in a molecule may be suitably used. The carbon-carbon unsaturated bond may be present in one of a main chain and a side chain of a polymer, or may be present in both chains. Hereinafter, the carbon-carbon unsaturated bond is simply referred to as “unsaturated bond” in some cases, and the carbon-carbon unsaturated bond remaining in a main chain or a side chain terminal is referred to as “polymerizable group” in some cases.

When a main chain of a polymer has the carbon-carbon unsaturated bond, the bond may be included in any of one terminal and both terminals of a polymer main chain, and a main chain. When a side chain of a polymer has the carbon-carbon unsaturated bond, the unsaturated bond may directly bind to a main chain structure, or may bind thereto via a suitable linking group.

Examples of a polymer containing the carbon-carbon unsaturated bond in a main chain include SB (polystyrene-polybutadiene), SBS (polystyrene-polybutadiene-polystyrene), SIS (polystyrene-polyisoprene-polystyrene), and SEBS (polystyrene-polyethylene/polybutylene-polystyrene).

When a polymer having a polymerizable unsaturated group having high reactivity such as a methacryloyl group is used as a polymer having the carbon-carbon unsaturated bond in a side chain, a film having an extremely high mechanical strength may be made. In particular, in polyurethane and polyester thermoplastic elastomers, a polymerizable unsaturated group having high reactivity may be introduced into a molecule relatively simply.

Upon introduction of an unsaturated bond or a polymerizable group into the binder polymer, any of the known methods may be adopted, such as a method of copolymerizing, into a polymer, a structural unit having a polymerizable group precursor in which a protecting group is bound to a polymerizable group, and eliminating the protecting group to form a polymerizable group, and a method of preparing a polymer compound having a plural reactive groups such as a hydroxy group, an amino group, an epoxy group, a carboxyl group, an acid anhydride group, a ketone group, a hydrazine residue, an isocyanate group, an isothiocyanate group, a cyclic carbonate group, and an ester group, thereafter, reacting a binding agent (e.g. polyisocyanate in the case of a hydroxy group and an amino group) having a plural groups which may bind to the reactive groups, performing regulation of a molecular weight, and a conversion of a terminal into a binding group, thereafter, reacting with an organic compound having a group reactive with this terminal binding group and a polymerizable unsaturated group to introduce a polymerizable group by a polymer reaction. According to these methods, an amount of an unsaturated bond and a polymerizable group to be introduced into a polymer compound may be controlled.

It is also preferable that such a polymer having an unsaturated bond is used together with a polymer having no unsaturated bond. That is, since a polymer obtained by adding hydrogen to an olefin part of a polymer having the carbon-carbon unsaturated bond, and a polymer obtained by forming a polymer using, as a raw material, a monomer in which an olefin part is hydrogenated, for example, a monomer in which butadiene or isoprene is hydrogenated, are excellent in compatibility, they may be also used to adjust an amount of an unsaturated bond included in the binder polymer.

When they are used, the polymer having no unsaturated bond may be used at a ratio of generally 1 part by mass to 90 parts by mass, preferably 5 parts by mass to 80 parts by mass relative to 100 parts by mass of the polymer having an unsaturated bond.

As described later, in an embodiment in which the binder polymer is not required to have curability such as the case where other polymerizable compound is used together, an unsaturated bond is not necessarily essential in the binder polymer, and only polymers having no unsaturated bond may be used as the binder polymer. Preferable examples of the polymer having no unsaturated bond in such a case include polyester, polyamide, polystyrene, acryl resin, acetal resin, and polycarbonate.

A number average molecular weight of the binder polymer having an unsaturated bond, or having no unsaturated bond, which may be used in the invention, is preferably in the range of 1,000 to 1,000,000. The more preferable range is 5,000 to 500,000. When the number average molecular weight is in the range of 1,000 to 1,000,000, a mechanical strength of a formed film may be maintained. The number average molecular weight is a molecular weight which is measured using gel permeation chromatography (GPC), and is evaluated relative to a polystyrene specimen having the known molecular weight.

A weight average molecular weight (in terms of polystyrene as measured by GPC) of the binder polymer in the invention is preferably 5,000 to 500,000. When the weight average molecular weight is 5,000 or more, form retainability as a single resin is excellent and, when the weight average molecular weight is 500,000 or less, the polymer is easily dissolved in a solvent such as water, and this is advantageous for preparing a coating liquid for the relief forming layer. The weight average molecular weight of the binder polymer is more preferably 10,000 to 400,000, particularly preferably 15,000 to 300,000.

A content of the binder polymer in the relief forming layer is preferably 5% by mass to 80% by mass, more preferably 15% by mass to 75% by mass, further preferably 20% by mass to 65% by mass.

Particularly, by adopting a content of the binder polymer of 15% by mass or more, print durability sufficient for use of the resulting relief printing plate as a printing plate is obtained and, by adopting 75% by mass or less, other components are not insufficient, and softness sufficient for use as a printing plate also when the relief printing plate is used as a flexographic printing plate may be obtained.

<(C) Compound Having Deodorizing Ability>

The relief forming layer in the invention contains (C) a compound having deodorizing ability as an essential component.

The compound having deodorizing ability in the invention has the effect of preventing or reducing an unpleasant odor generated when light and/or heat are applied to the relief forming layer of the relief printing plate precursor of the invention, and may be at least one compound selected from the group consisting of diphenols, polyphenols, hydroquinones, diarylamines, alkylated p-phenylenediamines, dihydroquinones, thioethers, hindered amines, phenols, phosphites, phosphonites, catechins, tannins, natural substance extracts, phenolic compound oxidases, and polysaccharides. Examples of such compounds include deodorizers and deodorants described later.

[Deodorizer]

As the deodorizer used in the invention, from a viewpoint of preventing an odor due to a photopolymerization initiator, a radical inhibitor may be exemplified.

The radical inhibitor is a compound which is added to a radical polymerizable composition such as the relief forming layer in the invention for inhibiting or stopping radical polymerization.

Examples of the radical inhibitor include a polymerization inhibitor, a stabilizer, an antioxidant, and a radical scavenger.

A radical inhibitor will be explained in detail below.

Previously, many radical inhibitors have been known, and are described in, for example, in U.V. and E.B. Curing Formulations for Printing Inks, Coatings and Paints, SITA-Technology (London, 1988), page 22 (written by R. Holman and P. Oldring).

Other radical inhibitors are listed in Table 4 of “Antioxidants” written by M. Dexter, Encyclopedia of Chemical Technology, vol. 3 (4^{th} edition, Wiley Interscience, New York, 1992) and edited by J. I. Kroschwitz, pp. 424 to 447 and examples of monophenols include monophenols having the following CAS Registry Numbers: 128-39-2, 128-37-0, 4130-42-1, 4306-88-1, 1879-09-0, 110553-27-0, 61788-44-1, 17540-75-9, 2082-79-3, 103-99-1, 88-27-7, and 99-1-84-4.

The polymerization inhibitor which is one of radical inhibitors is an additive which slows a process speed of, or inhibits a radical polymerization process of the relief forming layer in the invention.

Examples of such a polymerization inhibitor include diphenols, polyphenols, hydroquinones, diarylamines, alkylated p-phenylenediamines, dihydroquinones, thioethers, and hindered amines.

Examples of diphenols include diphenols having the following CAS Registry Numbers: 119-47-1, 88-24-4, 118-82-1, 35958-30-6, 36443-68-2, 85-60-9, 96-69-5, 96-66-2, 35074-77-2, 41484-35-9, 23128-74-7, 65140-91-2, 30947-30-9, 70331-94-1, 32687-78-8, 32509-66-3, and 105350-68-3.

Examples of polyphenols include polyphenols having the following CAS Registry Numbers: 68610-51-5, 6683-19-8, 1709-70-2, 27676-62-6, 1843-03-4, 34137-09-2, and 40601-76-1.

Examples of hydroquinones include hydroquinones having the following CAS

Registry Numbers: 79-74-3, 1948-33-0, and 121-00-6.

Examples of diarylamines include diarylamines having the following CAS Registry Numbers: 90-30-2, 68442-68-2, 68259-36-9, 101-67-7, and 10081-67-1.

Examples of alkylated p-phenylenediamines include alkylated p-phenylenediamines having the following CAS Registry Numbers: 793-24-8, 101-72-4, 69796-47-0, 15233-47-3, 101-87-1, 74-31-7, 93-46-9, 3081-14-9, 139-60-6, 793-24-8, 103-96-8, and 100-93-6.

Examples of dihydroquinones include dihydroquinones having the following CAS Registry Numbers: 26780-96-1, 89-28-1, and 91-53-2.

Examples of thioethers include thioethers having the following CAS Registry Numbers: 2500-88-1, 123-28-4, 693-36-7, 16545-54-3, 10595-72-9, 29598-76-3, 53988-10-6, 61617-00-3, 26523-78-4, 26741-53-7, 3806-34-6, 31570-04-4, 38-613-77-3, and 118337-09-0.

Examples of hindered amines include hindered amines having the following CAS Registry Numbers: 70624-18-9, 82541-48-7, and 106990-43-6.

Examples of a specific compound of the polymerization inhibitor include p-methoxyphenol, hydroquinone, methoxybenzoquinone, phenothiazine, catechols, alkylphenols, alkylbisphenols, zinc dimethyldithiocarbamate, copper dimethyldithiocarbamate, copper dibutyldithiocarbamate, copper salicylate, thiodipropionic acid esters, mercaptobenzimidazole, and phosphites, and p-methoxyphenol, catechols, alkylphenols, and alkylbisphenols are preferable.

Examples of catechols include p-t-butylcatechol.

Examples of alkylphenols and alkylbisphenols include 2,6-di-t-butyl-phenol, octadecyl-3-(3,5-di-t-butyl-4-hydroxyphenyl) propionate, N,N′-hexamethylenebis(3,5-di-t-butyl-4-hydroxy-hydrocinamide), 2,2′-methylenebis(4-methyl-6-t-butylphenol), 4,4′-methylenebis(2,6-di-t-butylphenol), 4,4′-butylidenebis(3-methyl-6-t-butylphenol), 2,6-bis(2′-hydroxy-3′-t-butyl-5′-methylbenzyl)-4-methylphenol, 1,1,3-tris(2′-methyl-5′-t-butyl-4′-hydroxyphenyl)butane, 1,3,5-trimethyl-2,4,6-tris(3′,5′-di-t-butyl-4′-hydroxybenzyl)benzene, triethylene glycol bis[3-(3-t-butyl-5-methyl-4-hydroxyphenyl)propionate], and pentaerythrityltetrakis[3-(3,5-di-t-butyl-4-hydroxyphenyl)propionate]. It is preferable that phenols are oil-soluble.

The antioxidant which is one of radical inhibitors is an additive which prevents an organic substance from becoming hydroperoxide (which is easily cleaved to produce a radical) due to an oxygen in the atmospheric air. Particularly, when the antioxidant is used as an additive for an ethylenic unsaturated oligomer, an antioxidant which prevents this process is usually called radical inhibitor (“Antioxidants” written by M. Dexter, Encyclopedia of Chemical Technology, vol. 3 (4^{th} edition, Wiley Interscience, New York, 1992) edited by J. I. Kroschwitz, pp. 424 to 447).

Examples of the antioxidant used in the invention include phenol antioxidants (phenols), phosphite antioxidants (phosphites), phosphonite antioxidants (phosphonites), sulfur containing antioxidants (thioethers), and hindered amine antioxidants (hindered amines).

The phenol antioxidant is not particularly limited, but a compound represented by the following formula [A], and hydroquinones are preferably exemplified.

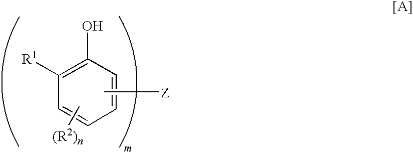

In the general formula [A], R¹ and R² each represent independently a lower alkyl group, n represents an integer of 0 to 2, m represents an integer of 1 to 4, and Z represents a hydrogen atom or a monovalent to tetravalent organic group.

The lower alkyl group represented by R¹ or R² represents an alkyl group having 1 to 8 carbon atoms, and may be straight, or may have a branch, and may have a ring structure.

The monovalent to tetravalent organic group represented by Z is not particularly limited, as far as it is an organic group which does not deteriorate the deodorizing ability of the compound having a partial structure represented by the formula [A].

Among the compounds having a partial structure represented by the formula [A], a compound represented by the following formula [A1] or [A2] is preferable.

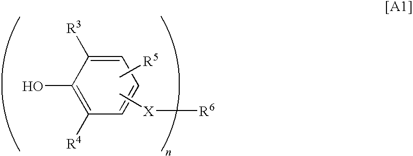

In the formula [A1], R³ represents a lower alkyl group, R⁴ and R⁵ each represent independently a hydrogen atom or a lower alkyl group, and n represents an integer of 1 to 4. When n is 1, X represents a single bond or an alkylenecarbonyloxy group and, when X is a single bond, R⁶ represents a hydrogen atom, an alkoxy group, or a lower alkyl group optionally substituted with an alkoxy group or an amino group and, when X is an alkylenecarbonyloxy group, R⁶ represents a hydrogen atom or an alkyl group. When n is 2 to 4, X represents an alkylenecarbonyloxy group, and R⁶ represents a divalent to tetravalent alcohol residue optionally containing a hetero atom in the residue. And, when n is 3, X may be an alkylene group, and R⁶ may be an isocyanuric acid residue.

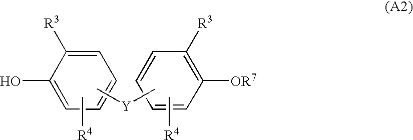

In the formula [A2], R³ and R⁴ have the same meanings as those of R³ and R⁴ of the formula [A1], and the preferable range is the same. R³s and R⁴s which are present at the plural number in the molecule may be the same or different. And, Y represents an alkylene group or a sulfur atom. R⁷ represents a hydrogen atom, an acrylic acid residue, or a methacrylic acid residue.

Examples of the phenol antioxidant include hydroquinone, methylhydroquinone, t-butylhydroquinone, 2,6-di-t-butyl-4-methylphenol, octadecyl-3-(3,5-di-t-butyl-4-hydroxyphenyl) propionate, 2,2′-methylenebis(6-t-butyl-4-methylphenol), 2-t-butyl-6-(3-t-butyl-2-hydroxy-5-methylbenzyl)-4-methylphenyl acrylate, 2-[1-(2-hydroxy-3,5-di-t-pentylphenyl)ethyl]-4,6-di-t-pentylphenyl acrylate, 4,4′-butylidenebis(6-t-butyl-3-methylphenol), 3,9′-bis{2-[3-(3-t-butyl-4-hydroxy-5-methylphenyl)propionyloxy]-1,1-dimethylethyl}-2,4,8,10-tetraoxaspiro[5.5]undecane, 2-(3,5-di-t-butyl-4-hydroxyanilino)-4,6-bis(n-octylthio)-1,3,5-triazine, 2,2′-ethyldenebis(4,6-di-t-butylphenol), 2,2′-ethylidenebis(4-sec-butyl-6-t-butylphenol), 2,2′-thiobis(6-t-butyl-3-methylphenol), 1,1,3-tris(5-t-butyl-4-hydroxy-2-methylphenyl)butane, bis[2-t-butyl-4-methyl-6-(3-t-butyl-2-hydroxy-5-methylbenzyl)phenyl]terephthalate, tetrakis[methylene-3-(3,5-di-t-butyl-4-hydroxyphenyl)propionate]methane, 2,2′-thiodiethyelenebis[3-(3,5-di-t-butyl-4-hydroxyphenyl)propionate], triethylene glycol bis[3-(3-t-butyl-4-hydroxy-5-methylphenyl)propionate], 1,6-hexanediolbis[3-(3,5-di-t-butyl-4-hydroxyphenyl)propionate], 1,3,5-tris(3,5-di-t-butyl-4-hydroxybenzyl) isocyanurate, 1,3,5-tris[2-{3-(3,5-di-t-butyl-4-hydroxyphenyl)propionyloxy}ethyl]isocyanurate, 1,3,5-tris(4-t-butyl-3-hydroxy-2,6-dimethylbenzyl) isocyanurate, and 1,3,5-tris(3,5-di-t-butyl-4-hydroxybenzyl)-2,4,6-trimethylbenzene.

In the invention, the sulfur containing antioxidant is not particularly limited, but examples include a compound represented by the following formula [B], and a compound represented by the formula [C].

S—(CH₂CH₂—COOR⁸)₂ [B]

In the formula [B], R⁸ represents an alkyl group, and is preferably an alkyl group having 12 to 18 carbon atoms.

(R⁹S—CH₂CH₂—COOCH₂)₄—C [C]

In the formula [C], R⁹ represents an alkyl group, and is preferably an alkyl group having 12 carbon atoms.

Examples of the sulfur containing antioxidant include dilauryl-3,3′-thiodipropionate, dimyristyl-3,3′-thiodipropionate, distearyl-3,3′-thiodipropionate, and tetrakis(3-laurylthiopropionyloxymetlhyl)methane.

In the invention, the phosphite antioxidant and the phosphonite antioxidant are not particularly limited, but examples include compounds represented by the following formulas [D] to [I].

P(OR¹⁰)₃ [D]

In the formula [D], R¹⁰ represents an optionally substituted alkyl group, or an optionally substituted aryl group.

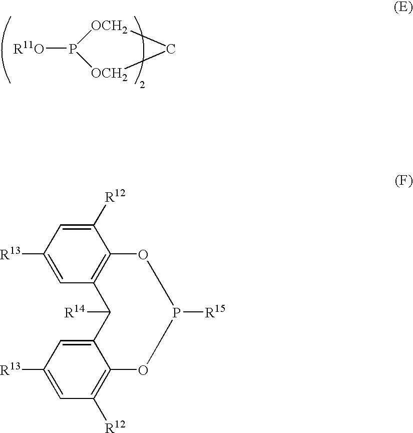

In the formulas [E] and [F], R¹¹ represents an optionally substituted alkyl group or an aryl group, R¹², R¹³, and R¹⁴ each represent independently a hydrogen atom or an alkyl group having 1 to 8 carbon atoms, and R¹⁵ represents a fluorine atom, an alkyl group, a hydroxy group, an alkoxy group, an amino group, a monoalkyl amino group, or a dialkyl amino group.

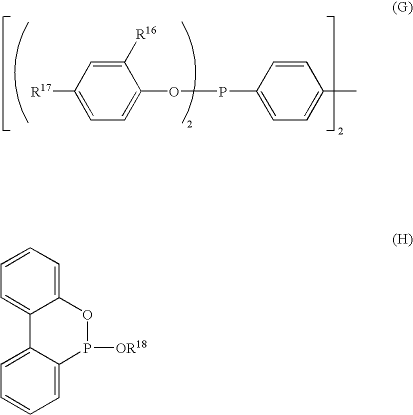

In the formulas [G] and [H], R¹⁶ and R¹⁷ each represent independently a hydrogen atom or an alkyl group, and R¹⁸ represents a hydrogen atom or an alkyl group, provided that when R¹⁸ is a hydrogen atom, a resonance structure represented by the following [I] is present, and this becomes a phosphinate compound.

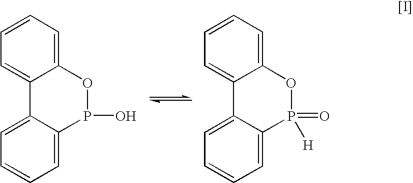

Examples of the phosphite antioxidant and phosphonite antioxidant include tris(nonylphenyl) phosphite, tris(2,4-di-t-butylphenyl) phosphite, tetrakis(2,4-di-t-butylphenyl)-4,4′-biphenylene diphosphonite, bis(2,4-di-t-butylphenyl)pentaerythritol diphosphite, bis(2,6-di-t-butylphenyl)pentaerythritol-diphosphite, distearylpentaerythritol-diphosphite, phenyldiisooctyl phosphite, phenyldiisodecyl phosphite, phenyldi(tridecyl) phosphite, diphenylisooctyl phosphite, diphenylisodecyl phosphite, diphenyltridecyl phosphite, 4,4′-isopropylidenebis(phenyldialkylphosphite), 2,2′-methylenebis(4,6-di-t-butylphenyl)octyl phosphite, and 2,2′-ethylidenebis(4,6-di-t-butylphenyl)fluorophosphonite.

In the invention, the hindered amine antioxidant is not particularly limited, but examples include preferably a compound having the following partial structure.

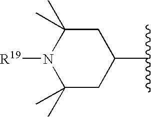

In the above formula, R¹⁹ represents a hydrogen atom or an optionally substituted alkyl group, and a wavy line part represents a binding position with another chemical structure.

Examples of the hindered amine antioxidant include bis(2,2,6,6-tetramethyl-4-piperidyl) sebacate, bis(N-methyl-2,2,6,6-tetramethyl-4-piperidyl) sebacate, N,N′-bis(2,2,6,6-tetramethyl-4-piperidyl)-1,6-hexamethylenediamine, 2-methyl-2-(2,2,6,6-tetramethyl-4-piperidyl)amino-N-(2,2,6,6-tetramethyl-4-piperidyl)propionamide, tetrakis(2,2,6,6-tetramethyl-4-piperidyl)-1,2,3,4-butanetetracarboxylate, poly{[6-(1,1,3,3-tetramethylbutyl)imino-1,3,5-triazine-2,4-diyl][(2,2,6,6-tetramethyl-4-piperidyl)imino]hexamethyl{(2,2,6,6-tetramethyl-4-piperidyl)imino}}, poly {(6-morpholino-1,3,5-triazine-2,4-diyl)[(2,2,6,6-tetramethyl-4-piperidyl)imino]hexamethine[(2,2,6,6-tetramethyl-4-piperidyl)imino]}, a polycondensate of dimethyl succinate and 1-(2-hydroxyethyl)-4-hydroxy-2,2,6,6-tetramethylpiperidene, and N,N′-4,7-tetrakis{4,6-bis[N-butyl-N-(1,2,2,6,6-pentamethyl-4-piperidyl)amino]-1,3,5-triazine-2-yl}-4,7-diazadecane-1,10-diamine.

Examples of other antioxidants include antioxidants described in each of JP-A Nos. 57-74192, 57-87989 and 60-72785, hydrazides described in JP-A No. 61-154989, hindered amine antioxidant described in JP-A No. 61-146591, a nitrogen-containing heterocyclic mercapto compound described in JP-A No. 61-177279, a thioether antioxidant described in JP-A Nos. 1-115677 and 1-36479, a hindered phenol antioxidant of a specified structure described in JP-A No. 1-36480, ascorbic acids described in JP-A Nos. 7-195824 and 8-150773, zinc sulfate described in JP-A No. 7-149037, thiocyanates described in JP-A No. 7-314882, a thiourea derivative described in JP-A No. 7-314883, sugars described in JP-A Nos. 7-276790 and 8-108617, a phosphoric acid antioxidant described in JP-A No. 8-118791, nitrite, sulfite and thiosulfate described in JP-A No. 8-300807, and a hydroxylamine derivative described in JP-A No. 9-267544. Further, a polycondensate of dicyandiamide and polyalkylenepolyamine described in JP-A No. 2000-263928 may be also used.

The antioxidant which may be used in the invention may be obtained by synthesis according to the known method, or may be easily available as a commercialized product.

In the invention, it is preferable that, as the antioxidant, the phenol antioxidant is used.

In addition, a stabilizer which is one of radical inhibitors is an additive which when the relief forming layer in the invention is constructed of an active light curing composition, may stabilize it.

In the invention, from a viewpoint of suppression of an odor due to a polymerization initiator, the deodorizer is preferably a compound having a phenolic hydroxyl group such as phenols, diphenols, polyphenols, hydroquinones, and dihydroquinones.

[Deodorant]

The deodorant used in the invention is not particularly limited, but examples include compounds described in “Advanced Deodorant and Deodorizing Technique (Industrial Technical Association)” and “New Deodorant, Development of Industrial Deodorant and Approach to Productization (Technical Information Institute Co., Ltd)”.

The deodorant which may be used in the invention is preferably a natural extraction component.

Examples of the natural extraction component include catechin, epigallocatechin, gallocatechin, epicatechin gallate, epigallocatechin gallate, gallotannin, and ellagitannin, which are extracts from plants such as catechins and tannins, extracts from natural products such as rosemary, sunflower seed, raw coffee, tea, fruit skin of grape, seed of grape, and apple, and components containing an enzyme which oxidizes a phenolic compound. In addition, polysaccharides, a representative of which is chitosan, and plant extraction components, representative of which is Japanese cypress oil, Korean houttuynia extract, and orange essential oil are preferable. Among them, catechins or tannins are preferable, and catechin, epicatechin gallate, and gallotannin are more preferable.

These deodorants may be used alone, or plural kinds of them may be used together.

In the invention, from a viewpoint of availability and general-use, it is preferable that the (C) compound having deodorizing ability is diphenols, polyphenols, hydroquinones, diarylamines, alkylated p-phenylenediamines, dihydroquinones, thioethers, or hindered amines, which are described above as the polymerization inhibitor; a phenol antioxidant (phenols), a phosphite antioxidant (phosphites), a phosphonite antioxidant (phosphonites), a sulfur containing antioxidant (thioethers), a hindered amine antioxidant (hindered amines), which are described above as the antioxidant; or catechins, tannins, extracts from natural products (natural product extracts), agent containing an enzyme which oxidizes a phenolic compound (phenolic compound oxidase), or polysaccharides, which are described above as a deodorant (natural extract component).

Among them, diphenols, polyphenols, hydroquinones, or dihydroquinones which are described above as the polymerization inhibitor, a phenol antioxidant (phenols) which is described above as the antioxidant, and a compound having a phenolic hydroxyl group such as catechins and tannins which are described above as the deodorant (natural extraction component) are preferably used. Among the compounds having a phenolic hydroxyl group, a compound having a plural phenolic hydroxyl groups is preferable. Particularly, a compound having 2 to 10 phenolic hydroxyl groups in one molecule is preferably used, and a compound having a catechol group or a pyrogallol group (more preferably, galloyl group) is further preferable. In addition, catechins having a flavane skeleton is preferably used, and catechins having 5 to 10 hydroxy groups is preferably used.

The following are examples of a preferable compound as the compound having deodorizing ability, but the invention is not limited by them.

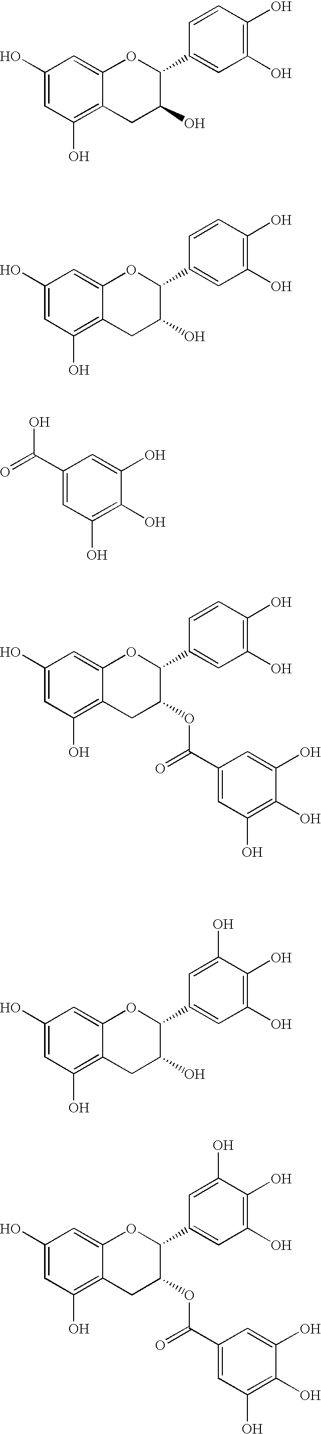

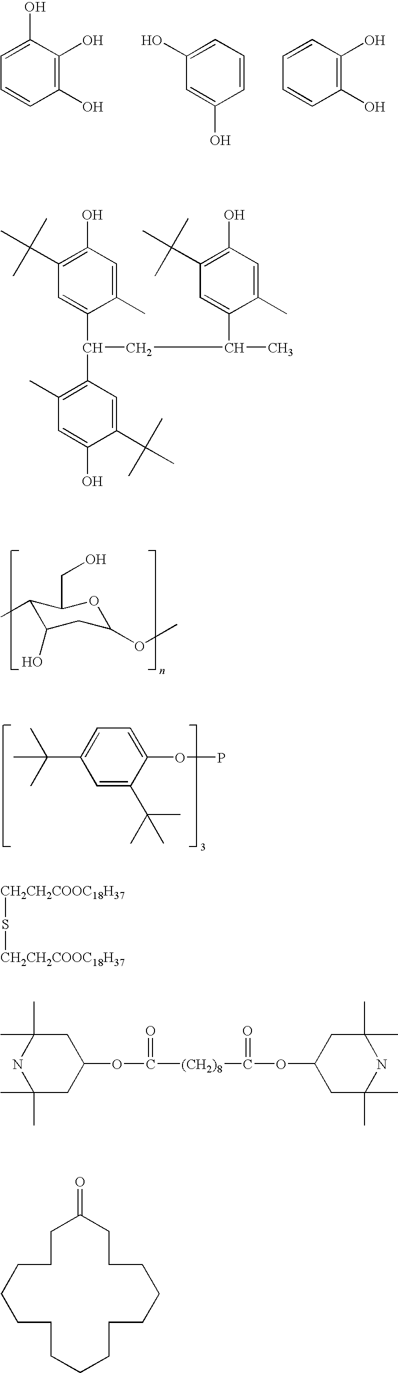

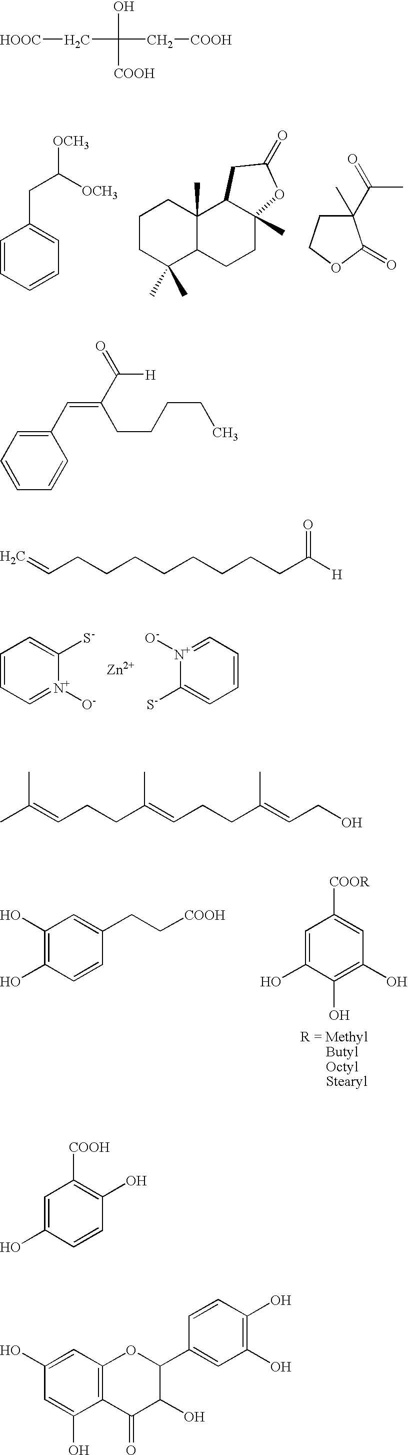

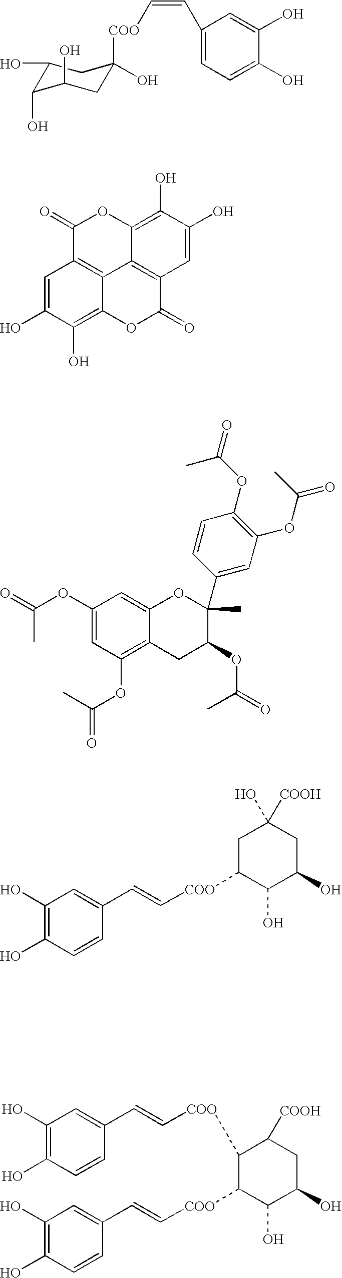

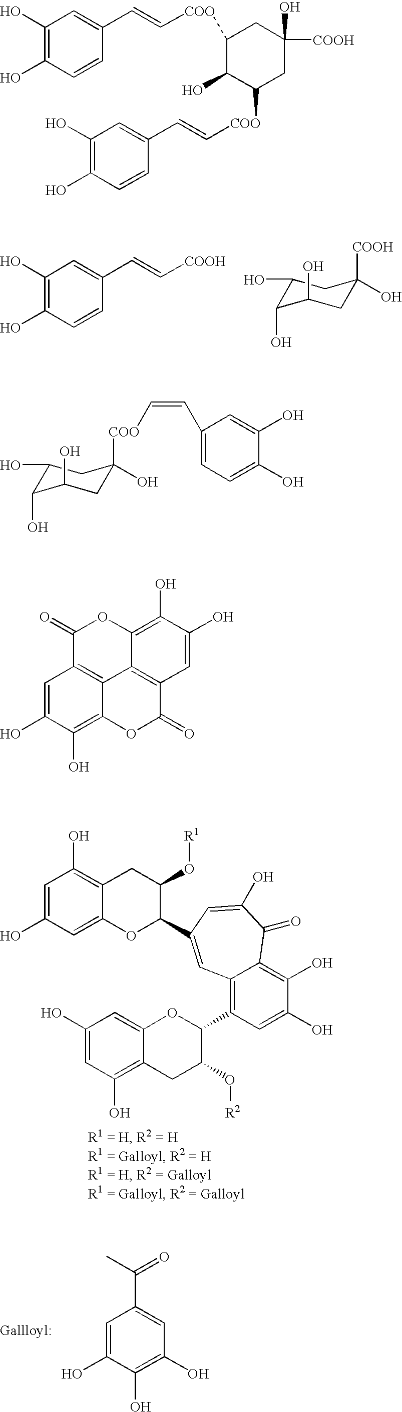

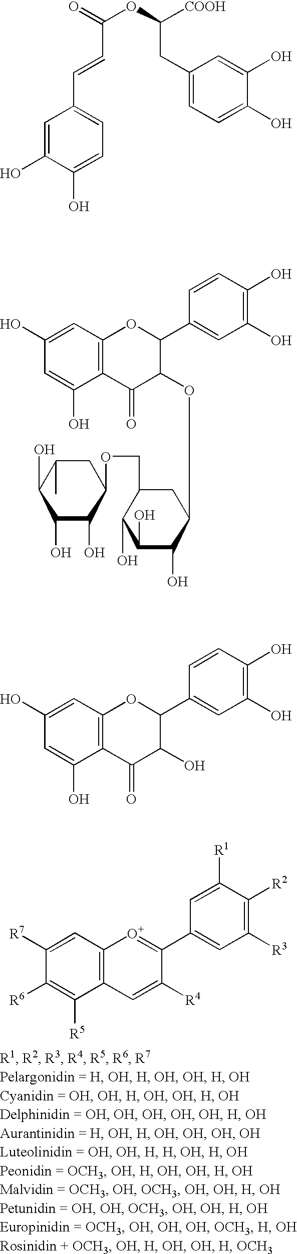

It is preferable that the compound having deodorizing ability used in the invention is at least one compound selected from polyphenols in that the deodorizing effect is high.

Herein, “polyphenols” in the invention is a compound having plural phenolic hydroxy groups, and examples thereof include not only compounds having plural aromatic rings having a hydroxy group, but also compounds having plural hydroxy groups on the same aromatic ring.

Particularly, the at least one compound selected from polyphenols is preferably a compound having at least one of a catechol group or a pyrogallol group, more preferably a compound having a functional group represented by the following structural formula (I). Among them, a catechin derivative is most preferable. Herein, “*” in the following structural formula is a site for binding to another structure.

Herein, examples of the catechin derivative include (+)-catechin, epicatechin, gallocatechin, epigallocatechin, and epigallocatachin gallate, and examples include a compound having a flavane structure as a fundamental skeleton, in which OH is introduced into an aromatic ring or an aliphatic cyclic ether ring in the structure, and a compound in which the OH is further modified with a substituent.

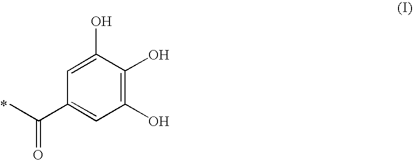

As described above, when a polyphenol is used as a compound having deodorizing ability, the effect of improving stability (pot life) of a coating liquid used in formation of a film is obtained in a combination with the sulfur-containing polyfunctional monomer. This reason is not clear, but OH groups in polyphenols or phenols and S atoms in the sulfur-containing polyfunctional monomer form hydrogen bond at many points and, as a result, polyphenols or phenols are present in vicinity with the sulfur-containing polyfunctional monomer. Generally, it is known that polyphenols or phenols have polymerization inhibiting effect and, as described above, by polyphenols or phenols being in vicinity with the sulfur-containing polyfunctional monomer, this polymerization inhibiting effect is enhanced and, it is presumed that as a result, the coating liquid stability is improved.

In addition, the compound having deodorizing ability used in the invention may be a compound having a polymerizable group and having deodorizing ability from a viewpoint of improvement in tackiness of the relief forming layer.

In the invention, preferable examples of the compound having a polymerizable group and having deodorizing ability include the following compound 1 to compound 20.

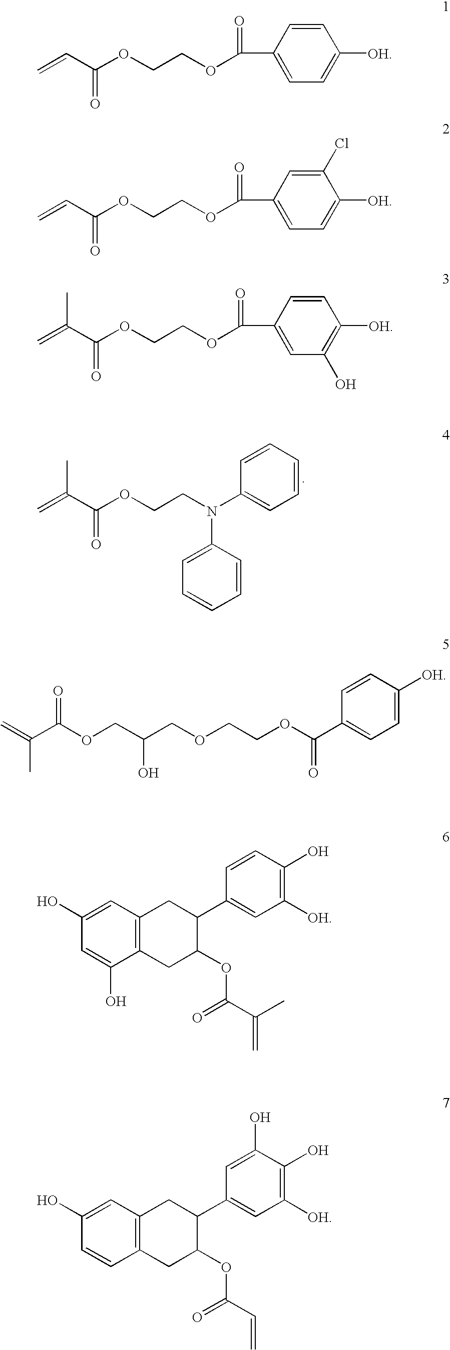

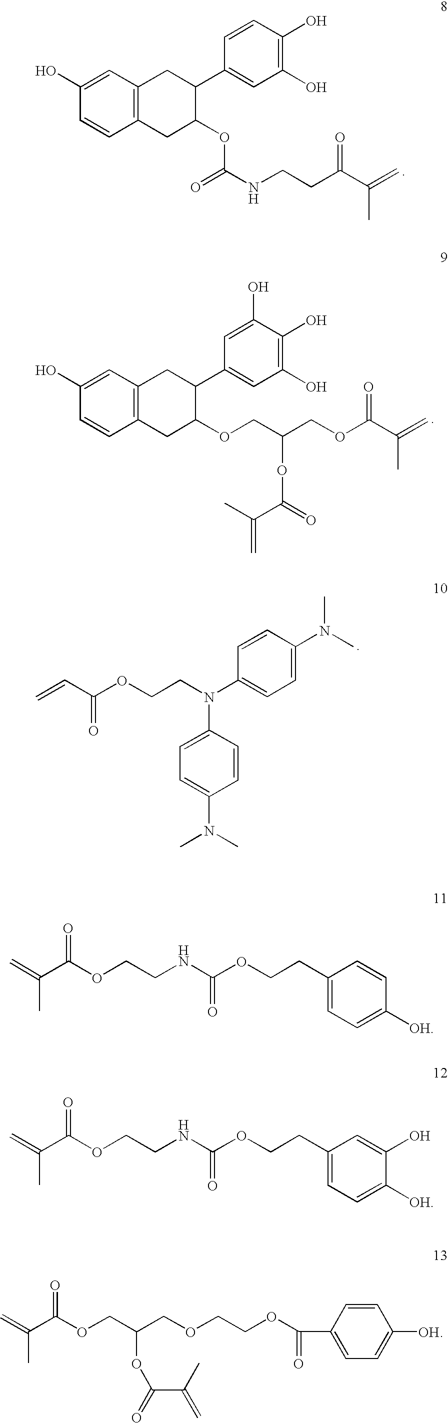

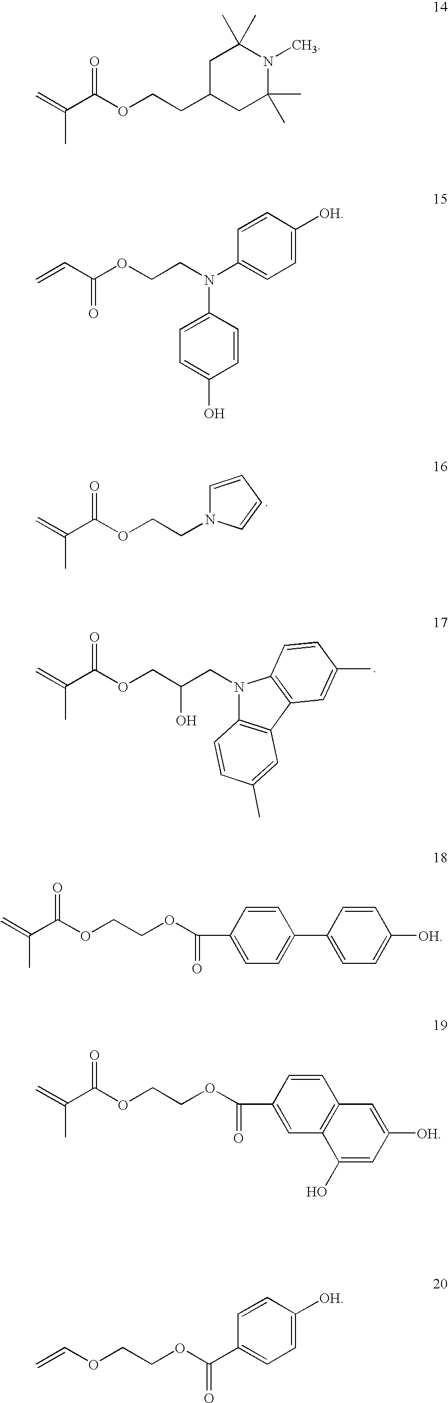

In addition, as an example of the compound having a polymerizable group and having deodorizing ability, compounds in which a partial structure represented by the following (Et-1) to (Et-3) is substituted with a partial structure represented by the following (Re-1) or (Re-2) in the compound 1 to compound 9 may be preferably exemplified.

A wavy line part in the following formula is a part binding with another structure.

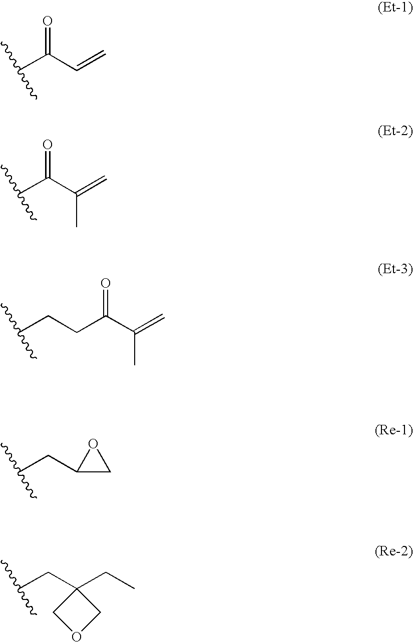

In the relief forming layer in the invention, the compound having deodorizing ability may by used alone, or a plural kinds may be used together.

As the compound having deodorizing ability, one of the deodorizer or the deodorant may be used, or the deodorizer and the deodorant may be used together.

When the deodorizer is used as the compound having deodorizing ability, an amount of this deodorizer to be added to the relief forming layer is preferably 0.01% by mass to 13% by mass, more preferably 0.05% by mass to 10% by mass relative to a total mass of the relief forming layer from a viewpoint of the odor reducing effect and curability of the relief forming layer.

When the deodorant is used as the compound having deodorizing ability, an amount of this deodorant to be added to the relief forming layer is preferably 0.01% by mass to 15% by mass, more preferably 0.05% by mass to 10% by mass relative to a total mass of the relief forming layer from a viewpoint of the odor reducing effect, a curing sensitivity of the relief forming layer, and a sufficient strength of a cured film.

An optional component preferably used in the relief forming layer in the invention will be explained below.

As the optional component, (D) a photothermal converting agent which may absorb light having a wavelength of 700 nm to 1,300 nm, and a polymerization initiator are preferably used.

<(D) Photothermal Converting Agent>

It is preferable that the relief forming layer in the invention contains the (D) photothermal converting agent. It is thought that the photothermal converting agent promotes thermal decomposition of the relief forming layer by absorption of light of laser and heat production. Therefore, it is preferable that a photothermal converting agent which absorbs light having a laser wavelength used in engraving is selected.

When a laser emitting infrared ray having a wavelength of 700 nm to 1,300 nm (YAG laser, semiconductor laser, fiber laser, plane emission laser etc.) is used as a light source in a laser engraving, it is preferable that the relief forming layer in the invention contains a photothermal converting agent which may absorb light having a wavelength of 700 nm to 1,300 nm.

As the photothermal converting agent in the invention, various dyes or pigments are used.

Among the photothermal converting agents, as the dye, commercially available dyes, and the known dyes described in a reference such as “Dye Handbook” (edited by The Society of Synthetic Organic Chemistry, Japan, published in 1970) may be utilized. Specifically, examples include dyes such as azo dyes, metal complex salts azo dyes, pyrazoloneazo dyes, naphthoquinone dyes, anthraquinone dyes, phthalocyanine dyes, carbonium dyes, diinmmonium compounds, quinoneimine dyes, methine dyes, cyanine dyes, squarylium coloring matters, pyrilium salts, and metal thiolate complexes.

Examples of the dye preferably used in the invention include dyes described in paragraphs [0124] to [0137] of JP-A No. 2008-63554.

One of preferable photothermal converting agents in the invention is at least one compound selected from the cyanine compound and the phthalocyanine compound from a viewpoint of a high engraving sensitivity. Further, when these photothermal converting agents are used in such a combination (condition) that thermal decomposition temperatures of them are equivalent or higher than a thermal decomposition temperature of a hydrophilic polymer preferable as the binder polymer, an engraving sensitivity tends to be further increased.

In addition, among the photothermal converting agents used in the invention, as the dyes, a dye having absorption maximum at the wavelength of 700 nm to 1,300 nm is preferable.

Examples of the dye which may be preferably used in the invention include dyes having a maximum absorption wavelength at 700 nm to 1,300 nm among cyanine coloring matters such as a heptamethinecyanine coloring matter, oxonol coloring matters such as a pentamethineoxonol coloring matter, indolium coloring matters, benzindolium coloring matters, benzthiazolium coloring matters, quinolinium coloring matters, and phthalide compounds which have been reacted with a developer. Light absorbing property is extremely greatly changed depending on the kind of a substituent and a position thereof in a molecule, the number of conjugate bonds, the kind of counter ions, and the surrounding environment in which a coloring matter molecule is present.

Generally commercially available laser coloring matters, supersaturated absorbing coloring matters, and near infrared absorbing coloring matters may be used. Examples of the laser coloring matter include products with trademarks “ADS740PP”, “ADS745HT”, “ADS760MP”, “ADS740WS”, “ADS765WS”, “ADS745HO”, “ADS790NH”, and “ADS800NH” of American Dye Source (Canada), and products with trademarks “NK-3555”, “NK-3509”, and “NK-3519” manufactured by Hayashibara Biochemical Labs, Inc. Examples of the near infrared absorbing coloring matter include products with trademarks “ADS775MI”, “ADS775MP”, “ADS775HI”, “ADS775PI”, “ADS775PP”, “ADS780MT”, “ADS780BP”, “ADS793EI”, “ADS798MI”, “ADS798MP”, “ADS800AT”, “ADS805PI”, “ADS805PP”, “ADS805PA”, “ADS805 PF”, “ADS812MI”, “ADS815EI”, “ADS818HI”, “ADS818HT”, “ADS822MT”, “ADS830AT”, “ADS838MT”, “ADS840MT”, “ADS845BI”, “ADS905AM”, “ADS956BI, “ADS1040T”, “ADS1040P”, “ADS1045P”, “ADS1050P”, “ADS1060A”, “ADS1065A”, “ADS1065P”, “ADS1100T”, “ADS1120F”, “ADS1120P”, “ADS780WS”, “ADS785WA”, “ADS790WS”, “ADS805WS”, “ADS820WS”, “ADS830WS”, “ADS850WS”, “ADS780HO”, “ADS810CO”, “ADS820HO”, “ADS821NH”, “ADS840NH”, “ADS880MC”, “ADS890MC” and “ADS920MC” manufactured by American Dye Source (Canada), products with trademarks “YKR-2200”, “YKR-2081”, “YKR-2900”, “YKR-2100”, and “YKR-3071” manufactured by Yamamoto Chemicals Inc., a product with trademark “SDO-1000B” manufactured by Arimoto Chemical Co., Ltd., and products with trademarks “NK-3508” and “NKX-114” manufactured by Hayashibara Biochemical Labs, Inc. Examples are not limited to them.

Among the photothermal converting agents used in the invention, as the pigment, commercially available pigments and pigments described in Color Index (C.I.) Handbook, “Advanced Pigment Handbook” (edited by Japan Pigment Technique Association, published in 1977), “Advanced Pigment Application Technique” (CMC Press, published in 1986), and “Printing Ink Technique” (CMC Press, published in 1984) may be utilized.

Examples of the kind of the pigment include black pigments, yellow pigments, orange pigments, brown pigments, red pigments, purple pigments, blue pigments, green pigments, fluorescent pigments, metal powder pigments, and polymer binding coloring matters. Specifically, insoluble azo pigments, azo lake pigments, condensed azo pigments, chelate azo pigments, phthalocyanine pigments, anthraquinone pigments, perylene and perynone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, and carbon blacks may be used. Among these pigments, carbon black is preferable.

As carbon black, any carbon black in addition to carbon blacks according to classification by ATSM may be used regardless of utility (e.g. for color, for rubber, for dry cell etc.) as far as dispersibility in a coating liquid composition for the relief forming layer is stable. Examples of carbon black include furnace black, thermal black, channel black, lamp black, and acetylene black. The black coloring agent such as carbon black may be used as a color chip or a color paste in which the agent has been dispersed in nitrocellulose or a binder in advance using, if necessary, a disperser in order to make dispersing easy, and such chip and paste are easily available as a commercialized product.

In the invention, from carbon black having a relatively low specific surface area and relatively low DBP absorption to finely-divided carbon black having a large specific surface area may be used. Examples of preferable carbon black include Printex (registered trademark) U, Printex (registered trademark) A, and Spezialschwarz (registered trademark) 4 (from Degussa).

As carbon black which may be applied to the invention, conductive carbon black having a specific surface area of at least 150 m²/g and a DBP number of at least 150 ml/100 g is preferable from a viewpoint that the engraving sensitivity is improved by effective conduction of heat generated by photothermal conversion to the surrounding polymer.

This specific surface area is preferably at least 250, particularly preferably at least 500 m²/g. The DBP number is preferably at least 200, particularly preferably at least 250 ml/100 g. The carbon black may be acidic or basic carbon black. Carbon black is preferably basic carbon black. A mixture of different carbon blacks may be naturally used.

Suitable conductive carbon black having a specific surface area of up to about 1,500 m²/g and a DBP number of up to about 550 ml/100 g is commercially available under the name of, for example, Ketjennlack (registered trademark) EC300J, Ketjennlack (registered trademark) EC600J (from Akzo), Prinrex (registered trademark) XE (from Degussa) or Black Pearls (registered trademark) 2000 (from Cabot), or Ketjenn Black (manufactured by Lion).

The content of the photothermal converting agent in the relief forming layer is greatly different depending on the molecular light absorption coefficient inherent to the molecule, and is preferably in the range of 0.01% by mass to 20% by mass, more preferably 0.05% by mass to 10% by mass, particularly preferably 0.1% by mass to 5% by mass relative to the total mass of the relief forming layer.

<(E) Polymerization Initiator>

The relief forming layer in the invention preferably contains (E) a polymerization initiator.

As the polymerization initiator, polymerization initiators known to a person skilled in the art may be used without limitation. Specifically, many are described in, for example, Bruce M. Monroe et al, “Chemical Review, 93, 435 (1993)” and R. S. Davidson et al., “Journal of Photochemistry and Biology A: Chemistry, 73.81 (1993)”; J. P. Faussier, “Photoinitiated Polymerization-Therapy and Applications”: Rapra Review vol. 9, Report, Rapra Technology (1998); M. Tsunooka et al., Prog. Polym. Sci., 21, 1 (1996). In addition, a compound group which oxidatively or reductively generates bond cleavage, as described in F. D. Saeva, Topics in Current Chemistry, 156, 59 (1990); G. G. Maslak, Topics in Current Chemistry, 168, 1 (1993); H. B. Shuster et al., JACS, 112, 6329 (1990); I. D. F. Eaton et al., JACS, 102, 3298 (1980) is also known.

Regarding an embodiment of a preferable polymerization initiator, a radical polymerization initiator which generates a radical by light and/or heat energy, and initiates and promotes a polymerization reaction of a polymerizale compound will be described in detail below, but the invention is not limited by these descriptions.

In the invention, examples of a preferable radical polymerization initiator include (a) aromatic ketones, (b) an onium salt compound, (c) organic peroxide, (d) a thio compound, (e) a hexaarylbiimidazole compound, (f) a ketooxime ester compound, (g) a borate compound, (h) an azinium compound, (i) a metallocene compound, (j) an active ester compound, (k) a compound having a carbon halogen bond, and (l) an azo compound. The following are examples of (a) to (l), but the invention is not limited by them.

In the invention, (c) organic peroxide and (l) an azo compound are more preferable, and (c) organic peroxide is particularly preferable from a viewpoint of that the sensitivity and the relief edge shape are made to be good.

Usually, when the hardness is increased in order to make the edge shape of the relief good, the engraving sensitivity is decreased, but by using the sulfur-containing polyfunctional monomer listed as a preferable embodiment of the polymerizable compound and the preferable polymerization initiator as described above, the edge shape may be made to be better without decreasing the engraving sensitivity. This is probably because due to formation of the interaction between a sulfur atom of the sulfur-containing polyfunctional monomer and an oxygen atom or a nitrogen atom in the polymerization initiator, and presence of both components in vicinity to each other, the polymerization degree is increased, and the hardness is increased, and thereby, the edge shape is made to be good and, at the same time, due to low temperature thermal decomposition property of the sulfur-containing polyfunctional monomer, reduction in the sensitivity due to the increased polymerization degree is suppressed.

As the (a) aromatic ketones, the (b) onium salt compound, the (d) thio compound, the (e) hexaaryl biimidazole compound, the (f) ketooxime ester compound, the (g) borate compound, the (h) azinium compound, the (i) metallocene compound, the (j) active ester compound, and the (k) compound having a carbon halogen bond, compounds listed in paragraphs [0074] to [0118] of JP-A No. 2008-63554 may be preferably used.

As the (c) organic peroxide and the (l) azo compounds, the following compounds are preferable.

(c) Organic Peroxide

Examples of a preferable (c) organic peroxide as the radical polymerization initiator which may be used in the invention include almost all organic compounds having one or more oxygen-oxygen bonds in a molecule, but examples include methyl ethyl ketone peroxide, cyclohexanone peroxide, 3,3,5-trimethylcyclohexanone peroxide, methylcyclohexanone peroxide, acetylacetone peroxide, 1,1-bis(tertiarybutylperoxy)-3,3,5-trimethylcyclohexane, 1,1-bis(tertiarybutylperoxy)cyclohexane, 2,2-bis(tertiarybutylperoxy)butane, tertiarybutyl hydroperoxide, cumene hydroperoxide, diisopropylbenzene hydroperoxide, paramethane hydroperoxide, 2,5-dimethylhexane-2,5-dihydroperoxide, 1,1,3,3-tetramethylbutyl hydroperoxide, di-tertiarybutyl peroxide, tertiarybutylcumyl peroxide, dicumylperoxide, bis(tertiarybutylperoxyisobutyl)benzene, 2,5-dimethyl-2,5-di(tertiarybutylperoxy)hexane, 2,5-xanoyl peroxide, succinic peroxide, benzoyl peroxide, 2,4-dichlorobenzoyl peroxide, meta-toluoyl peroxide, diisopropyl peroxydicarbonate, di-2-ethylhexylperoxy dicarbonate, di-2-ethoxyethylperoxy dicarbonate, dimethoxyisopropylperoxy carbonate, di(3-methyl-3-methoxybutyl)peroxy dicarbonate, tertiarybutylperoxy acetate, tertiarybutylperoxy pivalate, tertiarybutylperoxy neodecanoate, tertiarybutylperoxy octanoate, tertiarybutylperoxy-3,5,5-trimethylhexanoate, tertiarybutylperoxy laurate, tertiary carbonate, 3,3′,4,4′-tetra-(t-butylperoxycarbonyl)benzophenone, 3,3′,4,4′-tetra-(t-amylperoxycarbonyl)benzophenone, 3,3′,4,4′-tetra-(t-hexylperoxycarbonyl)benzophenone, 3,3′,4,4′-tetra-(t-octylperoxycarbonyl)benzophenone, 3,3′,4,4′-tetra-(cumylperoxycarbonyl)benzophenone, 3,3′,4,4′-tetra-(p-isopropylcumylperoxycarbonyl)benzophenone, carbonyldi(t-butylperoxy dihydrogen diphthalate), and carbonyldi(t-hexylperoxy dihydrogen diphthalate).

Among them, ester peroxides such as 3,3′,4,4′-tetra-(t-butylperoxycarbonyl)benzophenone, 3,3′,4,4′-tetra-(t-amylperoxycarbonyl)benzophenone, 3,3′,4,4′-tetra-(t-hexylperoxycarbonyl)benzophenone, 3,3′,4,4′-tetra-(t-octylperoxycarbonyl)benzophenone, 3,3′,4,4′-tetra-(cumylperoxycarbonyl)benzophenone, 3,3′,4,4′-tetra-(p-isopropylcumylperoxycarbonyl)benzophenone, and di-t-butyldiperoxy isophthalate are preferable.

### (1) Azo Compound

Examples of a preferable (1) azo compound as the radical polymerization initiator which may be used in the invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamidoxime), 2,2′-azobis[2-(2-imidazolin-2-yl)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], and 2,2′-azobis(2,4,4-trimethylpentane).

The polymerization initiator in the invention may be used alone, or two or more kinds may be used together.

The polymerization initiator may be added at the ratio of preferably 0.01% by mass to 10% by mass, more preferably 0.1% by mass to 3% by mass relative to the total mass of the relief forming layer.

<Other Additives>

It is preferable that the relief forming layer in the invention contains a plasticizer.

It is necessary that the plasticizer has the action of softening the relief forming layer, and has good compatibility with the binder polymer.

As the plasticizer, for example, dioctyl phthalate, didodecyl phthalate, polyethylene glycols, polypropylene glycol, (monool type or diol type), and polypropylene glycol (monool type or diol type) are preferably used.

It is more preferable that nitrocellulose or a highly thermal conductive substance as an additive for improving the engraving sensitivity is added to the relief forming layer in the invention.

Since nitrocellulose is a self-reacting compound, at laser engraving, nitrocellulose itself produces heat, and assists thermal decomposition of the binder polymer such as a hydrophilic polymer. As a result, it is presumed that the engraving sensitivity is improved.

In addition, the highly thermal conductive substance is added for the purpose of assisting thermal conduction, and examples of the thermal conductive substance include inorganic compounds such as metal particles, and organic compounds such as an electrically conductive polymer.

Examples of the metal particles include a gold fine particle, a silver fine particle, and a copper fine particle having a particle diameter of a micrometer order to a few nano meter order and, as the electrically conductive polymer, a conjugated polymer is particularly preferable, and examples include polyaniline, and polythiophene.

In addition, by using a cosensitizer, the sensitivity upon light curing of the relief forming layer may be further improved.

Further, the relief forming layer may contain a small amount of a thermal polymerization inhibitor. This thermal polymerization inhibitor is used for the purpose of arresting unnecessary thermal polymerization of the polymerizable compound during production or during storage of the relief forming layer.

Further, for the purpose of coloring the relief forming layer, a coloring agent such as a dye and a pigment may be added. Thereby, a nature of visibility of an image area, and image concentration measuring machine suitability may be improved.

Further, in order to improve physical property upon curing of the relief forming layer, the known additive such as a filler may be added.

<Construction of Relief Printing Plate Precursor>

A relief printing plate precursor for laser engraving of the invention has a relief forming layer constructed of the aforementioned respective components. It is preferable that this relief forming layer is provided on a support.

Herein, in the invention, the “relief printing plate precursor for laser engraving” refers to the state where a relief forming layer having crosslinkability is cured by at least one of light or heat. Thereafter, by laser-engraving this relief printing plate precursor, a “relief printing plate” is prepared.

The relief printing plate precursor of the invention may have, if necessary, an adhesive layer between the support and the relief forming layer, and may have a slip coating layer and a protecting film on the relief forming layer.

Constitutional elements of the relief printing plate precursor of the invention will be explained below.

<Relief Forming Layer>

It is preferable that the relief forming layer is constructed of the aforementioned respective components, and is a layer which is cured by at least one of light or heat, that is, a layer having crosslinkability.

An embodiment of producing a relief printing plate from the relief printing plate precursor of the invention is preferably an embodiment in which a relief printing plate is produced by forming a relief layer by crosslinking a relief forming layer and, then, laser-engraving this. By crosslinking the relief forming layer, wear of the relief layer at printing may be prevented, and a relief printing plate having the relief layer having a sharp shape may be obtained after laser engraving.

The relief forming layer may be formed by using a coating liquid composition for the relief forming layer, and molding this into a sheet or a sleeve.

<Support>

The support which may be used in the relief printing plate precursor of the invention will be explained.

A material used in the support for the relief printing plate precursor of the invention is not particularly limited, and a material having high size stability is preferably used, and examples include metals such as steel, stainless and aluminum, plastic resins such as polyester (e.g. PET, PBT, PAN) and polyvinyl chloride, synthetic rubbers such as a styrene-butadiene rubber, and plastic resins (such as epoxy resin and phenol resin) reinforced with a glass fiber. As the support, a PET (polyethylene terephthalate) film and a steel substrate are preferably used. A form of the support is determined depending on whether the relief forming layer is sheet-like or sleeve-like.

<Adhesive Layer>

In the relief printing plate precursor of the invention, between the relief forming layer and the support, an adhesive layer may be provided for the purpose of strengthening an adhesive force between both layers.

A material which may be used in the adhesive layer may be a material which enhances an adhesive force after crosslinking of the relief forming layer, and it is preferable that an adhesive force is great also before crosslinking of the relief forming layer. Herein, the adhesive force means both of an adhesive force between the support/the adhesive layer and an adhesive force between the adhesive layer/the relief forming layer.

The adhesive force between the support/the adhesive layer is such that, upon peeling of the adhesive layer and the relief forming layer from a laminate consisting of the support/the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

The adhesive force of the adhesive layer/the relief forming layer is such that, upon peeling of the adhesive layer from the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

As a material which may be used in the adhesive layer (adhesive), for example, a material described in I. Skeist, “Handbook of Adhesives”, second edition (1977) may be used.

<Protecting Film, Slip Coating Layer>

The relief forming layer becomes a part in which a relief is formed (relief layer) after laser engraving, and a surface of the relief layer functions as an inking part. Since the relief forming layer after crosslinking is strengthened by crosslinking, a flaw or a recess on a surface of the relief forming layer influencing on printing is generated rarely. However, a strength of the relief forming layer before crosslinking is insufficient in many cases, and a flaw or a recess is easily formed on a surface. From such a point of view, a protecting film may be provided on a surface of the relief forming layer for the purpose of preventing a flaw or a recess on a surface of the relief forming layer.

When the protecting film is too thin, the flaw/recess preventing effect is not obtained and, when the protecting film is too thick, handling becomes inconvenient, and the cost becomes high. Therefore, a thickness of the protecting film is preferably 25 μm to 500 μm, more preferably 50 μm to 200 μm.

In the protecting film, a material known as the protecting film of the printing plate, for example, a polyester film such as PET (polyethylene terephthalate), and a polyolefin film such as PE (polyethylene) and PP (polypropylene) may be used. A surface of the film may be plain, or may be matted.

When the protecting film is provided on the relief forming layer, the protecting film should be peelable.

When the protecting film is unpeelable, or when the protecting film is hardly adhered on the relief forming layer, a slip coating layer may be provided between both layers.

A material used in the slip coating layer is preferably a material containing, as a main component, a resin which is soluble or dispersible in water, and has little adhering property, such as polyvinyl alcohol, polyvinyl acetate, partially saponified polyvinyl alcohol, hydroxyalkylcellulose, alkylcellulose, and polyamide resin. Among them, from a viewpoint of adhering property, partially saponified polyvinyl alcohol having a saponification degree of 60 mol % to 99 mol %, and hydroxyalkylcellulose and alkylcellulose having an alkyl group having 1 to 5 carbon atoms are particularly preferably used.

When the protecting film is peeled from the relief forming layer (and the slip coating layer)/the protecting film at the rate of 200 mm/min, the peeling force per 1 cm is preferably 5 mN/cm to 200 mN/cm, further preferably 10 mN/cm to 150 mN/cm. When the peeling force is 5 mN/cm or more, working may be performed without peeling of the protecting film during working and, when the peeling force is 200 mN/cm or less, the peeling film may be peeled naturally.

—Process for Producing Relief Printing Plate Precursor for Laser Engraving—

Then, a process for producing a relief printing plate precursor for laser engraving will be explained.

Formation of the relief forming layer in the relief printing plate precursor for laser engraving is not particularly limited, but there is a process of preparing a coating liquid composition for the relief forming layer, removing a solvent from this coating liquid composition for the relief forming layer and, thereafter, performing melt extrusion on a support. Alternatively, a process of casting the coating liquid composition for the relief forming layer on a support, and drying this in an oven to remove a solvent from the coating liquid composition may be used.

Thereafter, if necessary, the protecting film may be laminated on the relief forming layer. Lamination may be performed by pressing the protecting film and the relief forming layer with a heated calendar roll, or adhering the protecting film to the relief forming layer having a surface impregnated with a small amount of a solvent.

When the protecting film is used, a process of first laminating the relief forming layer on the protecting film and, then, laminating the support may be adopted.

When the adhesive layer is provided, the support coated with an adhesive layer may be used. When the slip coating layer is provided, the protecting film coated with a slip coating layer may be used.

The coating liquid composition for the relief forming layer may be produced, for example, by dissolving a binder polymer and, as an optional component, a photothermal converting agent and a plasticizer in a suitable solvent and, then, dissolving a polymerizable compound and a polymerization initiator.

Since most of a solvent component is necessary to be removed at a stage of producing the relief printing plate precursor, it is preferable that, as a solvent, an easily vaporized low-molecular alcohol (e.g. methanol, ethanol, n-propanol, isopropanol, propylene glycol monomethyl ether) is used, and the total addition amount of the solvent is suppressed as less as possible. When a temperature of the system is high, an addition amount of the solvent may be suppressed, but when a temperature is too high, since a polymerizable compound is easily polymerization-reacted, a temperature for preparing a coating liquid composition after addition of the polymerizable compound and/or the polymerization initiator is preferably 30° C. to 80° C.

Herein, in the invention, the relief printing plate precursor for laser engraving refers to the state where the relief forming layer is crosslinked as described above. In a method of crosslinking the relief forming layer, it is preferable to perform a step of crosslinking the relief forming layer by irradiation with active light and/or heating (step (1) in a process of producing the relief printing plate of the invention described later).

A thickness of the relief forming layer in the relief printing plate precursor of the invention is preferably 0.05 mm or more but 10 mm or less, more preferably 0.05 mm or more but 7 mm or less, particularly preferably 0.05 mm or more but 3 mm or less.

[Relief Printing Plate and Process for Producing the Same]

A process for producing the relief printing plate of the invention is characterized in that it includes (1) a step of crosslinking an uncrosslinked relief forming layer in the relief printing plate precursor for laser engraving of the invention by at least one of irradiation with active light or heating (hereinafter, conveniently referred to as “step (1)”), and (2) a step of laser-engraving a crosslinked relief forming layer to form a relief layer (hereinafter, conveniently referred to as “step (2)”). By the process for producing the relief printing plate of the invention, the relief printing plate of the invention having a relief layer on a support may be produced.

<Step (1)>

The relief printing plate precursor for laser engraving of the invention has a relief forming layer in the state where it is cured by crosslinking, as described above. In order to obtain such a relief forming layer, it is preferable to use a step of crosslinking an uncrosslinked relief forming layer in the relief printing plate precursor for laser engraving of the invention by irradiation with active light and/or heating.

“Crosslinking” in the invention is a concept including a crosslinking reaction to connect binder polymers to each other, and is a concept also including a curing reaction of a relief forming layer by a polymerization reaction between polymerizable compounds having an ethylenic unsaturated bond or a reaction between a binder polymer and a polymerizable compound:

As described above, in the step (1), crosslinking of an uncrosslinked relief forming layer is performed by irradiation with active light and/or heat.

In the step (1), when a step of crosslinking by light, and a step of crosslinking by heat are used together, these steps may be performed simultaneously or separately.

The step (1) is a step of crosslinking a relief forming layer of the relief printing plate precursor for laser engraving by at least one of irradiation or heating.

The relief forming layer preferably contains a polymerizable compound, a binder polymer, a photothermal converting agent, and a polymerization initiator, and the step (1) is a step of polymerizing a polymerizable compound by the action of the polymerization initiator to form crosslinking.

The polymerization initiator is preferably a radical generator, and the radical generator is roughly classified into a photopolymerization initiator and a thermal polymerization initiator, depending on whether triggering for generating a radical is light or heat.

When the relief forming layer contains a photopolymerization initiator, the relief forming layer may be crosslinked by irradiating the relief forming layer with active light which is triggering of the photopolymerization initiator (step of crosslinking by light).

Irradiation with active light is generally performed on a whole surface of the relief forming layer. Examples of active light include visible light, ultraviolet light and electron beam, and ultraviolet light is most general. If a support side of the relief forming layer is a back side, it is enough that only a surface side is irradiated with active light, but when the support is a transparent film through which active light transmits, it is preferable that active light is irradiated also from a back side. Irradiation from a surface side, when there is a protecting film, may be performed while the protecting film is provided, or irradiation may be performed after peeling of the protecting film. Since polymerization inhibition may be generated in the presence of oxygen, active light may be irradiated after the relief forming layer is covered with a vinyl chloride sheet, and the system is evacuated.

When the relief forming layer contains a thermal polymerization initiator (the photopolymerization initiator may become the thermal polymerization initiator), the relief forming layer may be crosslinked by heating the relief printing plate precursor for laser engraving (step of crosslinking by heat). Examples of a heating means include a method of heating the printing plate precursor in a hot air oven or a far infrared oven for a predetermined time, and a method of contacting with a heated roll for a predetermined time.

When the step (1) is a step of crosslinking by light, although an apparatus for irradiating active light is of relatively high cost, a temperature of the printing plate precursor does not become high, therefore, there is little limitation of a raw material of the printing plate precursor.

When the step (1) is a step of crosslinking by heating, although there is an advantage that a particularly high cost apparatus is not necessary, a temperature of the printing plate precursor becomes high, therefore, it is necessary to carefully select a raw material to be used, because of possibility that a thermoplastic polymer which is softened at a high temperature is deformed during heating.

Upon thermal crosslinking, a thermal polymerization initiator may be added. The thermal polymerization initiator may be a commercial thermal polymerization initiator for free radical polymerization. Examples of such a thermal polymerization initiator include suitable peroxide, hydroperoxide, and a compound containing an azo group. A representative vulcanizing agent may be used for crosslinking. By adding a heat-curable resin, for example, an epoxy resin as a crosslinking component to a layer, thermal crosslinking may be implemented.

As a method of crosslinking the relief forming layer in the step (1), thermal crosslinking is preferable from a viewpoint that the relief forming layer may be uniformly cured (crosslinked) from a surface to an inside.

By crosslinking the relief forming layer, there is an advantage that, first, a relief formed after laser engraving becomes sharp and, secondarily, tackiness of an engraving waste generated upon laser engraving is suppressed. When an uncrosslinked relief forming layer is laser-engraved, a part of the layer tends to be unintentionally melted and deformed due to afterheat transmitted to the surrounding of a laser irradiation part, and a sharp relief layer is not obtained in some cases. In addition, as a general nature of a material, as a material is lower-molecular, it becomes not solid but liquid, that is, there is a tendency that tackiness is enhanced. There is a tendency that as a low-molecular material is used more, tackiness of an engraving waste generated upon engraving of the relief forming layer becomes high. Since a polymerizable compound which is low-molecular becomes a polymer by crosslinking, tackiness of a generated engraving waste becomes low.

<Step (2)>

The process for producing the relief printing plate of the invention is characterized in that, after the step (1), (2) a step of laser-engraving the crosslinked relief forming layer to form a relief layer is performed. By the process for producing the relief printing plate of the invention, the relief printing plate of the invention having a relief layer on a support may be produced.

The process for producing the relief printing plate of the invention may further include, if necessary, following step (3) to step (5) subsequent to the step (2).

Step (3): a step of rinsing a surface of the relief layer after engraving with water or a liquid containing water as a main component (rinsing step).

Step (4): a step of drying the engraved relief layer (drying step).

Step (5): a step of applying energy to the relief layer after engraving to further crosslinking the relief layer (post-crosslinking step).

The step (2) is a step of laser-engraving the relief forming layer crosslinked in the step (1) to form a relief layer. Specifically, by performing engraving by irradiating the crosslinked relief forming layer with laser light corresponding to an image to be formed, a relief layer is formed. Preferably, there is a step of scanning-irradiating the relief forming layer by controlling a laser head with a computer based on digital data of an image which is intended to be formed.

In this step (2), infrared laser is preferably used. When infrared laser is irradiated, molecules in the relief forming layer are vibrated to generate heat. When high output laser such as carbon dioxide gas laser and YAG laser is used as infrared laser, a large amount of heat is generated at a laser-irradiated part, and molecules in the relief forming layer are cut or ionized, thereby, selective removal, that is, engraving is implemented. An advantage of laser engraving is that since an engraving depth may be arbitrarily set, a structure may be three-dimensionally controlled. For example, at a part on which a fine dot is printed, a relief may be prevented from falling with a printing pressure, by engraving shallowly or with a shoulder and, at a groove part on which a fine outline letter is printed, it becomes difficult to fill the groove with an ink by engraving deeply, and unclear outline letter may be suppressed.

Inter alia, when engraving is performed with infrared laser corresponding to the absorption wavelength of a photothermal converting agent, the relief forming layer may be selectively removed with higher sensitivity, and a relief layer having a sharp image may be obtained. As infrared laser used in such a step (2), carbon dioxide gas laser or semiconductor laser is preferable from productivity and the cost. Particularly, semiconductor infrared laser with fiber is preferably used.

[Platemaking Apparatus Equipped with Semiconductor Laser]

Generally, semiconductor laser has a higher efficiency of laser oscillation, and is inexpensive as compared with CO₂ laser, and may be miniaturized. In addition, since semiconductor laser is small, it may be easily arrayed. Controlling of a beam diameter may be performed using an image forming lens, and a specified optical fiber. Since the semiconductor laser with fiber may output laser light effectively by further attaching an optical fiber, it is effective in forming an image in the invention. Further, a beam shape may be controlled by processing of a fiber. For example, a beam profile may be made to be a top hat shape, and it is possible to safely apply the energy to a plate surface. Details of semiconductor laser are described, for example, in “Laser Handbook, second edition” edited by Laser Academy, Practical Laser Technique, The Institute of Electronics, Engineers.

In addition, the platemaking apparatus equipped with semiconductor laser with fiber which may be preferably used in the process for producing the relief printing plate using the relief printing plate precursor of the invention is described in detail in Japanese Patent Application No. 2008-15460, and Japanese Patent Application No. 2008-58160 which were submitted by the present applicant, and this may be used in platemaking of the relief printing plate related to the invention.

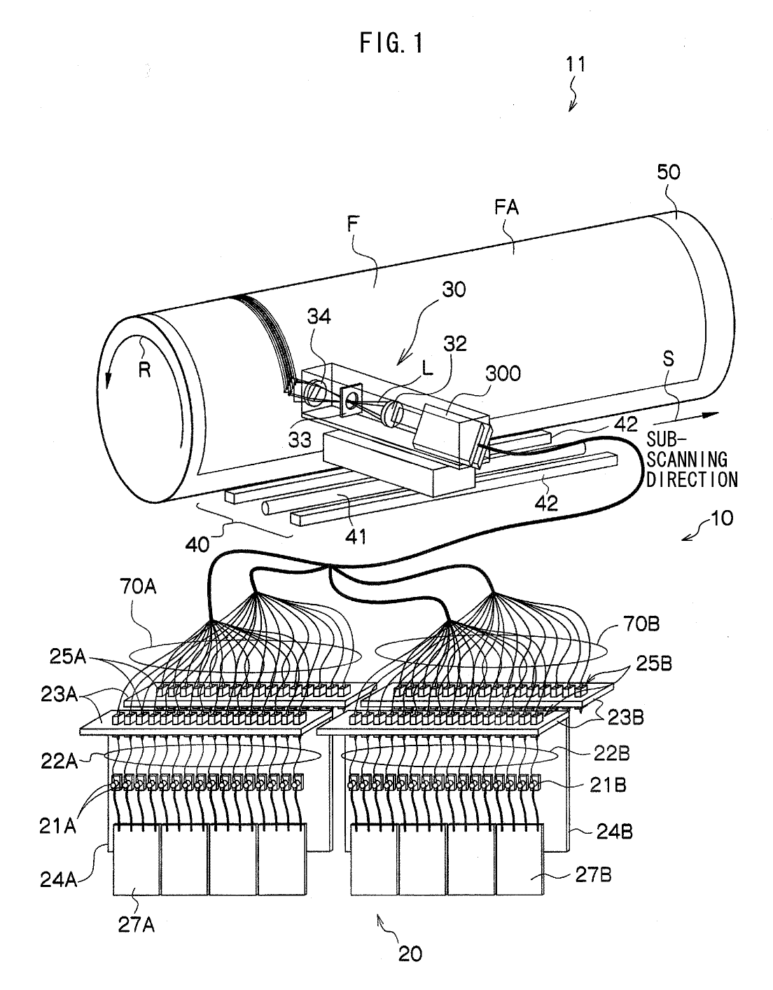

One embodiment of a platemaking apparatus 11 equipped with a semiconductor laser recording apparatus 10 with fiber which may be used in platemaking of the relief printing plate using the relief printing plate precursor of the invention will be explained regarding a construction thereof, referring to FIG. 1.

The platemaking apparatus 11 equipped with the semiconductor laser recording apparatus 10 with fiber which may be used in the invention engraves (records) a two-dimensional image on a relief printing plate precursor F by rotating a drum 50 mounted with the relief printing plate precursor F (recording medium) of the invention on an external circumferential surface in a main scanning direction and, at the same time, scanning a light exposing head 30 at a predetermined pitch in a sub-scanning direction orthogonal to a main scanning direction while a plural laser beams depending on image data of an image to be engraved (recorded) on the relief printing plate precursor F is emitted at the same time. In addition, when a narrow region is engraved (precise engraving such as fine line and dot), the relief printing plate precursor F is engraved shallowly and, when a wide region is engraved, the relief printing plate precursor F is engraved deeply.

As shown in FIG. 1, the platemaking apparatus 11 is constructed of the drum 50 which is mounted with the relief printing plate precursor F to be engraved with laser beam and image-recorded, and is rotation-driven in a FIG. 1 arrow R direction so that the relief printing plate precursor F is moved in a main scanning direction, and the laser recording apparatus 10. The laser recording apparatus 10 is constructed of a light source unit 20 generating plural laser beams, a light exposing head 30 with which the relief printing plate precursor F is exposed with plural laser beams generated in the light source unit 20, and a light exposing head moving part 40 which moves the light exposing head 30 along a sub-scanning direction.

The light source unit 20 is provided with semiconductor lasers 21A, 21B constructed of broad area semiconductor laser in which one end of each of optical fibers 22A, 22B is separately coupled, light source substrates 24A, 24B having a surface on which semiconductor lasers 21A, 21B are arranged, adaptor substrates 23A, 23B which are attached to one end of light source substrates 24A, 24B vertically and, at the same time, on which a plurality (the same number of semiconductor lasers 21A, 21B) of adaptors of SC-type light connectors 24A, 24B are provided, and LD driver substrates 27A, 27B which are attached to the other end of light source substrates 24A, 24B and, at the same time, on which a LD driver circuit 26 are provided which drives semiconductor lasers 21A, 21B depending on image data of an image to be engraved (recorded) on the relief printing plate precursor F.

The light head 30 is provided with a fiber array part 300 which collects and emits respective laser beams emitted from plural semiconductor lasers 21A, 21B. To this fiber array part 300 are transmitted laser beams emitted from respective semiconductor lasers 21A, 21B by plural optical fibers 70A, 70B connected to SC-type light connectors 25A, 25B connected to respective adaptor substrates 23A, 23B.

As shown in FIG. 1, in the light exposing head 30, a collimeter lens 32, an opening member 33, and an image forming lens 34 are arranged in an order from a fiber array part 300 side. The opening member 33 is arranged so that the opening is situated at a far field position, when it is seen from a fiber array part 300 side. Thereby, the equivalent light amount controlling effect may be imparted to all laser beams emitted from optical fiber ends 71A, 71B of plural optical fibers 70A, 70B in the fiber array part 300.

Laser beam forms an image in vicinity of a light exposing side (surface) FA of the relief printing plate precursor F by an image forming means constructed of the collimeter lens 32 and an image forming lens 34.

Since the beam shape may be changed in the semiconductor laser with fiber, in the invention, it is desirable to control the beam diameter at a light exposing side (relief forming layer surface) FA in the range of 10 μm to 80 μm by adjusting an image forming position P in the range which is an inside from the light exposing side FA (transmitting laser beam side) from a viewpoint that effective engraving is performed, and fine line reproductivity becomes good.

The light exposing head moving part 40 is provided with a ball screw 41 and two rails 42 arranged so that the longitudinal direction is along the sub-scanning direction and, by actuating a sub-scanning motor 43 which rotation-drives the ball screw 41, a base part 310 on which the light exposing head 30 is provided may be moved in the sub-scanning direction in the state where it is guided in the rail 42. In addition, the drum 50 may be rotated in the arrow R direction of FIG. 1 by actuating a main scanning motor (not shown), whereby, main scanning is performed.

Alternatively, in controlling of the shape to be engraved, by not chancing the beam shape of the semiconductor laser with fiber but changing the amount of energy supplied to the laser, the shape of an engraved region may be changed.

Specifically, there are a method of controlling by changing output of semiconductor laser, and a method of controlling by changing the laser irradiation time.

When an engraving waste is attached to the engraving surface, a step (3) of rinsing the engraving surface with water or a liquid containing water as a main component to wash out the engraving waste may be added. Examples of the rinsing means include a method of washing with tap water, a method of spraying pressurized water, and a method of brush-rubbing the engraving surface mainly in the presence of water with a batch-type or conveyance-type brushing washing machine known as a developing machine for photosensitive resin letterpress printing plate and, when sliminess of the engraving waste is not removed, a rinsing liquid with a surfactant added thereto may be used.

When the step (3) of rinsing the engraving surface is performed, it is preferable to add a step (4) of drying the engraved relief forming layer to evaporate the rinsing liquid.

Further, if necessary, a step (5) of further crosslinking the relief forming layer may be added. By performing the additional crosslinking step (5), a relief formed by engraving may be made to be more firm.

As described above, the relief printing plate of the invention having a relief layer on a support may be obtained.

The thickness of the relief layer in the relief printing plate is preferably 0.05 mm or more but 10 mm or less, more preferably 0.05 mm or more but 7 mm or less, particularly preferably 0.05 mm or more but 0.3 mm or less from a viewpoint that various flexography suitabilities such as wear resistance and ink transferability are satisfied.

In addition, it is preferable that the Shore A hardness of the relief layer in the relief printing plate is 50° or more but 90° or less.

When the Shore A hardness of the relief layer is 50° or more, even when a fine dot formed by engraving undergoes a strong printing pressure of a letterpress printing machine, the dot does not fall down and is not crushed, and normal printing may be performed. On the other hand, when the Shore A hardness of the relief layer is 90° or less, even in the case of flexography in which a printing pressure is kiss touch, printing shortage in a solid area may be prevented.

The Shore A hardness in the present specification is a value obtained by using a durometer (spring-type rubber hardness scale) for indentation-deforming the surface of an object to be measured with an indenter (also called a press needle), and measuring the value of the deformation amount (indentation depth).

The relief printing plate produced by the process of the invention may carry out printing with an oily ink or a UV ink with a letterprint printing machine, and may carry out printing with a UV ink with a flexographic printing machine.

According to the invention, for example, the following embodiments <1> to <13> are provided.

<1> A relief printing plate precursor for laser engraving, comprising a relief forming layer containing (A) a polymerizable compound having an ethylenic unsaturated bond, (B) a binder polymer, and (C) a compound having deodorizing ability.
<2> The relief printing plate precursor for laser engraving of <1>, wherein the (A) polymerizable compound having an ethylenic unsaturated bond is a compound comprising a sulfur atom in a molecule.
<3> The relief printing plate precursor for laser engraving of <I> or <2>, wherein the (C) compound having deodorizing ability is at least one compound selected from polyphenols.
<4> The relief printing plate precursor for laser engraving of <3>, wherein the at least one compound selected from polyphenols is a compound comprising at least one of a catechol group or a pyrogallol group.
<5> The relief printing plate precursor for laser engraving of <3> or <4>, wherein the at least one compound selected from polyphenols is a compound comprising a functional group represented by the following structural formula (I):

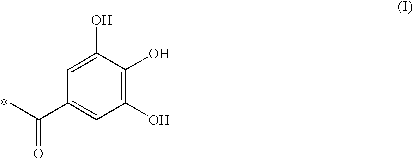

<6> The relief printing plate precursor for laser engraving of any one of <3> to <5>, wherein the at least one compound selected from polyphenols is a catechin derivative.
<7> The relief printing plate precursor for laser engraving of any one of <1> to <6>, wherein the relief forming layer further comprises (D) a photothermal converting agent which absorbs light having a wavelength of 700 nm to 1,300 nm.
<8> The relief printing plate precursor for laser engraving of any one of <1> to <7>, wherein the relief forming layer is cured by at least one of light or heat.
<9> A process for producing a relief printing plate, comprising:

crosslinking the relief forming layer in the relief printing plate precursor for laser engraving as defined in any one of <1> to <7> by at least one of light or heat, and

laser-engraving the crosslinked relief forming layer to form a relief layer.

<10> The process for producing a relief printing plate of <9>, wherein the relief forming layer is crosslinked by heat.
<11> A relief printing plate comprising a relief layer, which is produced by the process for producing a relief printing plate as defined in <9> or <10>.
<12> The relief printing plate of <11>, wherein the thickness of the relief layer is from 0.05 mm to 10 mm.
<13> The relief printing plate of <11> or <12>, wherein the Shore A hardness of the relief layer is from 50° to 90°.

According to the invention, a relief printing plate precursor for laser engraving in which the engraving sensitivity is sufficiently high, platemaking may be performed directly by laser engraving, and an unpleasant order generated thereupon may be suppressed, a process for producing a relief printing plate using the relief printing plate precursor, and a relief printing plate obtained by the process may be provided.

### EXAMPLES

The present invention will be explained in more detail below by way of Examples, but the invention is not limited to these Examples.

First, Synthesis Examples and structures of sulfur-containing polyfunctional monomers M1 and M2, and a polyfunctional monomer C, and a structure of a sulfur-containing polyfunctional monomer M3, used in Examples and Comparative Examples, will be shown.

### Synthesis Example

### Synthesis of Sulfur-Containing Polyfunctional Monomer M1

Into a 500 mL three-neck flask equipped with a stirring blade and a condenser were placed 3,3′-thiodipropionic acid (89.05 g, manufactured by Wako Pure Chemical Industries, Ltd.), glycidyl methacrylate (156.26 g, manufactured by Wako Pure Chemical Industries, Ltd.), 1-methoxy-2-propanol (27.78 g, manufactured by Nippon Nyukazai Co., Ltd.), tetraethylammonium bromide (4.20 g, manufactured by Tokyo Chemical Industry Co., Ltd.), and 4-hydroxy-2,2,6,6-tetramethylpyridine 1-oxyl free radical (0.50 g, manufactured by Tokyo Chemical Industry Co., Ltd.), and the mixture was stirred at 80° C. for 4 hours. To this solution were added water (500 g) and ethyl acetate (500 g), this was transferred to a separation funnel, the mixture was vigorously stirred, and the aqueous layer was removed. Subsequently, an aqueous saturated sodium carbonate solution (200 g) was added, the mixture was vigorously stirred, and the aqueous layer was removed. Subsequently, an aqueous saturated sodium chloride solution (200 g) was added, the mixture was vigorously stirred, and the aqueous layer was removed. The organic layer was transferred to a IL Erlenmeyer flask, and magnesium sulfate (100 g) was added for drying. Magnesium sulfate was removed by filtration, and ethyl acetate was removed under reduced pressure to obtain a sulfur-containing polyfunctional monomer M1 (233.04 g) of the following structure. A structure of the resulting sulfur-containing polyfunctional monomer M1 was identified by ¹H NMR.

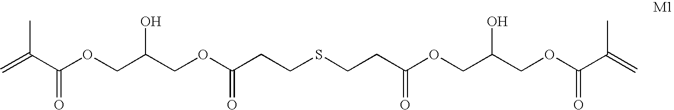

### Synthesis Example

### Synthesis of Sulfur-Containing Polyfunctional Monomer M2

A sulfur-containing polyfunctional monomer M2 of the following structure was synthesized by applying the same synthesis method as that of the sulfur-containing polyfunctional monomer M1, but substituting the “3,3′-thiodipropionic acid” with “3,3′-dithiodipropionic acid”. The structure of the resulting sulfur-containing polyfunctional monomer M2 was identified by ¹H NMR.

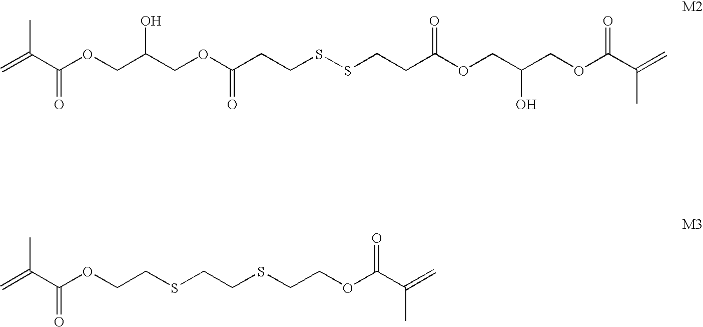

### Synthesis Example

### Synthesis of Polyfunctional Monomer C

A polyfunctional monomer C of the following structure was synthesized by applying the same synthesis method as that of the sulfur-containing polyfunctional monomer M1, but substituting the “3,3′-thiodipropionic acid” with “pimelic acid”. The structure of the resulting polyfunctional monomer C was identified by ¹H NMR.

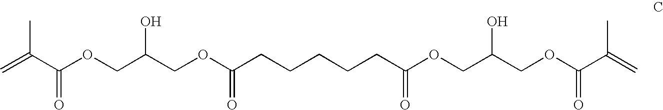

Structures of compounds C-1 to C-12 having deodorizing ability used in Examples are shown below.

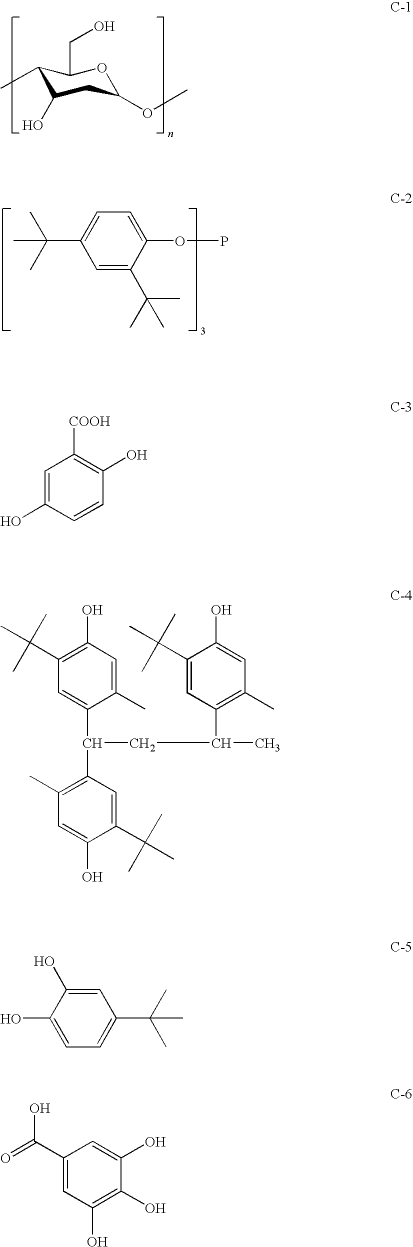

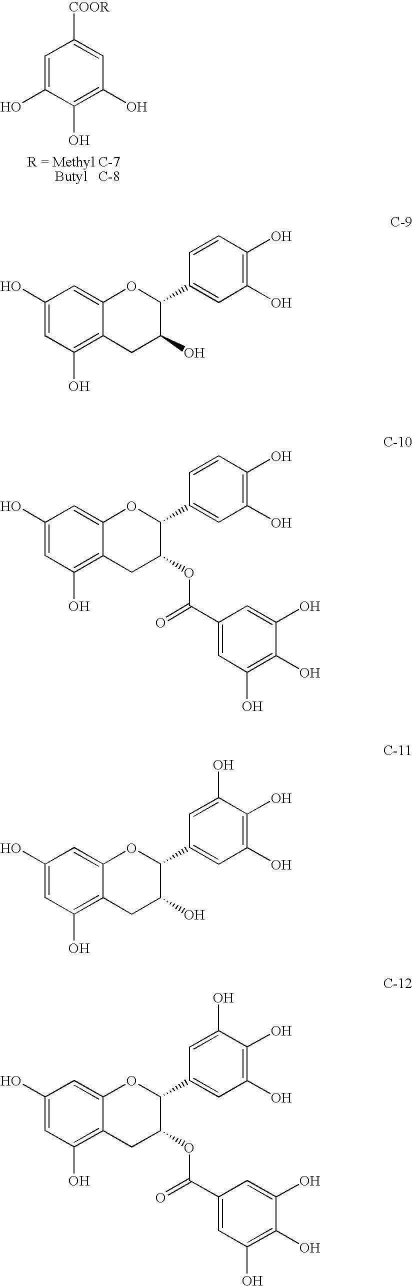

Subsequently, Synthesis Examples and structures of Compound 1, Compound 6, Compound 7, and Compound 8 used in Examples will be shown.

### Synthesis Example

### Synthesis of Compound (Compound 1) Having Polymerizable Group and Having Odor Preventing Ability

4-Hydroxybenzoic acid (0.2 mol), 2-bromoethanol (0.2 mol), diazabicycloundecene (0.2 mol), and acetonitrile (300 ml) were mixed, and they were reacted at 80° C. for 6 hours. Thereafter, the resulting reaction solution were subjected to liquid separating operation using aqueous hydrochloric acid solution, and an aqueous sodium bicarbonate solution, and the organic layer was extracted. The extract was dried with magnesium sulfate, and the solvent was removed with an evaporator to obtain a precursor (1-a) of the following structure (yield 86%).

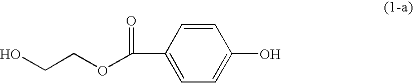

Then, acryloyl chloride (0.3 mol) was added dropwise to a mixed solution in which the resulting precursor (1-a) (0.1 mol) had been dissolved in N-methylpyrrolidone (200 ml), to react them at room temperature for 24 hours. After completion of the reaction, the reaction solution was added dropwise to ice water (2 L), unreacted acryloyl chloride was decomposed into acrylic acid, and a liquid separation procedure was performed using an aqueous sodium bicarbonate solution to extract the organic layer. The extract was dried with magnesium sulfate, and the solvent was removed with an evaporator to obtain a compound (Compound 1 of the following structure) having a polymerizable group and having odor preventing ability (yield 79%).

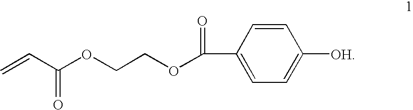

### Synthesis Example

### Synthesis of Compound (Compound 6) Having Polymerizable Group and Having Odor Preventing Ability

Methacryloyl chloride (0.3 mol) was added dropwise to a mixed solution in which epicatechin (0.2 mol) had been dissolved in N-methylpyrrolidone (200 ml), to react them at room temperature for 24 hours. After completion of the reaction, the reaction solution was added dropwise to ice water (2 L), unreacted methacryloyl chloride was decomposed into methacrylic acid, and a liquid separation procedure was performed using an aqueous sodium bicarbonate solution to extract the organic layer. The extract was dried with magnesium sulfate, and the solvent was removed with an evaporator to obtain a compound (Compound 6 of the following structure) having a polymerizable group and having odor preventing ability (yield 84%).

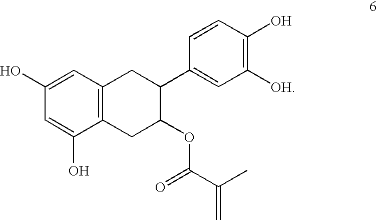

### Synthesis Example

### Synthesis of Compound (Compound 7) Having Polymerizable Group and Having Odor Preventing Ability

Acryloyl chloride (0.3 mol) was added dropwise to a mixed solution in which epigallocatechin (0.2 mol) had been dissolved in N-methylpyrrolidone (200 ml), to react them at room temperature for 24 hours. After completion of the reaction, the reaction solution was added dropwise to ice water (2 L), unreacted acryloyl chloride was decomposed into acrylic acid, and a liquid separation procedure was performed using an aqueous sodium bicarbonate solution to extract the organic layer. The extract was dried with magnesium sulfate, and the solvent was removed with an evaporator to obtain a compound (Compound 7 of the following structure) having a polymerizable group and having odor preventing ability (yield 69%).

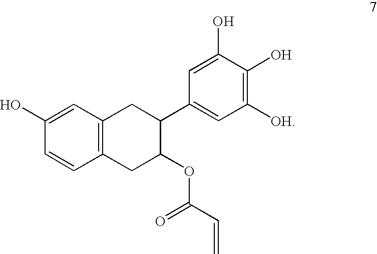

### Synthesis Example

### Synthesis of Compound (Compound 8) Having Polymerizable Group and Having Odor Preventing Ability

KARENZ MOI (0.2 mol) was added dropwise to a mixed solution in which epicatechin (0.2 mol) had been dissolved in N-methylpyrrolidone (200 ml), to react them at room temperature for 24 hours. After completion of the reaction, the reaction solution was added dropwise to ice water (2 L), and a liquid separation procedure was performed using an aqueous sodium bicarbonate solution to extract the organic layer. The extract was dried with magnesium sulfate, and the solvent was removed with an evaporator to obtain a compound (Compound 8 of the following structure) having a polymerizable group and having odor preventing ability (yield 77%).

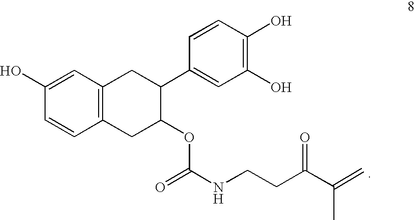

### Example A-1

### 1. Preparation of Coating Liquid Composition for Relief Forming Layer

Into a three-neck flask equipped with a stirring blade and a condenser were placed 50 g of “DENKA BUTYRAL #3002-2” (manufactured by Denki Kagaku Kogyo K.K., polyvinyl butyral derivative Mw=90000) as a binder polymer, and 47 g of propylene glycol monomethyl ether acetate as a solvent, and this was heated at 70° C. for 120 minutes while it was stirred, to dissolve the polymer. Thereafter, a temperature of the solution was adjusted to 40° C., 15 g of M2 (the aforementioned structure) as a polymerizable compound (sulfur-containing polyfunctional monomer), 8 g of BLENMER LMA (manufactured by NOF Corporation) as a polymerizable compound (monofunctional monomer), 1.6 g of PERBUTIL Z (manufactured by NOF Corporation) as a polymerization initiator, 1 g of KEDJENN BLACK EC600 JD (carbon black manufactured by Lion Corporation) as a photothermal converting agent, and 1 g of Compound C-1 (the aforementioned structure, β-cyclodextrin) having deodorizing ability were added, and the mixture was stirred for 30 minutes. By this procedure, a coating liquid A for a crosslinkable relief forming layer having flowability was obtained.

[Evaluation]

—Coating Liquid Stability—

The resulting coating liquid (2 g) for a crosslinkable relief forming layer having flowability was placed into a sample bottle, and the bottle was closed. This was immersed into a water bath set at a water temperature of 70° C. to a height which was a half from a bottom of the sample bottle, a time at which flowability of the coating liquid was lost (even when the sample bottle was turned bottom up, a liquid did not fall) (gelling time) was measured and this was used as an index for coating liquid stability. A longer gelling time means that coating liquid stability is better.

### 2. Production of Relief Printing Plate Precursor for Laser Engraving

A spacer (frame) of the predetermined thickness was arranged on a PET substrate, the coating liquid composition A for a relief forming layer obtained as described above was calmly cast to such an extent that it did not flow out from the spacer (frame), and dried in an oven at 70° C. for 4 hours to provide a relief forming layer having a thickness of approximately 1 mm.

After the resulting relief forming layer was heated at 80° C. for 3 hours, this was further heated at 100° C. for 3 hours to thermally crosslink the relief forming layer, to obtain a relief printing plate precursor for laser engraving.

### 3. Production of Relief Printing Plate

The relief forming layer after crosslinking was engraved using two kinds of lasers described in the following 3-1 and 3-2.

### 3-1. Engraving Using FC-LD

As a semiconductor laser engraving machine, the aforementioned laser recording apparatus with fiber shown in FIG. 1 equipped with a semiconductor laser with fiber (FC-LD) SDL-6390 (manufactured by JDSU, wavelength 915 nm) having a maximum output of 8.0 W was used. For the relief forming layer after crosslinking, a solid area of 1 cm square was luster-engraved with this semiconductor laser engraving machine under the condition of laser output: 6 W, head speed: 100 mm/sec, and pitch setting: 2400 DPI (Results of evaluation using this laser are expressed by “FC-LD” in Table).

### 3-1. Engraving Using CO₂ Laser

As a carbon dioxide gas laser engraving machine, high quality CO₂ laser marker ML-9100 Series (manufactured by KEYENCE) was used. For the relief forming layer after crosslinking, a solid area of 1 cm square was luster-engraved with this carbon dioxide gas laser engraving machine under the condition of output: 12 W, head speed: 200 nm/sec, and pitch setting: 2400 DPI (Results of evaluation using this laser is expressed by “CO₂ Laser” in Table).

The thickness of the relief layer in the relief printing plate after engraving was 1.14 mm.

In addition, when the Shore A hardness of the relief layer was measured by the aforementioned measuring method, the hardness was found to be 74°. Measurement of the Shore hardness A of the relief layer was performed similarly in each Example and Comparative Example described later.

### Examples A-2 to A-21

According to the same manner as that of Example A-1 except that the “sulfur-containing polyfunctional monomer M2” used in Example A-1 was changed to a polyfunctional monomer described in the following Table 1, and/or the “Compound C-1 having deodorizing ability” was changed to each compound described in the following Table 1, a coating liquid composition for a relief forming layer was prepared, a relief printing plate precursor for laser engraving was produced and, thereafter, a relief printing plate was produced from the relief printing plate precursor for laser engraving.

The thickness and the Shore A hardness of a relief layer in the resulting relief printing plate are as shown in the following Table 1.

### Comparative Examples A-1 to A-3

According to the same manner as that of Example A-1 except that the “sulfur-containing polyfunctional monomer M2” used in Example A-1 was changed to a polyfunctional monomer described in the following Table 1, and/or a coating liquid composition for a relief forming layer was prepared without using the “Compound C-1 having deodorizing ability”, a relief printing plate precursor for laser engraving was produced and, thereafter, a relief printing plate was produced from the relief printing plate precursor for laser engraving.

The thickness and the Shore A hardness of a relief layer in the resulting relief printing plate are as shown in the following Table 1.

<Evaluation>

—Engraving Depth—

The “engraving depth” of the relief layer in the relief printing plate after engraving was measured as follows. Herein, the “engraving depth” refers to a difference between an engraved position (height) and an unengraved position (height) when a cross-section of the relief layer is observed. The “engraving depth” in the present Example was measured by observing a cross-section of the relief layer with a superdepth color 3D shape measuring microscope VK9510 (manufactured by Keyence corporation). A greater engraving depth means the higher engraving sensitivity. Results are shown in Table 1.

—Odor Evaluation—

Regarding the printing plate precursor during laser engraving by the aforementioned method, an odor was smelled to perform organoleptic evaluation, and a level of an odor was evaluated as follows. Results are shown in Table 1.

Evaluation was performed by six professional panelists under the following evaluation criteria (scores).

### Evaluation Criteria (Scores):

A: Four or more of six persons recognized the odor decreasing effect.
B: Two or more of six persons recognized the odor decreasing effect.
C: The odor decreasing effect was not recognized.

When the score is A or B, it is thought that there is no practical problem.

Herein, the “odor decreasing effect” refers to the effect obtained by laser-engraving both of a relief printing plate precursor with a compound having deodorizing ability added thereto, and a relief printing plate precursor having entirely the same composition except that a compound having deodorizing ability is not added, by the aforementioned method, and comparing odors therefrom.

TABLE 1

| | Coating liquid A for relief forming layer | | | Relief layer | | Engraving | | |
|---|---|---|---|---|---|---|---|---|
| | | (C) Compound | Coating liquid | | Shore A | depth (μm) | | |
| | | having | stability (hr) | Thickness | hardness | | CO₂ | |
| | (A) Polymerizable compound | deodorizing ability | (70° C.) | (mm) | (°) | FC-LD | laser | Odor |
| Example A-1 | Sulfur-containing polyfunctional monomer M2 | C-1 | 21 | 1.14 | 74 | 460 | 368 | B |
| Example A-2 | Sulfur-containing polyfunctional monomer M2 | C-2 | 23 | 1.13 | 78 | 455 | 364 | B |
| Example A-3 | Sulfur-containing polyfunctional monomer M2 | C-3 | >30 | 1.11 | 69 | 450 | 360 | B |
| Example A-4 | Sulfur-containing polyfunctional monomer M2 | C-4 | >30 | 1.20 | 70 | 460 | 368 | B |
| Example A-5 | Sulfur-containing polyfunctional monomer M2 | C-5 | >30 | 1.33 | 70 | 440 | 352 | B |
| Example A-6 | Sulfur-containing polyfunctional monomer M2 | Resorcinol | >30 | 1.25 | 70 | 445 | 356 | B |
| Example A-7 | Sulfur-containing polyfunctional monomer M2 | Pyrogallol | >30 | 1.14 | 70 | 450 | 360 | A |
| Example A-8 | Sulfur-containing polyfunctional monomer M3 | C-6 | >30 | 1.14 | 79 | 450 | 360 | A |
| Example A-9 | Sulfur-containing polyfunctional monomer M3 | C-7 | >30 | 1.15 | 70 | 450 | 360 | A |
| Example A-10 | Sulfur-containing polyfunctional monomer M3 | C-8 | >30 | 1.10 | 75 | 460 | 368 | A |
| Example A-11 | Sulfur-containing polyfunctional monomer M3 | C-9 | >30 | 1.10 | 75 | 460 | 368 | A |
| Example A-12 | Sulfur-containing polyfunctional monomer M3 | C-10 | >30 | 1.12 | 75 | 460 | 368 | A |
| Example A-13 | Sulfur-containing polyfunctional monomer M3 | C-11 | >30 | 1.14 | 74 | 460 | 368 | A |
| Example A-14 | Sulfur-containing polyfunctional monomer M3 | C-12 | >30 | 1.30 | 73 | 460 | 368 | A |
| Example A-15 | Glycerol 1,3-dimethacrylate | C-6 | 17 | 1.25 | 65 | 390 | 312 | A |
| Example A-16 | Glycerol 1,3-dimethacrylate | C-7 | 19 | 1.14 | 66 | 380 | 304 | A |
| Example A-17 | Glycerol 1,3-dimethacrylate | C-8 | 20 | 1.14 | 69 | 380 | 304 | A |
| Example A-18 | Glycerol 1,3-dimethacrylate | C-9 | 18 | 1.15 | 65 | 385 | 308 | A |
| Example A-19 | Glycerol 1,3-dimethacrylate | C-10 | 15 | 1.16 | 64 | 370 | 296 | A |
| Example A-20 | Glycerol 1,3-dimethacrylate | C-11 | 16 | 1.11 | 66 | 390 | 312 | A |
| Example A-21 | Glycerol 1,3-dimethacrylate | C-12 | 18 | 1.10 | 70 | 380 | 304 | A |
| Comparative | Sulfur-containing polyfunctional monomer M2 | None | >30 | 1.14 | 74 | 450 | 360 | C |
| example A-1 | | | | | | | | |
| Comparative | Sulfur-containing polyfunctional monomer M3 | None | >30 | 1.12 | 75 | 450 | 360 | C |
| example A-2 | | | | | | | | |
| Comparative | Glycerol 1,3-dimethacrylate | None | 16 | 1.10 | 66 | 370 | 296 | C |
| example A-3 | | | | | | | | |

As shown in Table 1, it was confirmed that an unpleasant odor at laser engraving was suppressed by adding the compound having deodorizing ability. In addition, all of engraving depths exceed 300 μm, and it is seen that the engraving sensitivity is sufficiently high.

Particularly, upon use of a polymerizable compound having a sulfur atom (sulfur-containing polyfunctional monomer) as a polymerizable compound, the engraving depth is particularly great, and it was confirmed that the remarkable odor suppressing effect is obtained by using a compound having deodorizing ability containing at least one of a catechol group or a pyrogallol group (galloyl group) together with this polymerizable compound.

### Example B-1

### 1. Preparation of Coating Liquid Composition for Relief Forming Layer

Into a three-neck flask equipped with a stirring blade and a condenser were placed 34 g of GOHSENOL T-215 (manufactured by Nippon Synthetic Chemical Industry, Co., Ltd., PVA derivative) as a binder polymer, 0.75 g of KEDJENN BLACK EC600 JD (carbon black manufactured by Lion Corporation) as a photothermal converting agent, 20 g of diethylene glycol as a plasticizer, and 35 g of water and 12 g of ethanol as a solvent, and the mixture was heated at 60° C. for 120 minutes while it was stirred, to dissolve the polymer. Further, 34 g of the sulfur-containing polyfunctional monomer M1 synthesized as described above, 1.8 g of PERBUTIL Z (manufactured by NOF Corporation) as a polymerization initiator, and 1.5 g of catechin as a deodorizing agent were added and the mixture was stirred for 30 minutes to obtain a coating liquid composition B for a relief forming layer having flowability.

### 2. Production of Relief Printing Plate Precursor for Laser Engraving

A spacer (frame) of the predetermined thickness was arranged on a PET substrate, the coating liquid composition B for a relief forming layer obtained as described above was calmly cast to such an extent that the composition did not flow out from the spacer (frame), and this was dried in an oven at 70° for 4 hours to provide a relief forming layer having a thickness of approximately 1 mm.

The resulting relief forming layer was heated at 100° C. for 3 hours to thermally crosslink the relief forming layer, to obtain a relief printing plate precursor for laser engraving.

### 3. Production of Relief Printing Plate

For the relief forming layer after crosslinking, a solid area of a 2 cm square was engraved using “FD-100” (manufactured by Tosei Electrobeam Co., Ltd.) equipped with semiconductor laser (laser oscillation wavelength 840 nm) of a maximum output of 16 W as a near infrared laser engraving machine and setting the engraving condition at laser output: 15 W, scanning speed: 100 mm/sec, and pitch interval: 0.15 mm, thereby, a relief layer was formed to obtain a relief printing plate.

The thickness of the relief layer in the relief printing plate after engraving was 1.36 mm.

In addition, when the Shore A hardness of the relief layer was measured by the aforementioned measuring method, the hardness was found to be 64°.

### Examples B-2 to B-8, Comparative Examples B-1 to B-3

According to the same manner as that of Example B-1 except that the “sulfur-containing polyfunctional monomer M1” used in Example B-1 was changed to a polyfunctional monomer described in the following Table 2, and the “catechin” was changed to each compound described in the following Table 2, a coating liquid composition for a relief forming layer was prepared, a relief printing plate precursor for laser engraving was produced and, thereafter, a relief printing plate was produced from the relief printing plate precursor for laser engraving.

The thickness and the Shore A hardness of the relief layer in the resulting relief printing plate are as shown in the following Table 2.

Further, as in Example A-1, measurement of the engraving depth and evaluation of an odor were performed. Results are shown in Table 2.

### Examples B-9 to B-16, Comparative Examples B-4 to B-6

According to the same manner as that of Example B-1 except that the “sulfur-containing polyfunctional monomer M1” used in Example B-1 was changed to a polyfunctional monomer described in the following Table 2, and the “catechin” was changed to each compound described in the following Table 2, a coating liquid composition for a relief forming layer was prepared, and a relief printing plate precursor for laser engraving was produced.

According to the same manner as that of Example B-1 except that laser engraving was performed on the resulting relief printing plate precursor for laser engraving using a carbon dioxide gas laser engraving machine as described below, a relief printing plate was produced.

That is, as the carbon dioxide gas laser engraving machine, “CO₂ laser marker ML-Z9500” (manufactured by Keyence Corporation) equipped with carbon dioxide gas laser of a maximum output of 30 W was used. The engraving condition was set at laser output: 15 W, scanning speed: 100 mm/sec, and pitch interval: 0.15 mm, and a solid area of 2 cm square was engraved to obtain a relief printing plate.

Herein, the thickness and the Shore A hardness of the relief layer in the resulting relief printing plate are as shown in the following Table 2.

Further, as in Example A-1, measurement of the engraving depth and evaluation of the odor were performed. Results are shown in Table 2.

TABLE 2

| | Coating liquid B for relief forming layer | | | Relief layer | | | |
|---|---|---|---|---|---|---|---|
| | | (C) Compound | | | Shore A | Engraving | |
| | | having | | Thickness | hardness | depth | |
| | (A) Polymerizable compound | deodorizing ability | Engraving laser | (mm) | (°) | (μm) | Odor |
| Example B-1 | Sulfur-containing polyfunctional monomer M1 | Catechin | Semiconductor laser | 1.36 | 64 | 600 | B |
| Example B-2 | Sulfur-containing polyfunctional monomer M2 | t-Butylcatechol | Semiconductor laser | 1.26 | 67 | 580 | B |
| Example B-3 | Polyfunctional monomer C | Gallotannin | Semiconductor laser | 1.52 | 66 | 470 | B |
| Example B-4 | Glycerol 1,3-dimethacrylate | Compound 1 | Semiconductor laser | 1.38 | 70 | 460 | A |
| Example B-5 | Sulfur-containing polyfunctional monomer M1 | Epigallocatechin | Semiconductor laser | 1.47 | 69 | 560 | B |
| | | gallate | | | | | |
| Example B-6 | Sulfur-containing polyfunctional monomer M2 | Compound 6 | Semiconductor laser | 1.39 | 67 | 550 | A |
| Example B-7 | Polyfunctional monomer C | Compound 8 | Semiconductor laser | 1.28 | 72 | 450 | A |
| Example B-8 | Glycerol 1,3-dimethacrylate | 4-Methyl-6-t- | Semiconductor laser | 1.46 | 65 | 440 | B |
| | | butylphenol | | | | | |
| Example B-9 | Sulfur-containing polyfunctional monomer M1 | Compound 7 | Carbon dioxide gas | 1.64 | 63 | 270 | A |
| | | | laser | | | | |
| Example B-10 | Sulfur-containing polyfunctional monomer M2 | Catechin | Carbon dioxide gas | 1.53 | 64 | 280 | B |
| | | | laser | | | | |
| Example B-11 | Polyfunctional monomer C | t-Butylcatechol | Carbon dioxide gas | 1.38 | 67 | 190 | B |
| | | | laser | | | | |
| Example B-12 | Glycerol 1,3-dimethacrylate | Gallotannin | Carbon dioxide gas | 1.25 | 66 | 180 | B |
| | | | laser | | | | |
| Example B-13 | Sulfur-containing polyfunctional monomer M1 | Compound 1 | Carbon dioxide gas | 1.46 | 70 | 285 | A |
| | | | laser | | | | |
| Example B-14 | Sulfur-containing polyfunctional monomer M2 | Epigallocatechin | Carbon dioxide gas | 1.47 | 69 | 280 | B |
| | | gallate | laser | | | | |
| Example B-15 | Polyfunctional monomer C | Compound 6 | Carbon dioxide gas | 1.32 | 71 | 180 | A |
| | | | laser | | | | |
| Example B-16 | Glycerol 1,3-dimethacrylate | Compound 8 | Carbon dioxide gas | 1.28 | 68 | 170 | A |
| | | | laser | | | | |
| Comparative | Polyfunctional monomer C | — | Semiconductor laser | 1.38 | 78 | 460 | C |
| example B-1 | | | | | | | |
| Comparative | Sulfur-containing polyfunctional monomer M1 | — | Semiconductor laser | 1.36 | 62 | 585 | C |
| example B-2 | | | | | | | |
| Comparative | Glycerol 1,3-dimethacrylate | — | Semiconductor laser | 1.42 | 76 | 440 | C |
| example B-3 | | | | | | | |
| Comparative | Polyfunctional monomer C | — | Carbon dioxide gas | 1.38 | 78 | 160 | C |
| example B-4 | | | laser | | | | |
| Comparative | Sulfur-containing polyfunctional monomer M1 | — | Carbon dioxide gas | 1.36 | 62 | 270 | C |
| example B-5 | | | laser | | | | |
| Comparative | Glycerol 1,3-dimethacrylate | — | Carbon dioxide gas | 1.42 | 76 | 140 | C |
| example B-6 | | | laser | | | | |

As shown in Table 2, it was confirmed that an unpleasant odor at laser engraving was suppressed by adding the compound having deodorizing ability. In addition, all of engraving depths exceed 100 μm, and it is seen that the engraving sensitivity is sufficiently high.

Particularly, upon use of a polymerizable compound having a sulfur atom (sulfur-containing polyfunctional monomer) as a polymerizable compound, the engraving depth is particularly great, and it was confirmed that the remarkable odor suppressing effect is obtained.

All publications, patent applications, and technical standards mentioned in this specification are herein incorporated by reference to the same extent as if each individual publication, patent application, or technical standard was specifically and individually indicated to be incorporated by reference.

What is claimed is:

1. A relief printing plate precursor for laser engraving, comprising a relief forming layer containing (A) a polymerizable compound having an ethylenic unsaturated bond, (B) a binder polymer, and (C) a compound having deodorizing ability.

2. The relief printing plate precursor for laser engraving of claim 1, wherein the (A) polymerizable compound having an ethylenic unsaturated bond is a compound comprising a sulfur atom in a molecule.

3. The relief printing plate precursor for laser engraving of claim 1, wherein the (C) compound having deodorizing ability is at least one compound selected from polyphenols.

4. The relief printing plate precursor for laser engraving of claim 3, wherein the at least one compound selected from polyphenols is a compound comprising at least one of a catechol group or a pyrogallol group.

5. The relief printing plate precursor for laser engraving of claim 3, wherein the at least one compound selected from polyphenols is a compound comprising a functional group represented by the following structural formula (I):

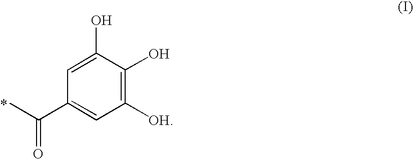

6. The relief printing plate precursor for laser engraving of claim 3, wherein the at least one compound selected from polyphenols is a catechin derivative.

7. The relief printing plate precursor for laser engraving of claim 1, wherein the relief forming layer further comprises (D) a photothermal converting agent which absorbs light having a wavelength of 700 nm to 1,300 nm.

8. The relief printing plate precursor for laser engraving of claim 1, wherein the relief forming layer is cured by at least one of light or heat.

9. A process for producing a relief printing plate, comprising:
crosslinking the relief forming layer in the relief printing plate precursor for laser engraving as defined in claim 1 by at least one of light or heat, and
laser-engraving the crosslinked relief forming layer to form a relief layer.

10. The process for producing a relief printing plate of claim 9, wherein the relief forming layer is crosslinked by heat.

11. A relief printing plate comprising a relief layer, which is produced by the process for producing a relief printing plate as defined in claim 9.

12. The relief printing plate of claim 11, wherein the thickness of the relief layer is from 0.05 mm to 10 mm.

13. The relief printing plate of claim 11, wherein the Shore A hardness of the relief layer is from 500 to 90°.
